(19) United States
(12) Patent Application Publication
(10) Pub. No.: US 2026/0136834 A1
(43) Pub. Date: May 14, 2026

(54) BORON-NITROGEN COMPOUND AND ORGANIC ELECTROLUMINESCENT DEVICE COMPRISING SAME

(71) Applicant: Anhui Huaxian New Materials Technology Co., Ltd, Fuyang (CN)

(72) Inventors: Lei Zhang, Fuyang (CN); Yongfeng Zhu, Fuyang (CN); Hailin Wang, Fuyang (CN); Lijun Tang, Fuyang (CN); Yunqi Liu, Fuyang (CN); Xiaoyu Zhao, Fuyang (CN)

(21) Appl. No.: 19/038,820

(22) Filed: Jan. 28, 2025

(30) Foreign Application Priority Data
Nov. 13, 2024 (CN) 202411612687.4

(51) Int. Cl. H10K 85/60; C07F 5/02; C07F 7/08; C07F 7/30; H10K 50/12; H10K 85/30; H10K 85/40

(52) U.S. Cl. CPC H10K 85/658; C07F 5/027; C07F 7/0816; C07F 7/30; H10K 85/30; H10K 85/40; H10K 85/622; H10K 85/626; H10K 85/654; H10K 85/6572; C07B 2200/05; H10K 50/121

(57) ABSTRACT

The present disclosure relates to the technical field of organic photoelectric material preparation and particularly to a boron-nitrogen compound and an organic electroluminescent device comprising same. The boron-nitrogen compound of the present disclosure has a good ability to accept electrons and holes. By introducing groups with large steric hindrance such as azafluorene/benzofluorene/azabenzofluorene/silafluorene/germafluorene, the interactions between luminescent molecules can be effectively inhibited. Structures such as the large conjugated spiro-ring structural unit and the sp² aza-aromatic rings in the compound can improve the energy transmission performance between the host and the guest or the sensitizer. Specifically, after the boron-nitrogen compound of the present disclosure is used as a functional layer, particularly as the emissive layer, in a manufactured organic electroluminescent device, there is an improvement in current efficiency, a reduction in turn-on voltage, and a relatively big improvement in the lifespan of the device.

### CROSS-REFERENCE TO RELATED APPLICATION

This application claims priority to Chinese Patent Application No. 202411612687.4, filed on Nov. 13, 2024, the content of which is incorporated herein by reference in its entirety.

### TECHNICAL FIELD

The present disclosure relates to the technical field of organic photoelectric material preparation and particularly to a boron-nitrogen compound and an organic electroluminescent device comprising same.

### BACKGROUND

As multimedia technology advances and the demand for informatization increases, the performance requirements for panel displays have become more stringent. Organic light-emitting diodes (OLEDs) have attracted significant attention for their advantages, such as self-emission, low-voltage direct-current operation, full curing, wide viewing angles, and rich colors, and their potential applications in new-generation display and lighting technologies. Their application prospect is very wide. Organic electroluminescent devices are spontaneous light-emitting devices. OLEDs' light emission mechanism is that electrons and holes, after being injected from the positive and negative electrodes, respectively, under an external electric field, migrate, recombine, and are attenuated in an organic material, thereby emitting light. A typical OLED structure contains one or more functional layers of the cathode layer, the anode layer, the electron injection layer, the electron transport layer, the hole blocking layer, the hole transport layer, the hole injection layer, and the emissive layer. Despite the very rapid advancements in organic electroluminescence research, many urgent problems remain to be addressed. For example, the development of efficient, long-lifespan, and narrow-emission green light materials has always been an urgent problem in the art.

### SUMMARY

The purpose of the present disclosure is to provide a boron-nitrogen compound and an organic electroluminescent device comprising same to address the defects of the prior art. The present disclosure effectively inhibits the interactions between luminescent molecules by introducing a spiro-ring group with large steric hindrance. Introducing structures such as a large conjugated spiro-ring structure and sp² aza-aromatic rings to optimize boron-nitrogen compounds' ability to accept electrons and holes can improve the energy transmission performance between the host and the guest and reduce the concentration of high-energy excitons in the emissive layer, thereby realizing an efficient, long-lifespan, and narrow-emission green light material.

To achieve the purpose of the present disclosure, the present disclosure uses the following technical solutions:

According to one or more embodiments, the present disclosure provides a boron-nitrogen compound having a structure represented by formula (I) as shown below:

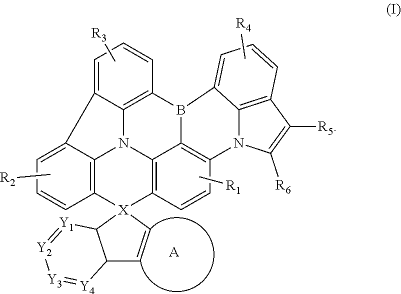

In formula (I), X is selected from C, Si and Ge; ring A is selected from substituted or unsubstituted C6-C30 aryl and substituted or unsubstituted C6-C30 heteroaryl; Y₁, Y₂, Y₃ and Y₄ are each independently selected from CR and N; each of R₁-R₄ represents one or more substitutents; and R and R₁-R₆ are each independently selected from hydrogen, deuterium, C1-C24 alkyl, substituted or unsubstituted C3-C24 cycloalkyl, substituted or unsubstituted C6-C30 aryl, and substituted or unsubstituted C6-C30 heteroaryl, a heteroatom in the heteroaryl being selected from N, O and S, and a substituent therein being selected from deuterium, C1-C24 alkyl, C3-C24 cycloalkyl and C6-C30 aryl when substitution is contained.

According to a preferred embodiment, the boron-nitrogen compound has a structure represented by formula (I-1) or formula (I-2) as shown below:

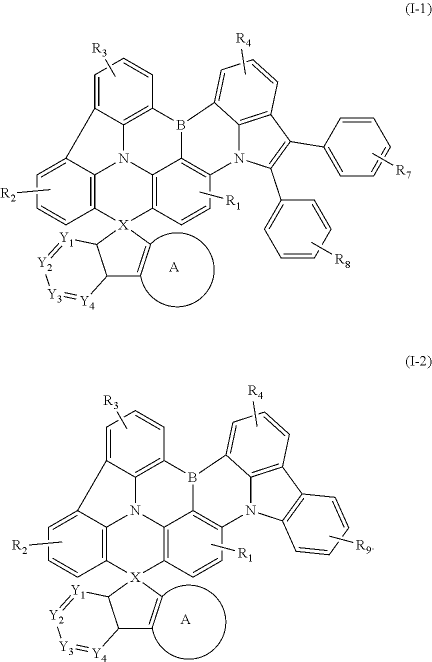

In formula (I-1) or formula (I-2), X, ring A, Y₁-Y₄ and R₁-R₄ have the same meanings as defined above in formula (I); each of R₇, R₈ and R₉ represents one or more substituents; and R₇, R₈ and R₉ are each independently selected from hydrogen, deuterium, C1-C24 alkyl and C3-C24 cycloalkyl.

According to a preferred embodiment, in formula (I-1), R₁ is hydrogen; one or more substituents represented by R₄ is identically or differently selected from hydrogen, deuterium, methyl, ethyl, propyl, butyl, tert-butyl, pentyl, tert-pentyl, hexyl and a benzene or naphthalene ring formed by fusion with an adjacent substituent; and one or more substituents represented by each of R₇ and R₈ are identically or differently selected from hydrogen, deuterium, methyl, ethyl, propyl, butyl, tert-butyl, pentyl, tert-pentyl, hexyl, heptyl, cyclohexane and adamantyl.

According to a preferred embodiment, in formula (I-2), R₁ is selected from substituted or unsubstituted C6-C18 aryl and substituted or unsubstituted tetrahydronaphthyl, a substituent therein being selected from hydrogen, deuterium, methyl, ethyl, propyl, butyl, tert-butyl, adamantyl and pyridyl when substitution is contained; and one or more substituents represented by R₄ and R₉ are identically or differently selected from hydrogen, deuterium, methyl, ethyl, propyl, butyl, tert-butyl, pentyl, tert-pentyl, hexyl, heptyl and adamantyl.

According to a preferred embodiment, at least one of R₄, R₇ or R₈ is fused with an adjacent group to form a ring.

According to a preferred embodiment, R₂ and R₃ in formula (I) are each independently selected from hydrogen, deuterium, methyl, ethyl, propyl, tert-butyl and tert-pentyl.

According to a preferred embodiment, ring A in formula (I), formula (I-1) or formula (I-2) is any one selected from phenyl, pyridyl, naphthyl and following ring structures:

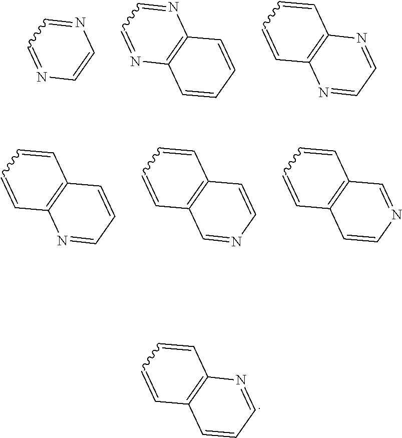

According to a more preferred embodiment, when Y₁-Y₄ in formula (I), formula (I-1) or formula (I-2) each are CR, ring A is any one selected from pyridyl and following ring structures:

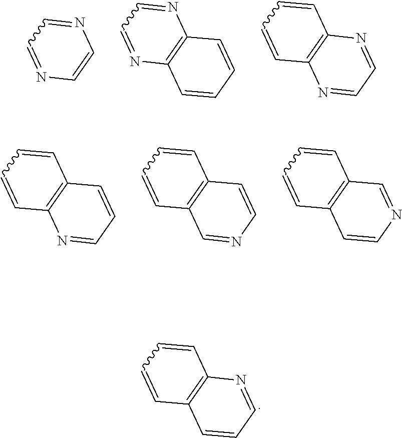

According to a more preferred embodiment, when at least one of Y₁-Y₄ in formula (I), formula (I-1) or formula (I-2) is N, ring A is selected from phenyl and naphthyl.

According to a preferred embodiment, each of one or more substituents represented by R in formula (I), formula (I-1) or formula (I-2) is independently selected from hydrogen, deuterium, methyl, ethyl, propyl, butyl, tert-butyl, pentyl, tert-pentyl, hexyl, heptyl, cyclohexane, substituted or unsubstituted phenyl and substituted or unsubstituted pyridyl; each of one or more substituents represented by each of R₂ and R₃ is independently selected from hydrogen, deuterium, methyl, ethyl, propyl, butyl, tert-butyl, pentyl, tert-pentyl, hexyl and heptyl.

According to one or more embodiments, R is fused with an adjacent substituent to form substituted or unsubstituted cyclopentane.

According to one or more embodiments, the present disclosure provides a specific boron-nitrogen compound selected from chemical structures shown below:

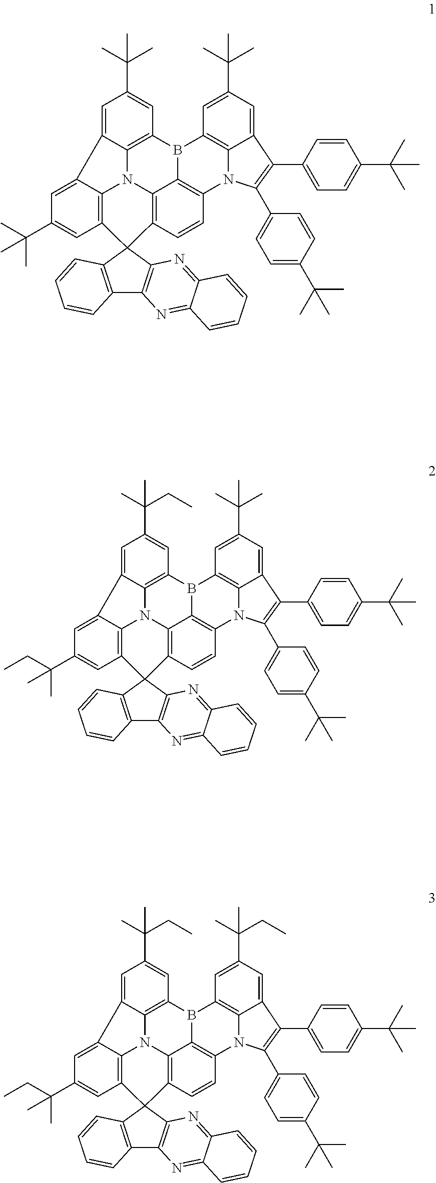

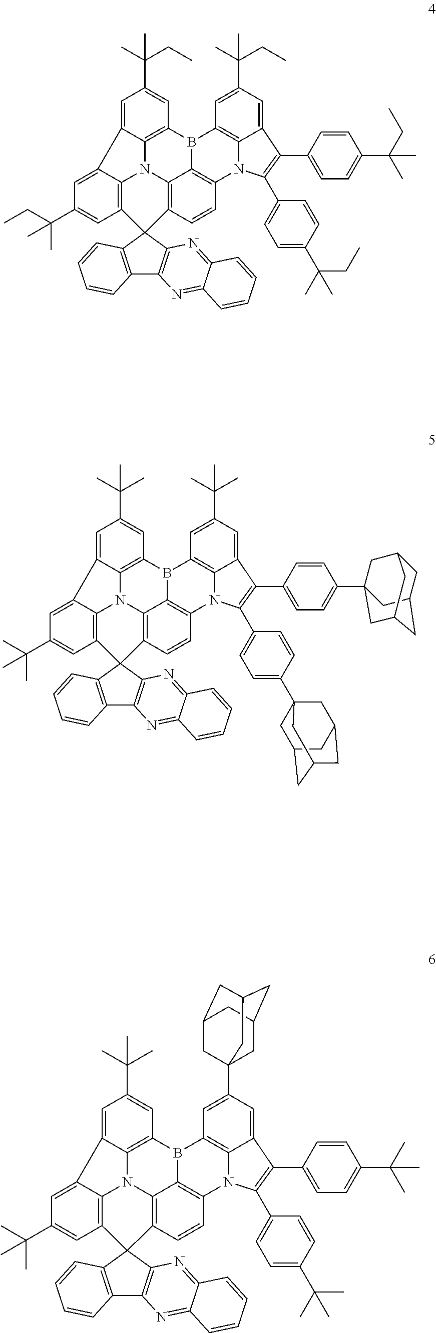

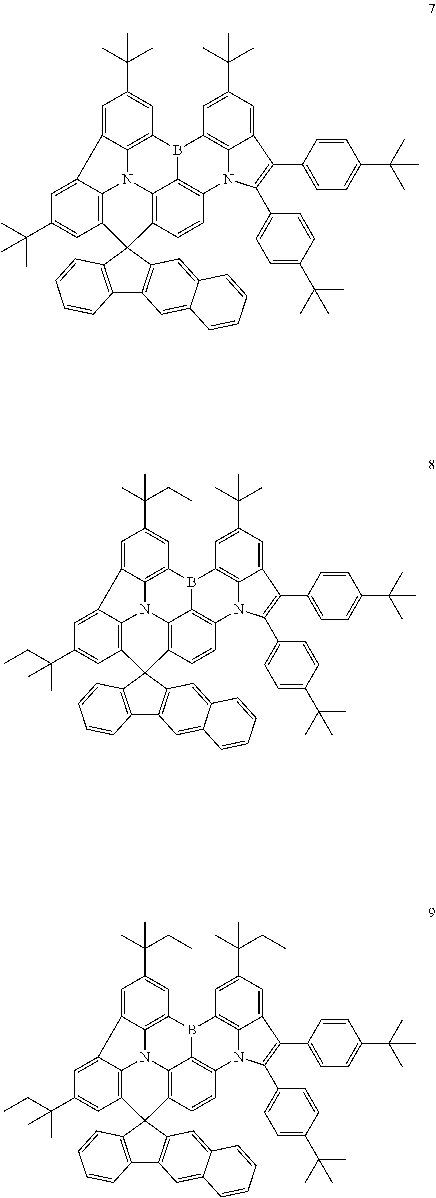

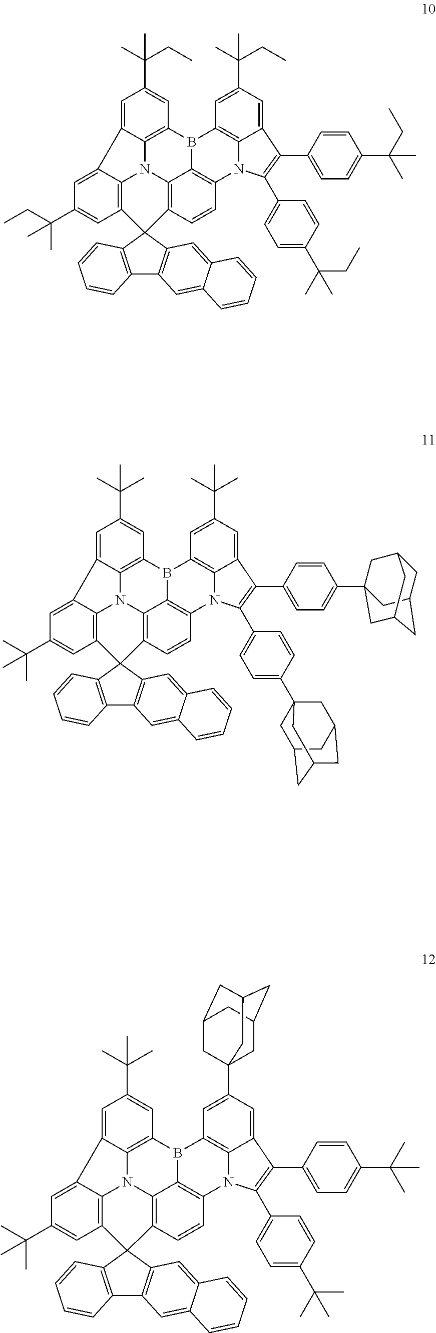

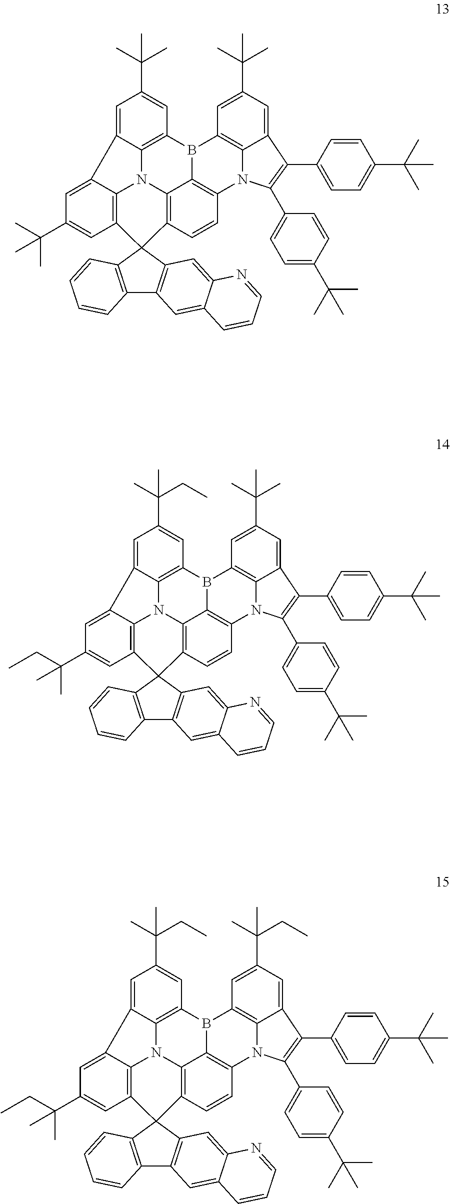

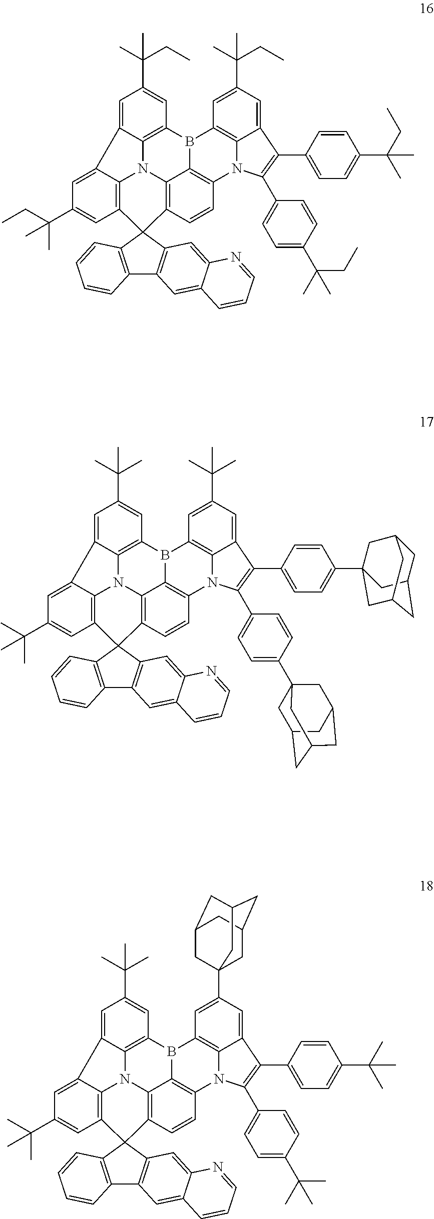

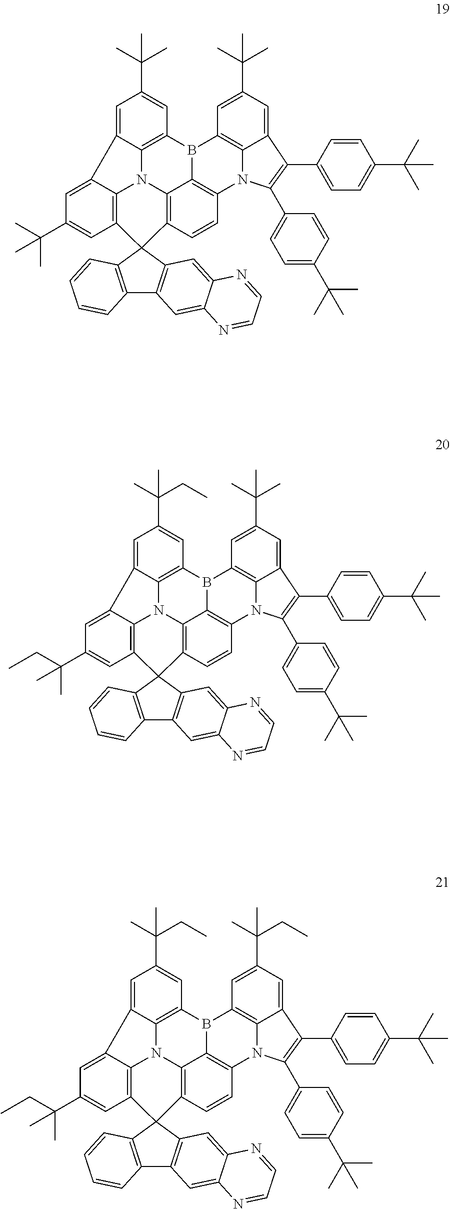

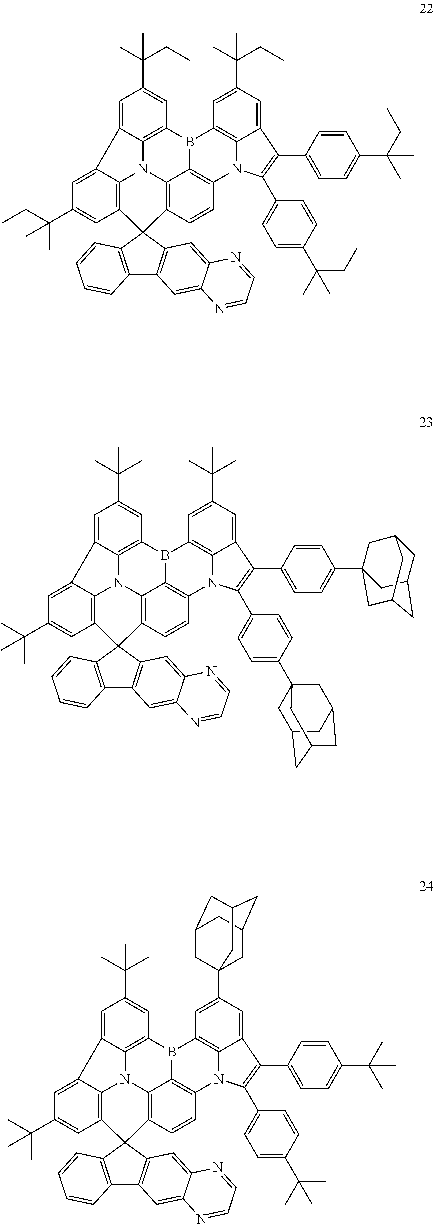

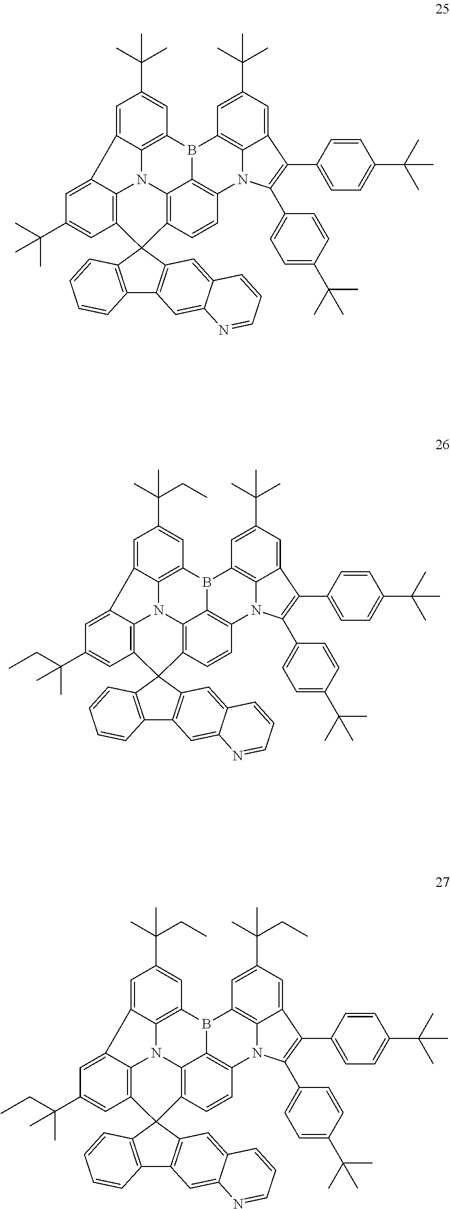

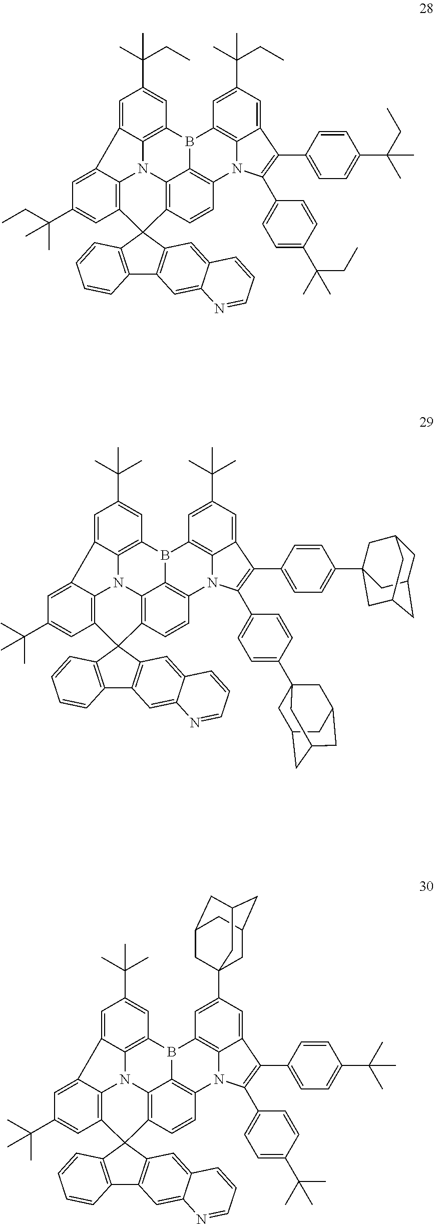

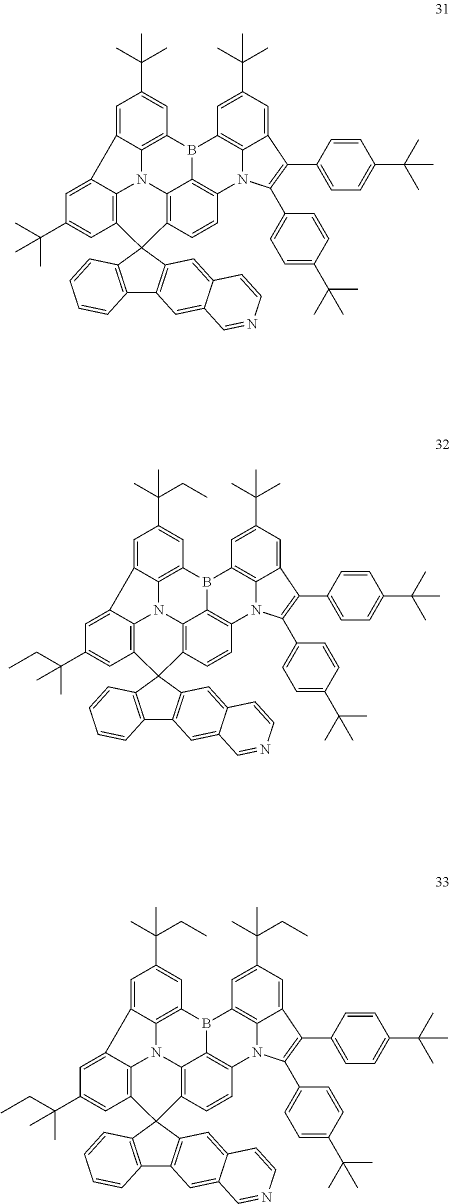

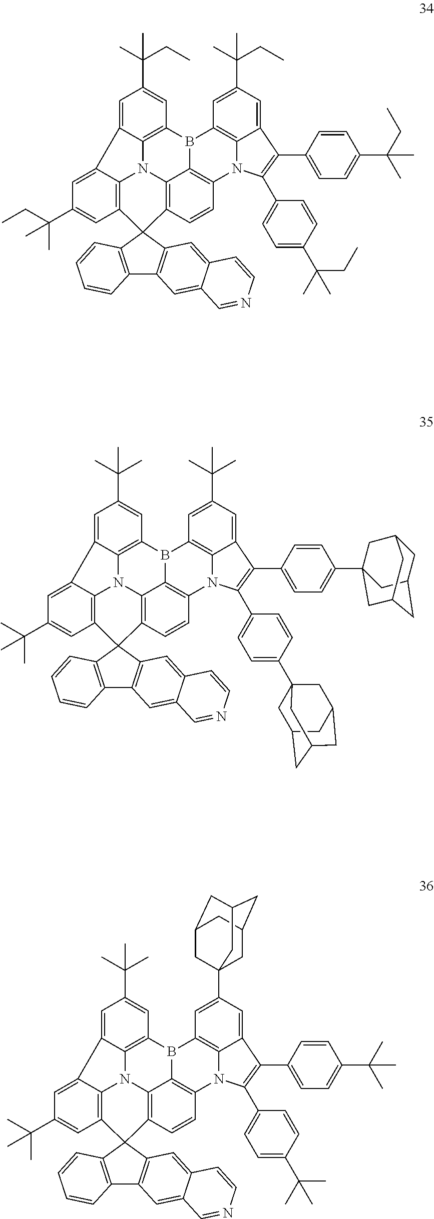

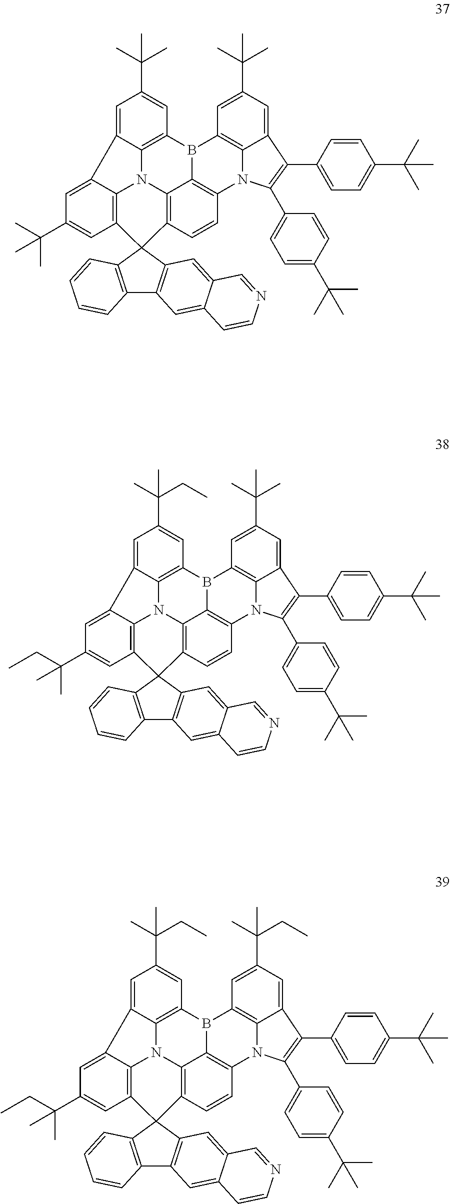

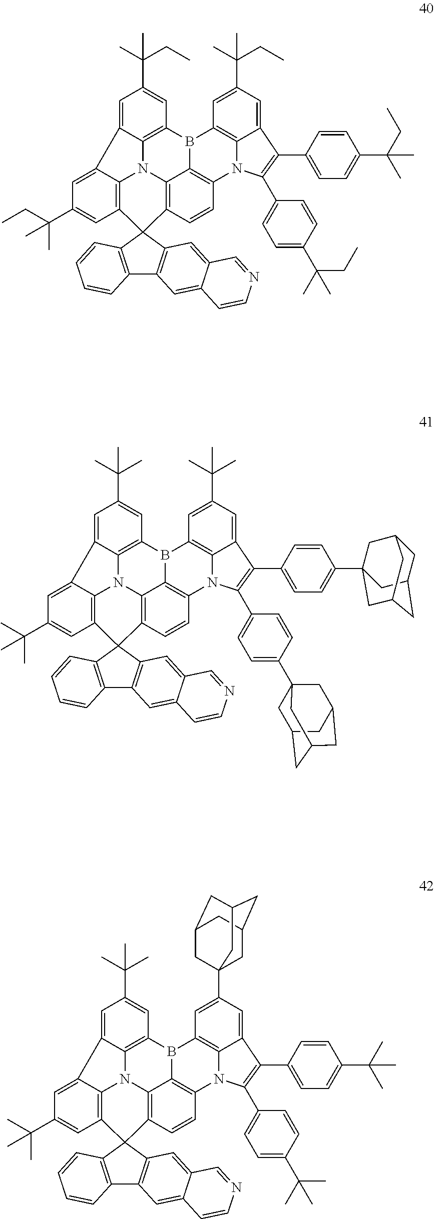

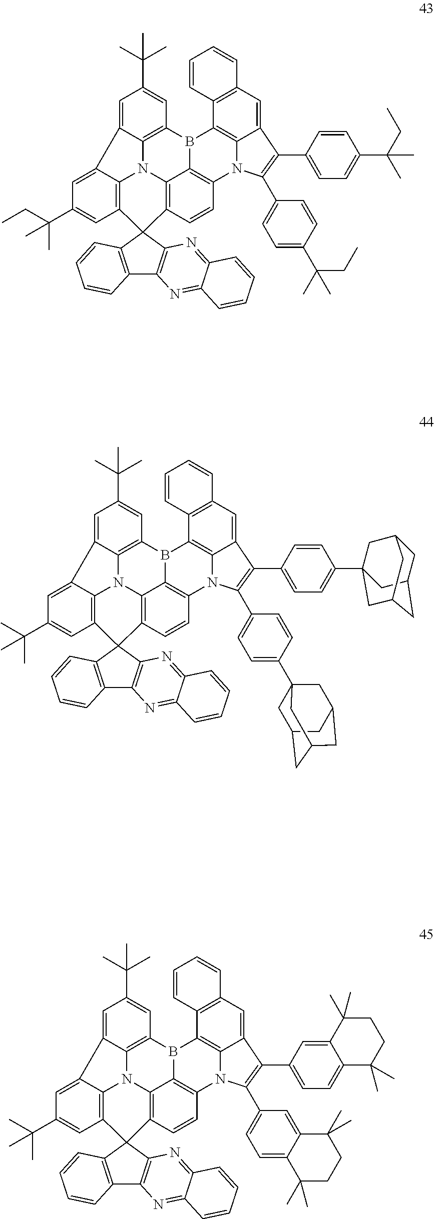

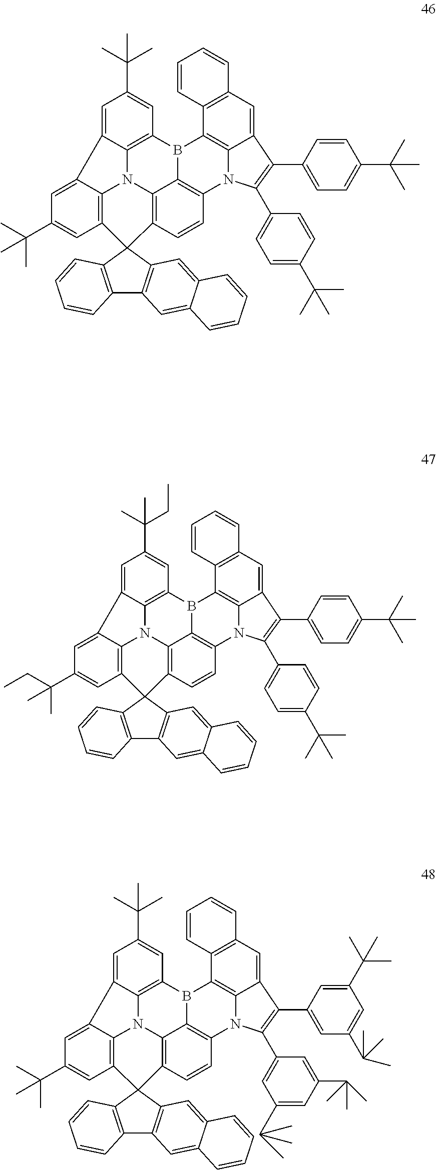

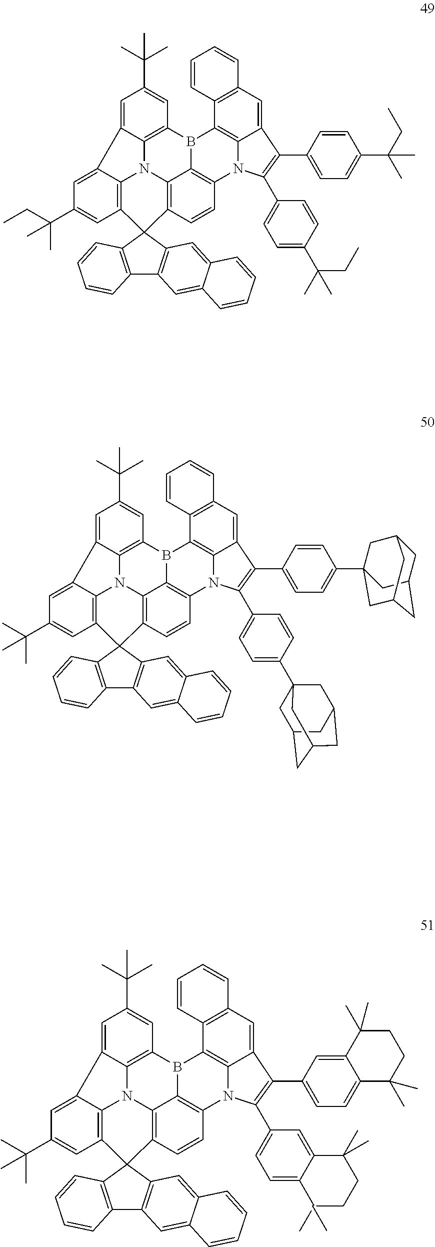

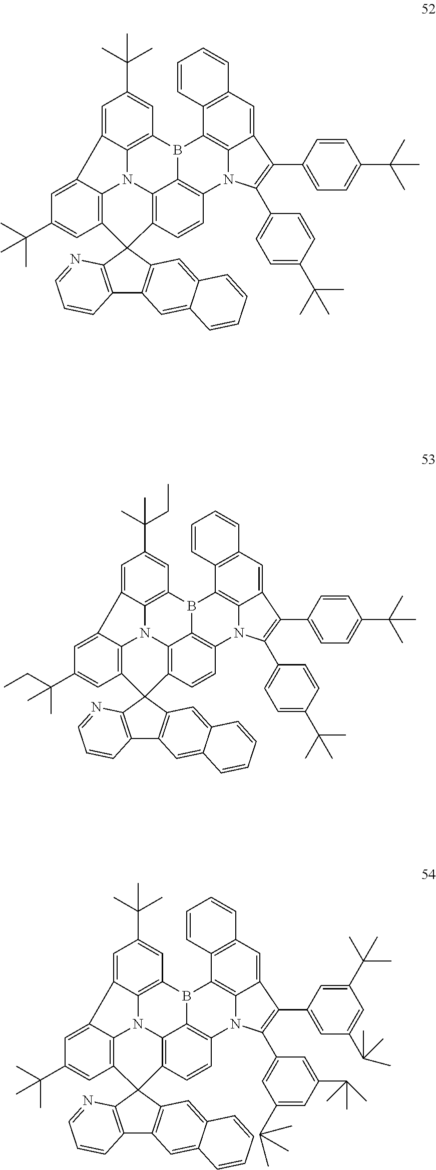

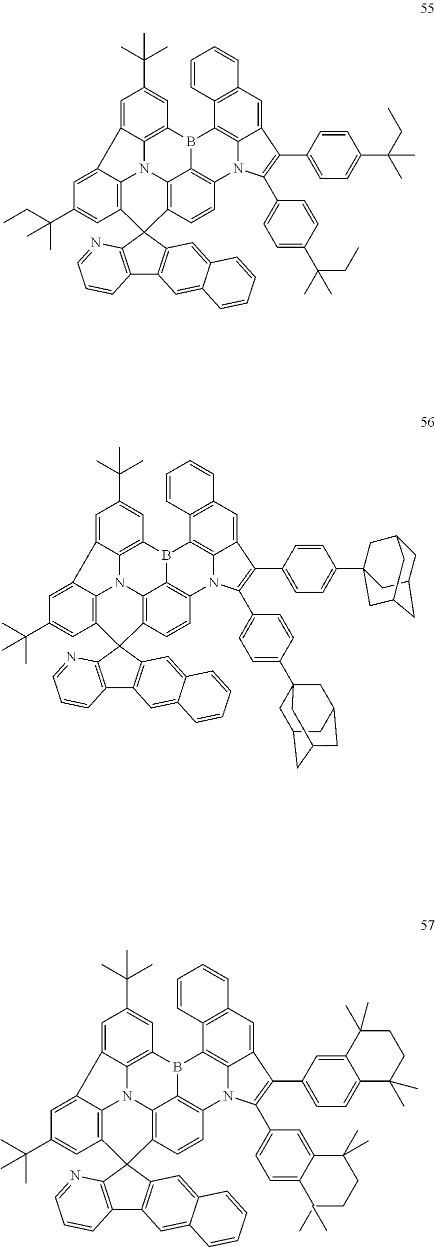

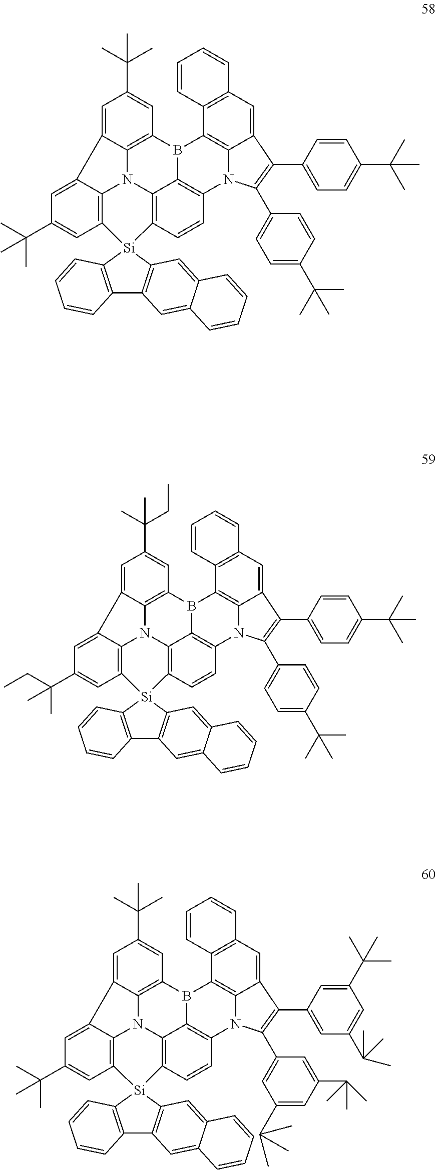

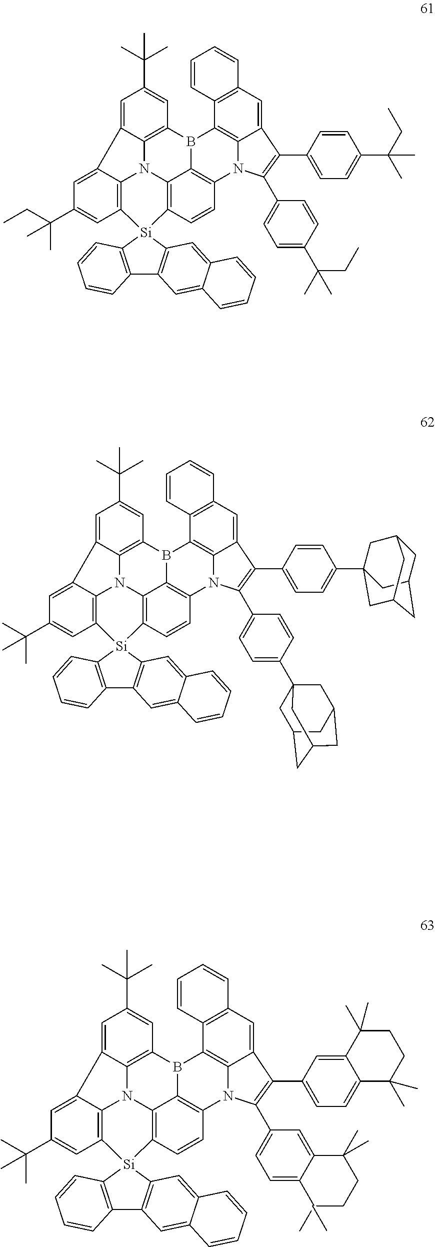

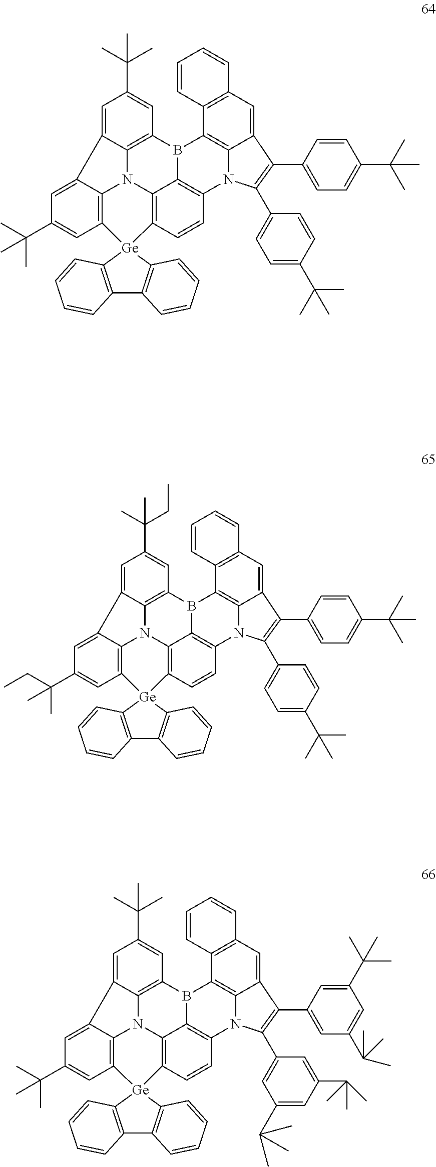

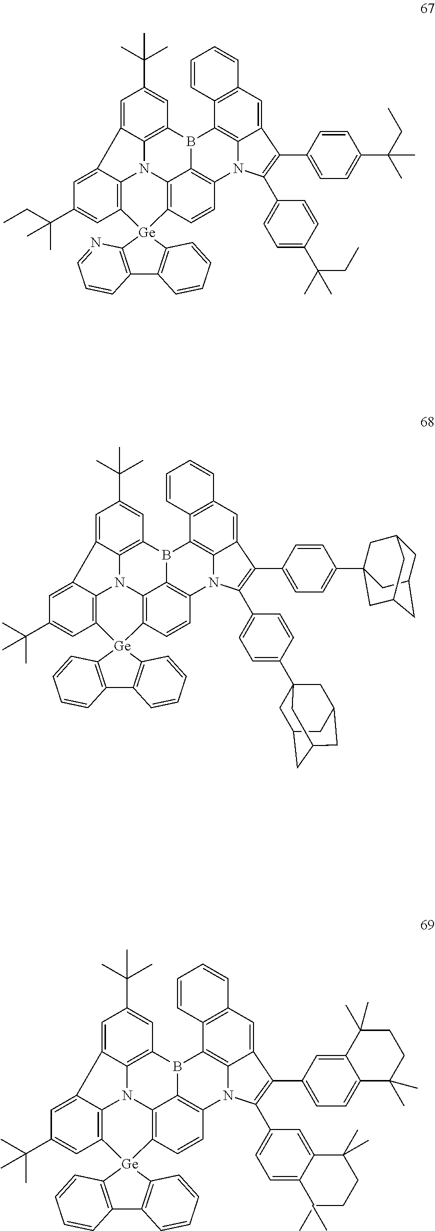

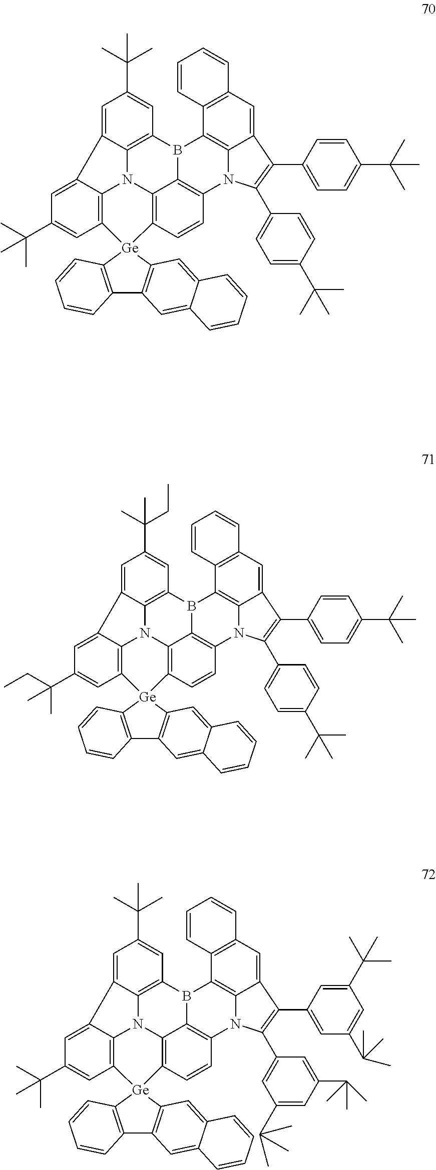

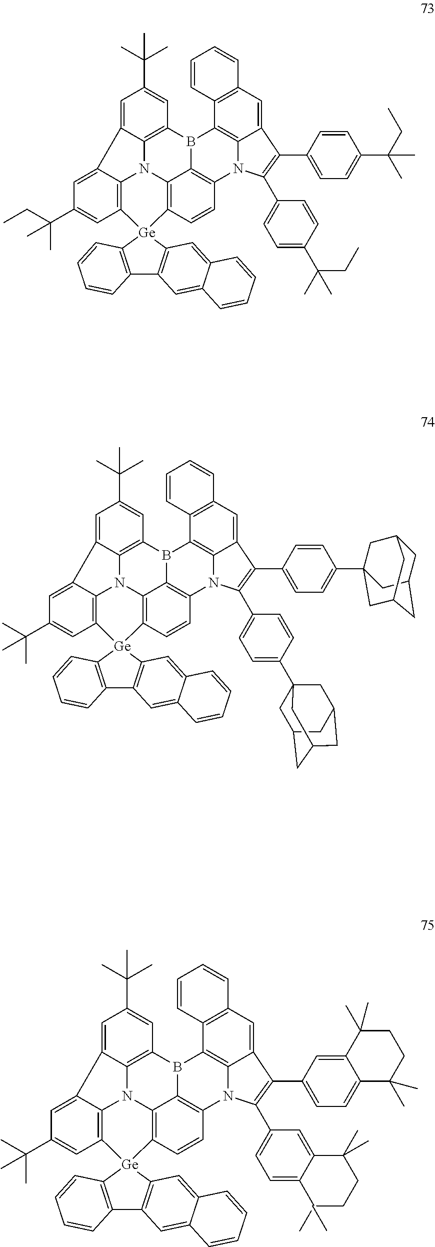

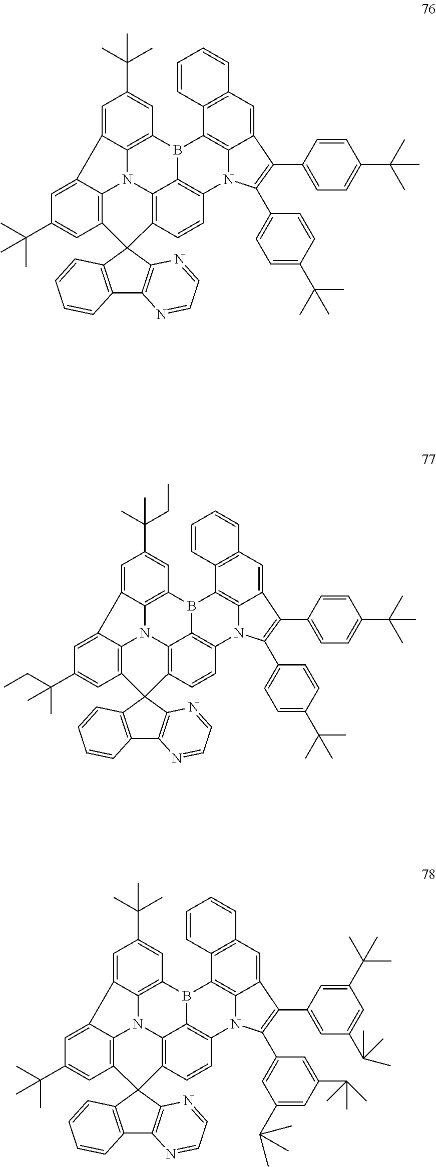

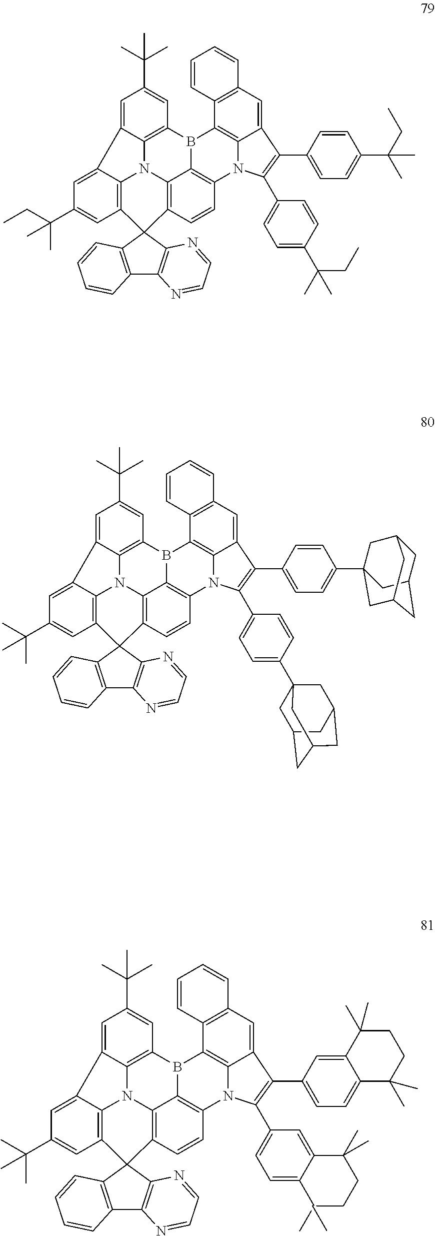

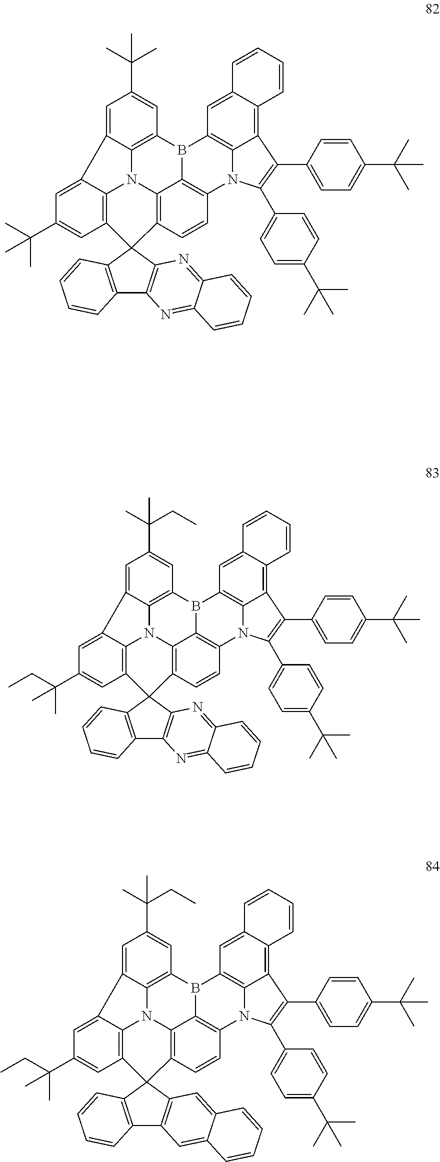

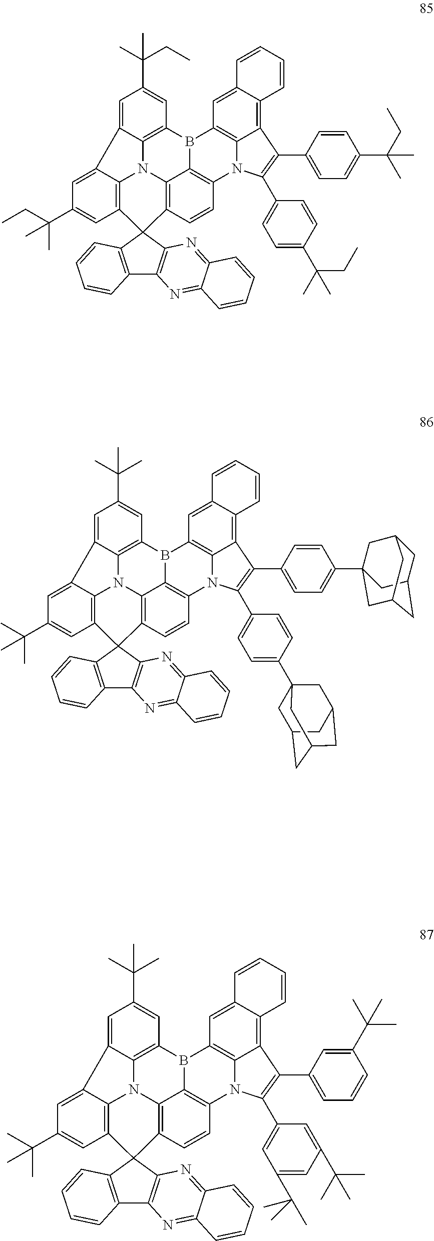

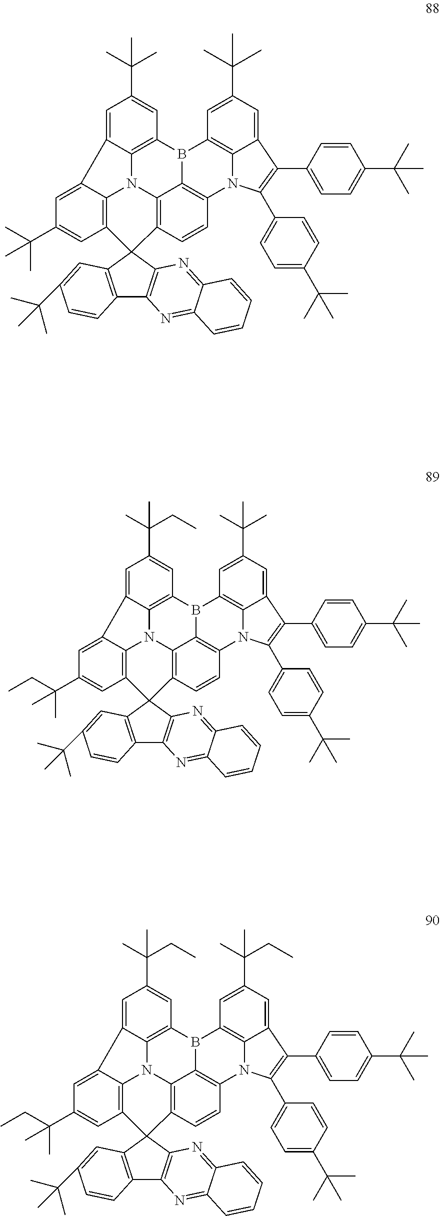

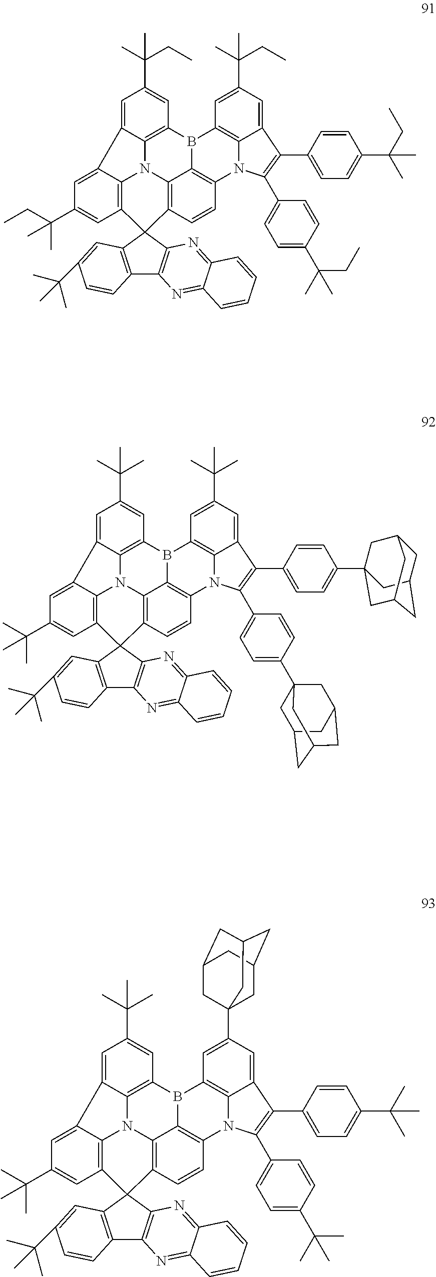

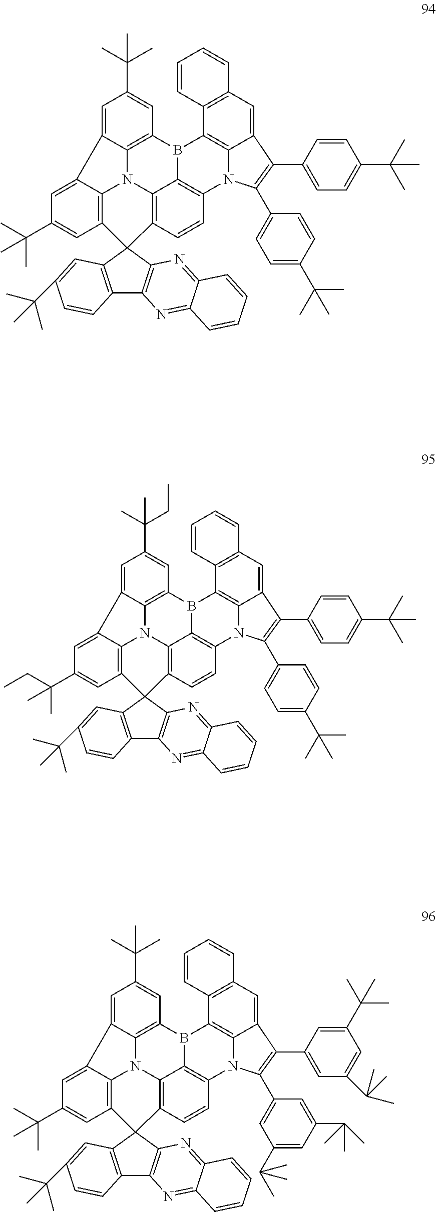

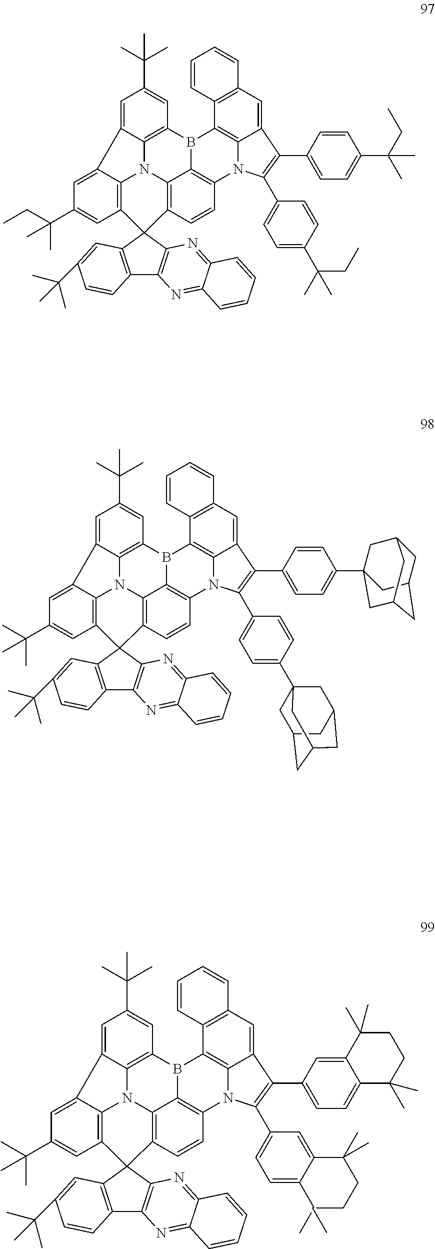

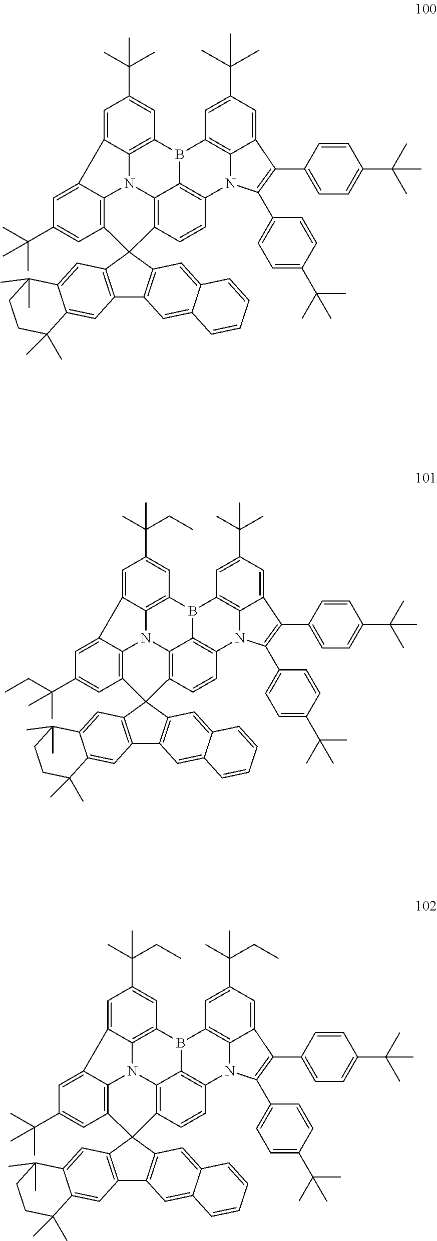

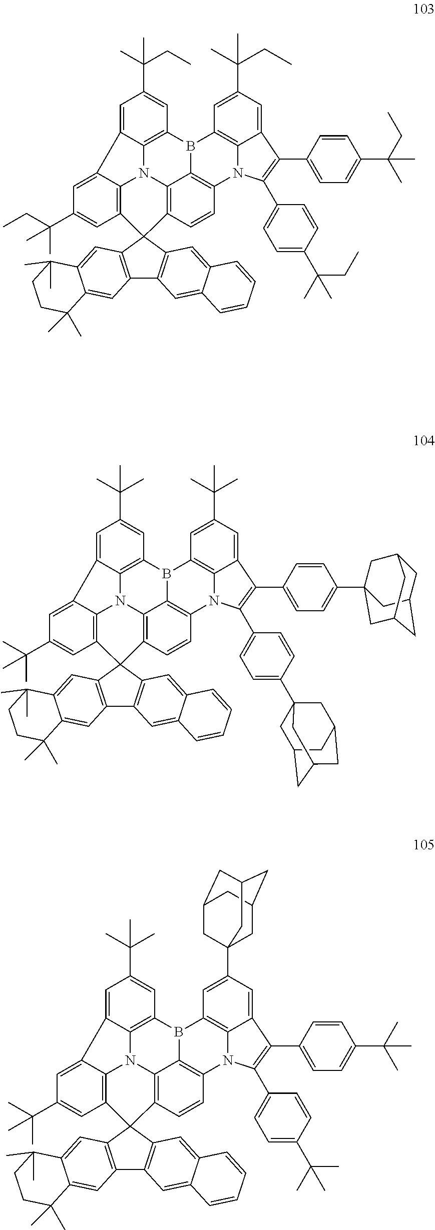

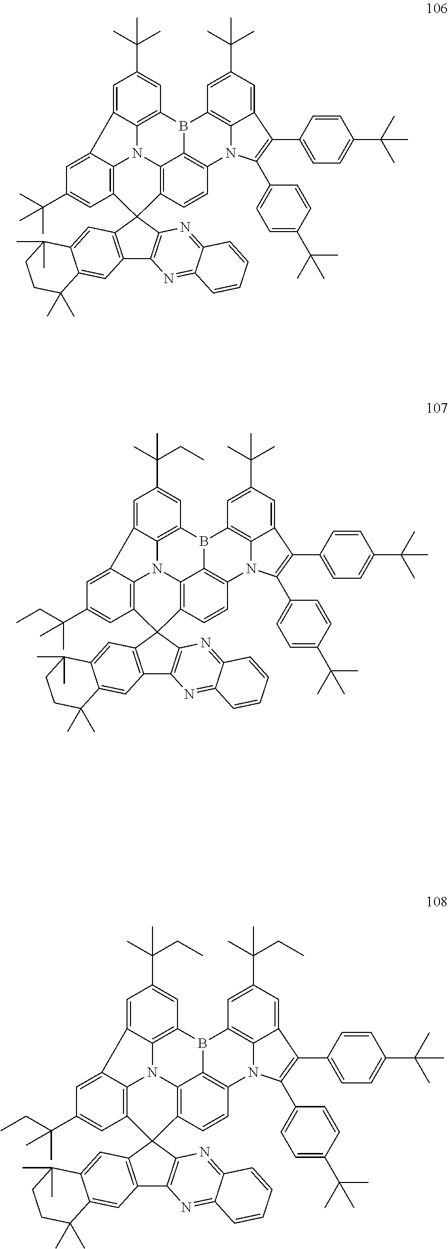

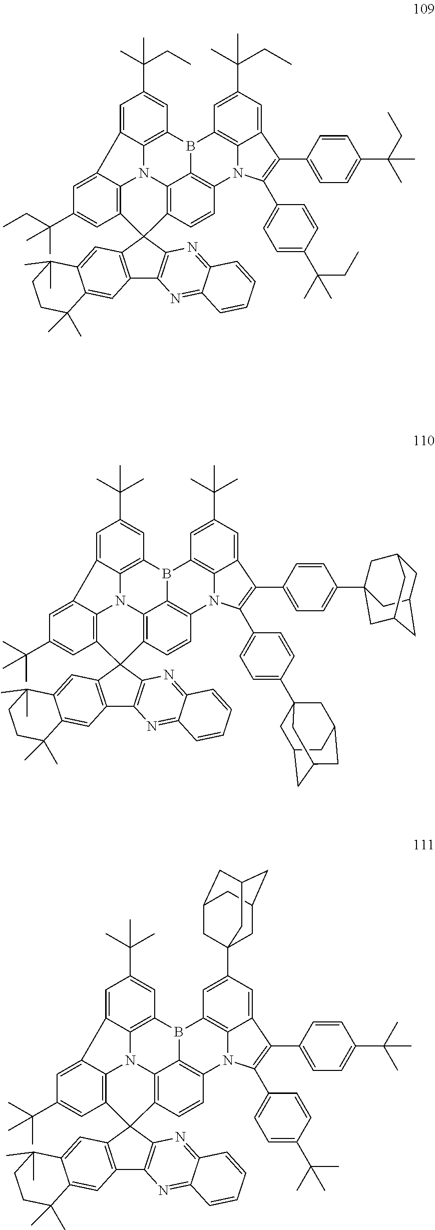

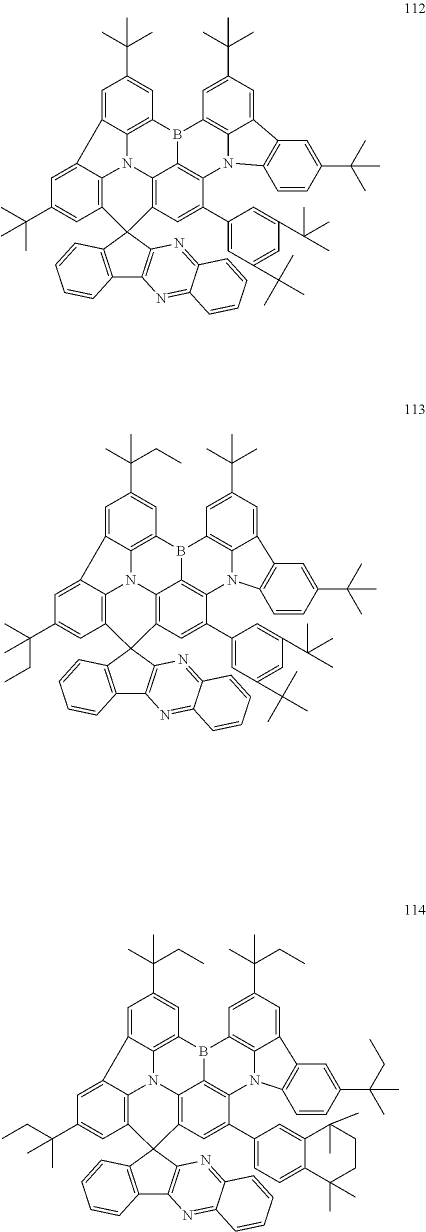

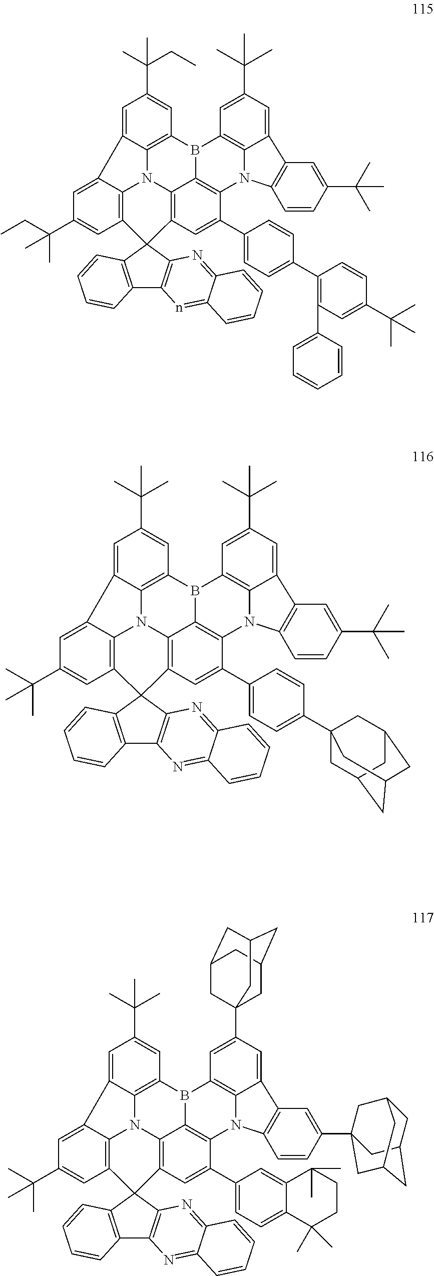

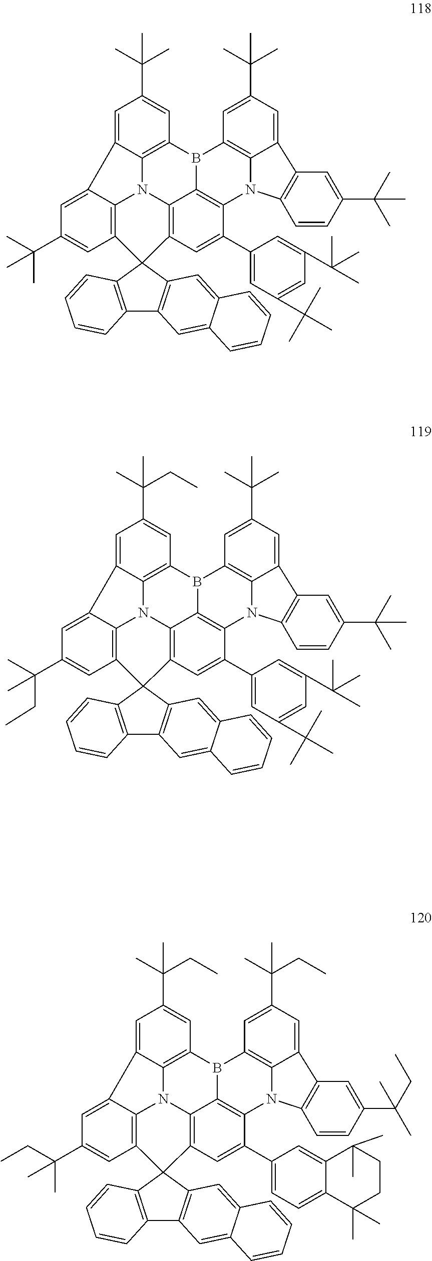

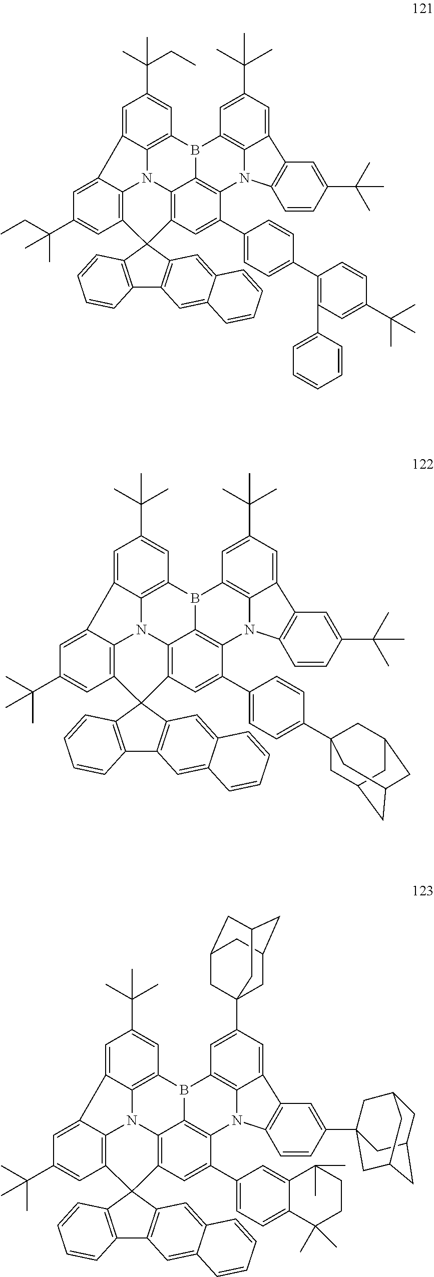

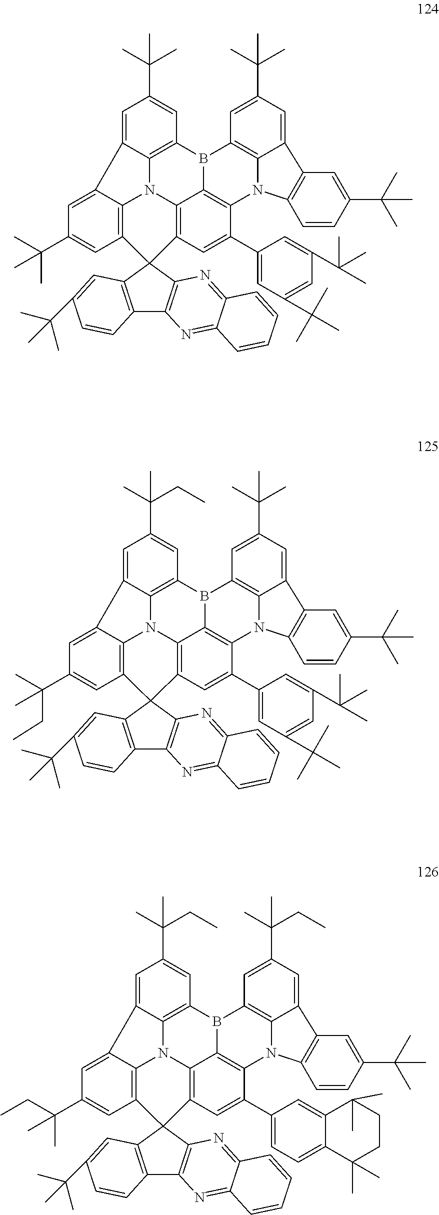

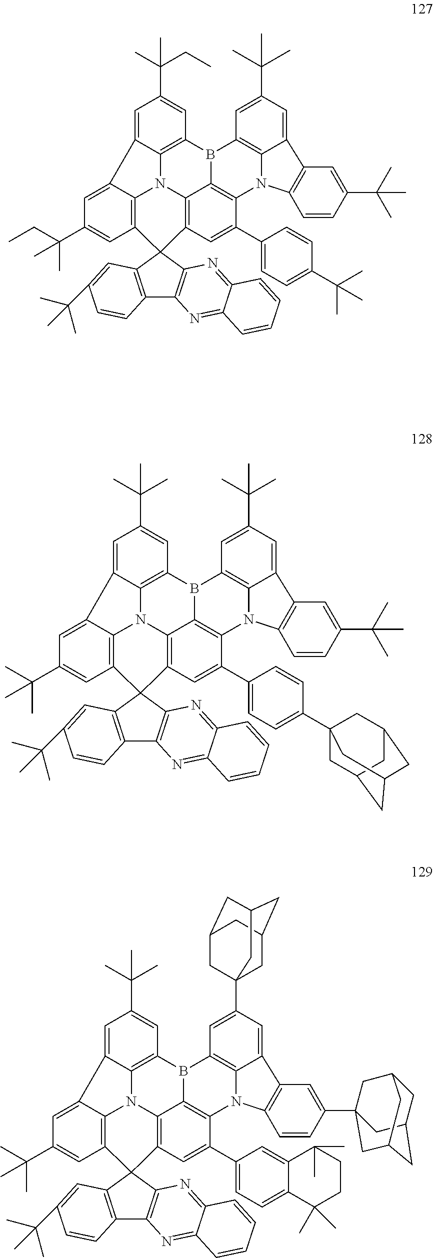

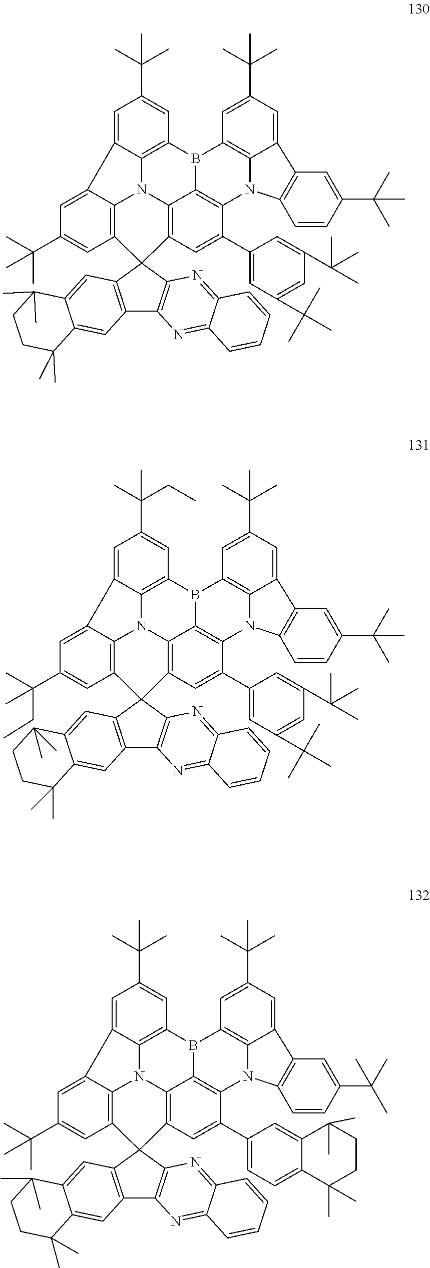

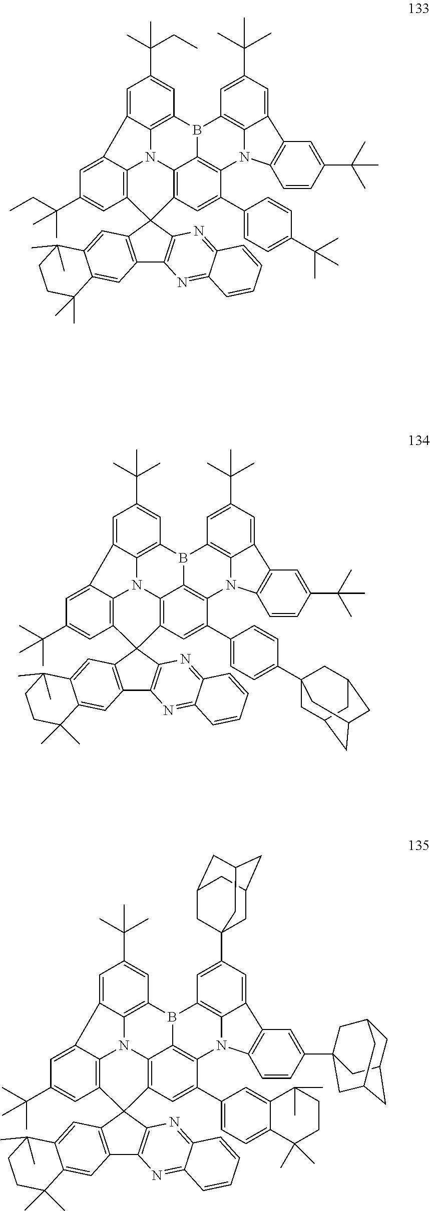

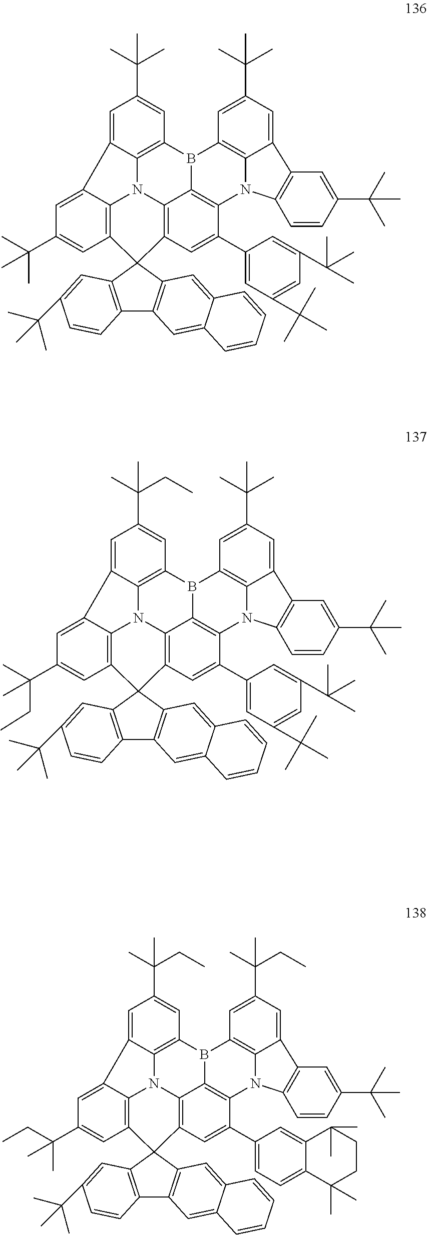

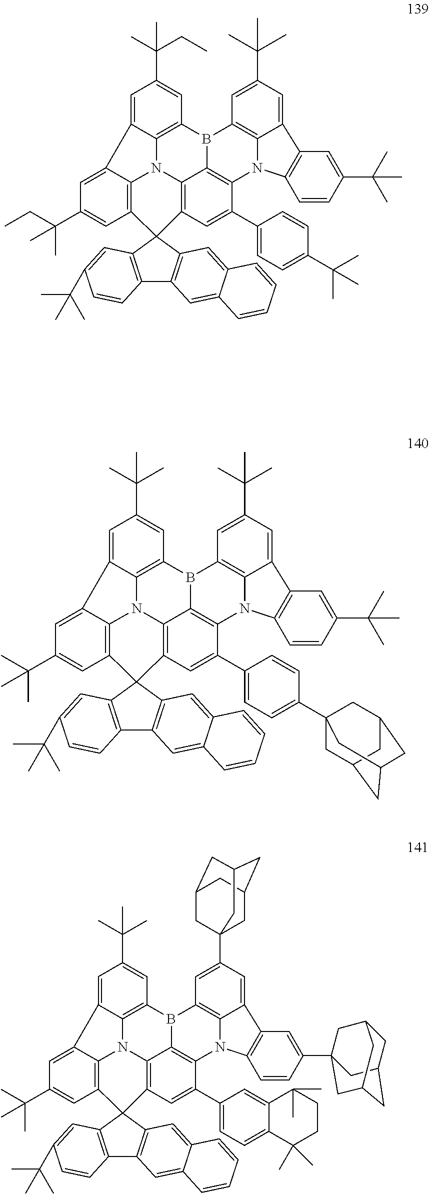

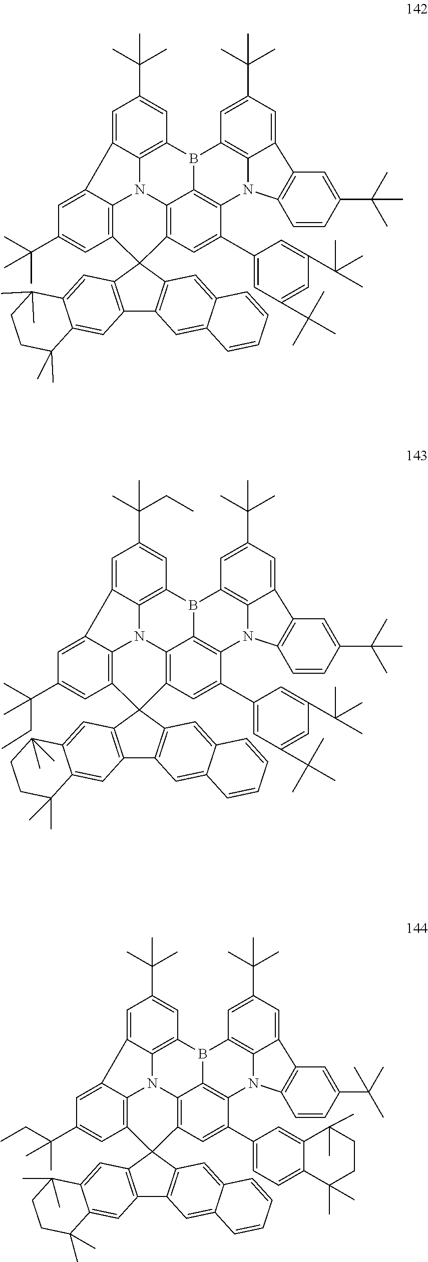

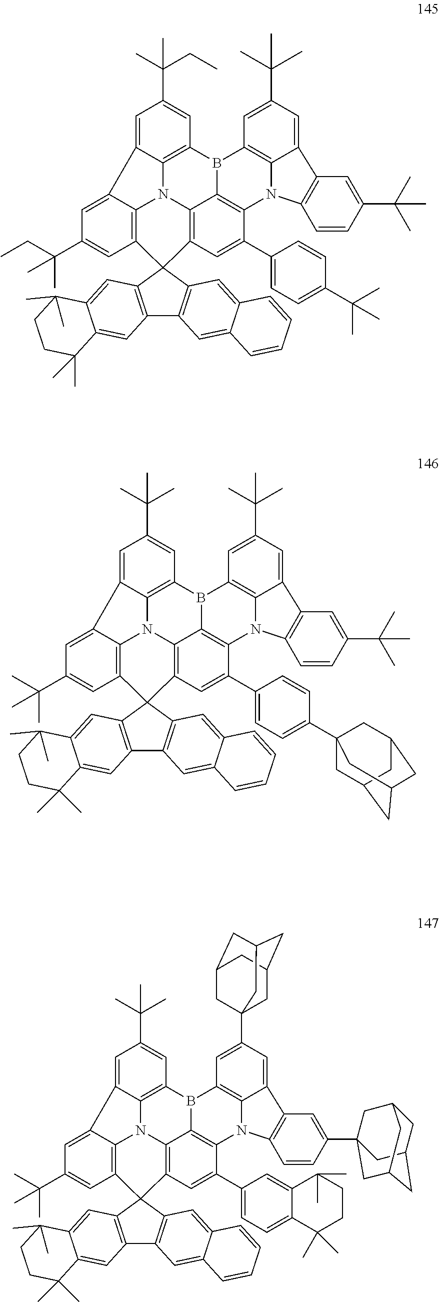

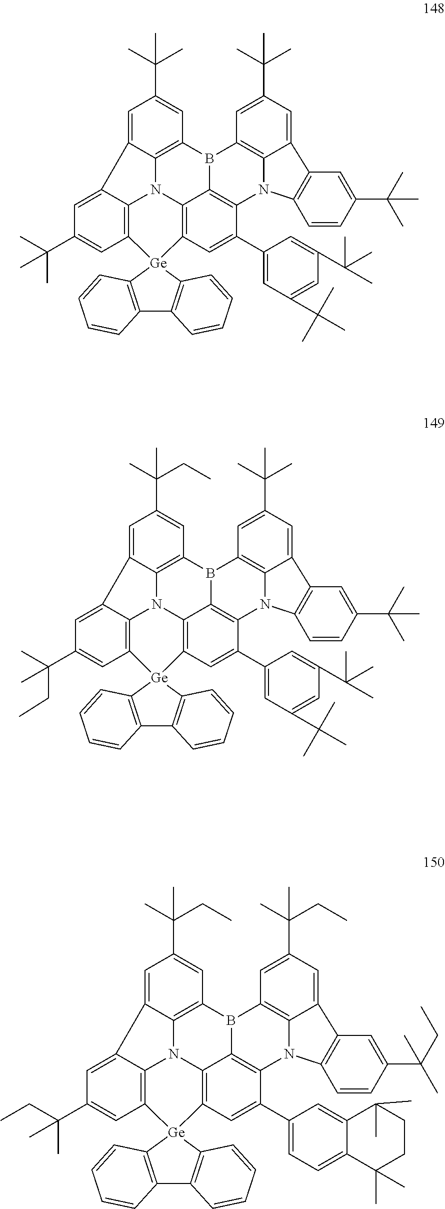

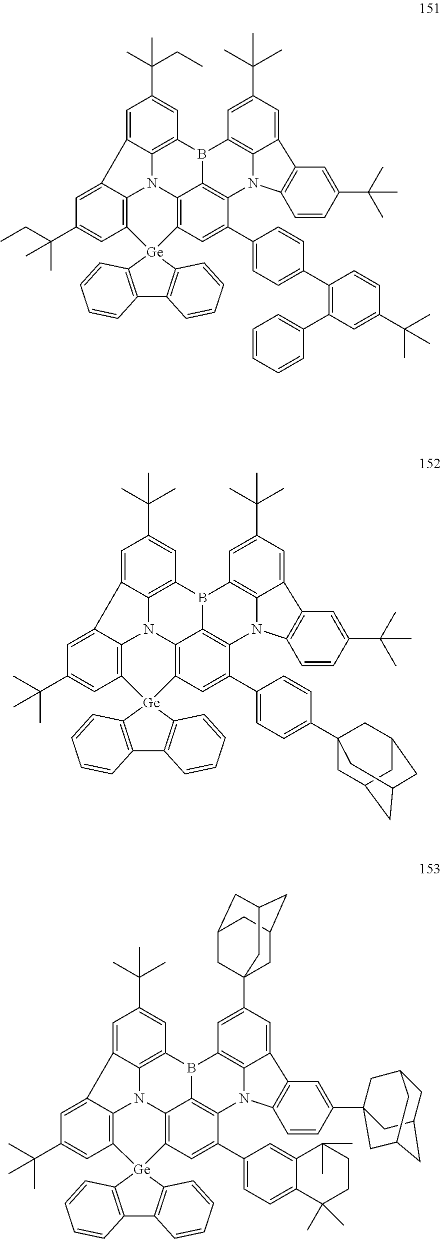

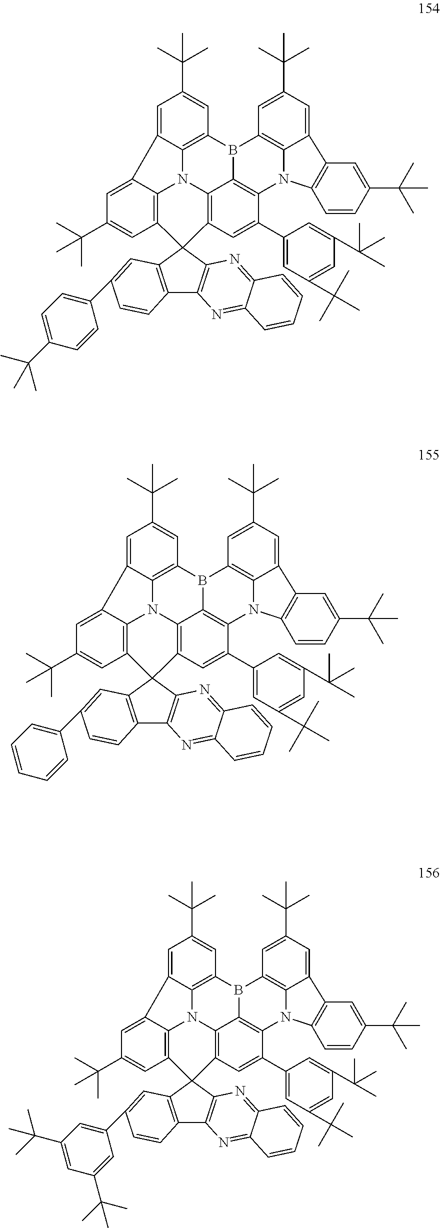

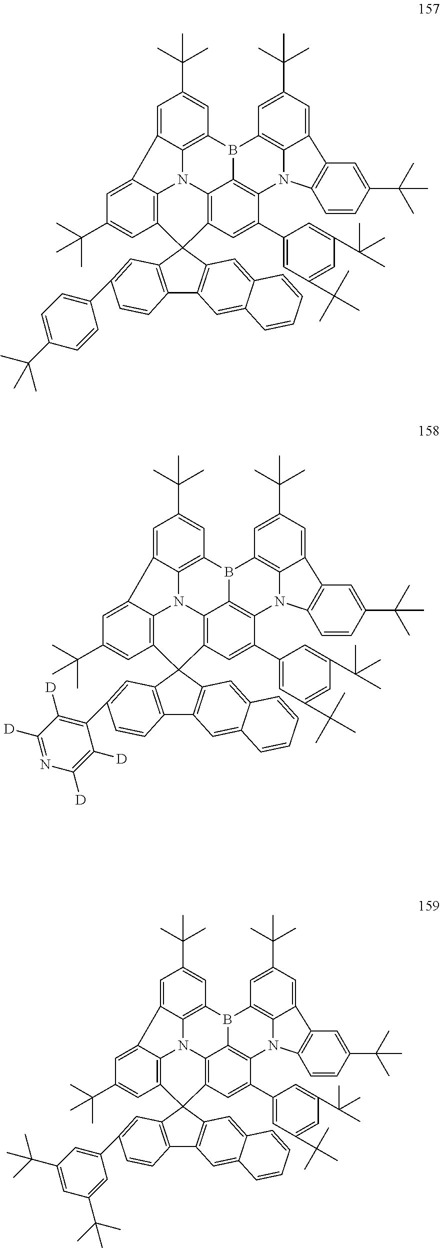

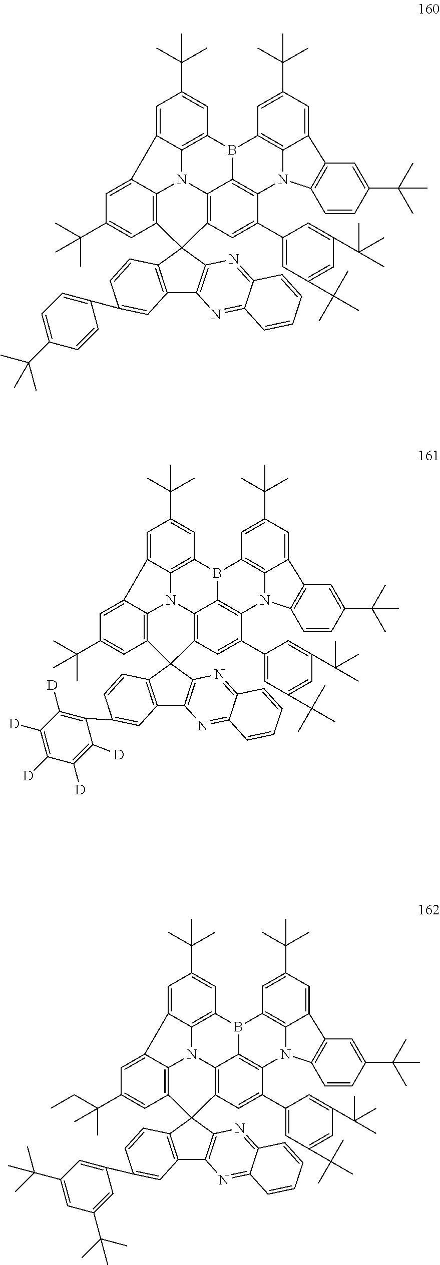

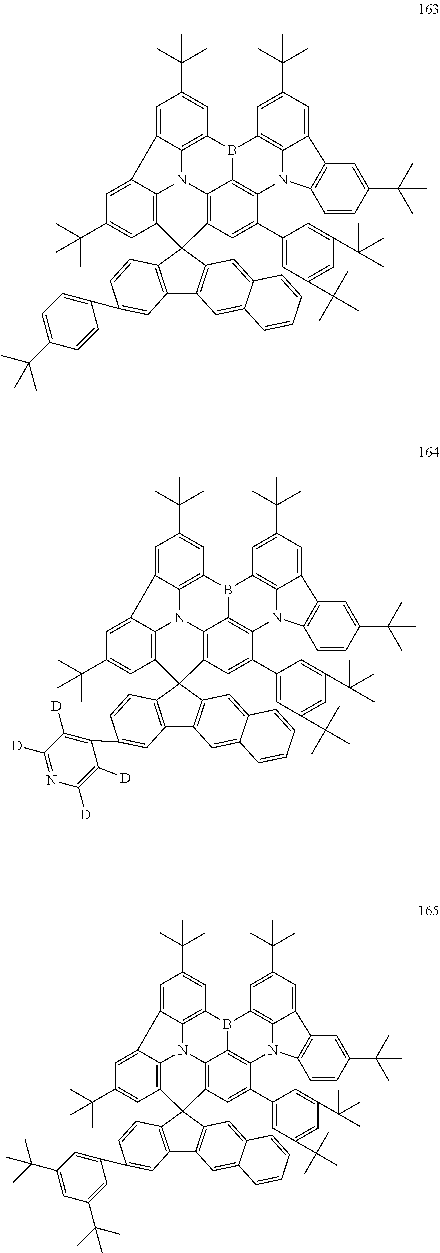

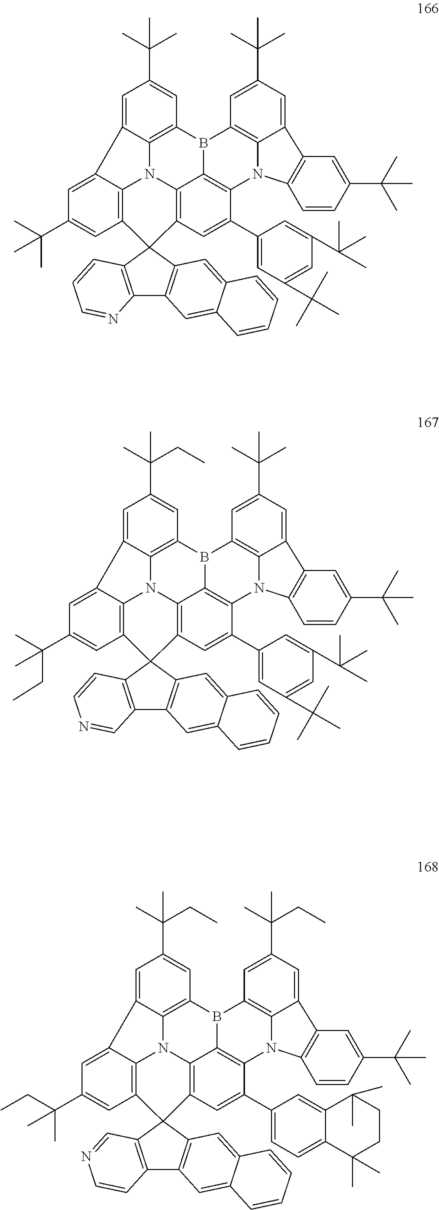

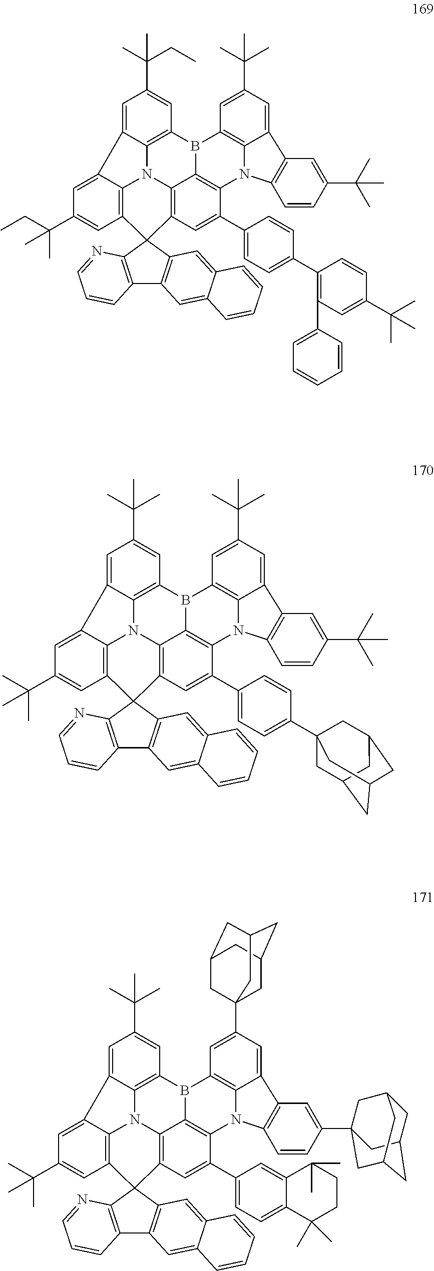

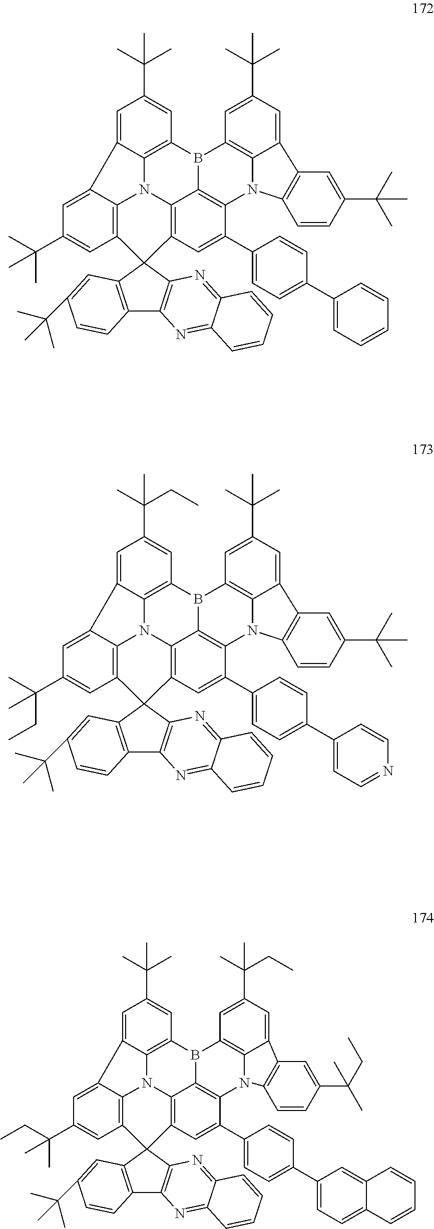

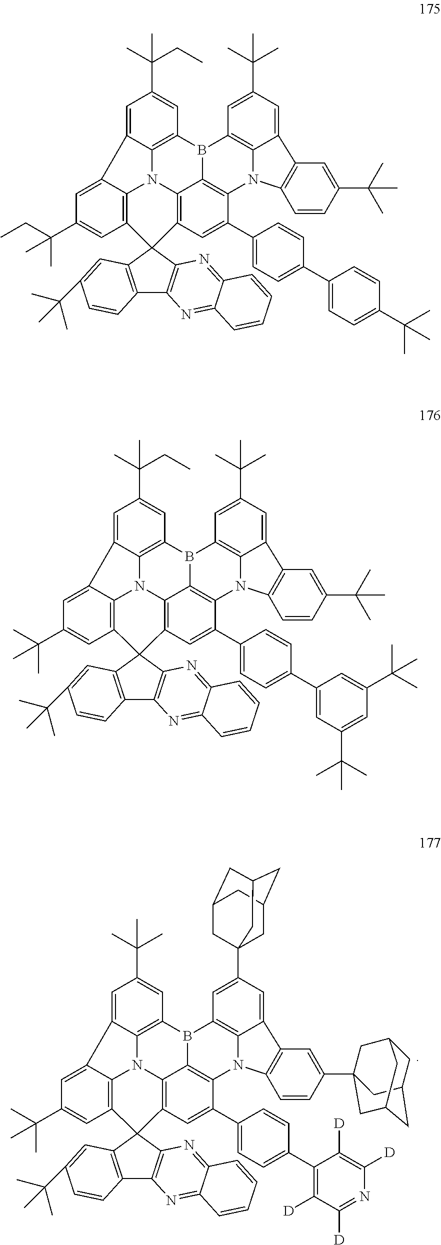

Here, D represents deuterium.

According to a preferred embodiment, at least one of R, R₄, R₅ or R₆ is connected with an adjacent substituent to form a ring.

In one aspect, the present disclosure further provides use of a boron-nitrogen compound of a general-formula structure represented by formula (I) as shown above in electronic devices.

Further, the electronic devices include organic electroluminescent devices (OLEDs), organic integrated circuits (O-ICs), organic field-effect transistors (O-FETs), organic thin-film transistors (O-TFTs), organic light-emitting transistors (O-LETs), organic solar cells (O-SCs), organic photoelectric devices, organic optical detectors, organic photoreceptors, organic field-quenching devices (O-FQDs), light-emitting electrochemical cells (LECs), and organic laser diodes (O-laser).

In another aspect, the present disclosure further provides an organic electroluminescent device comprising the boron-nitrogen compound of the general-formula structure represented by formula (I) as shown above.

Further, the organic electroluminescent device comprises a cathode, an anode and an organic functional layer therebetween; and the organic functional layer comprises an emissive layer, and the emissive layer comprises the boron-nitrogen compound of the general-formula structure represented by formula (I) as shown above. The boron-nitrogen compound accounts for 0.1%-50% by mass.

In another aspect, the present disclosure further provides an organic photoelectric device comprising a first electrode, a second electrode facing the first electrode and a light-emitting material layer arranged between the first electrode and the second electrode. The light-emitting material layer comprises the boron-nitrogen compound of the general-formula structure represented by formula (I) as shown above. For example, the boron-nitrogen compound may be contained as a dopant in the light-emitting material layer.

The present disclosure further provides a composition comprising the boron-nitrogen compound of the general-formula structure represented by formula (I) as shown above.

The present disclosure further provides a formulation comprising either the boron-nitrogen compound of the general-formula structure represented by formula (I) as shown above or the composition described above, and at least one solvent. The solvent is not particularly limited, and for example, an unsaturated hydrocarbon solvent, a halogenated saturated hydrocarbon solvent, a halogenated unsaturated hydrocarbon solvent, an ether solvent, or an ester solvent that is well known to those skilled in the art may be used, wherein the unsaturated hydrocarbon solvent is toluene, xylene, mesitylene, tetrahydronaphthalene, n-butylbenzene, sec-butylbenzene, or tert-butylbenzene; the halogenated saturated hydrocarbon solvent is carbon tetrachloride, chloroform, dichloromethane, dichloroethane, chlorobutane, bromobutane, chloropentane, bromopentane, chlorohexane, bromohexane, chlorocyclohexane, or bromocyclohexane; the halogenated unsaturated hydrocarbon solvent is chlorobenzene, dichlorobenzene or trichlorobenzene; the ether solvent is tetrahydrofuran or tetrahydropyran; the ester solvent is alkyl benzoate.

The present disclosure further provides a display or lighting apparatus comprising one or more of the organic electroluminescent device or the organic photoelectric device described above.

### Compared to the Prior Art, the Present Disclosure has the Following Beneficial Effects.

The present disclosure provides a boron-nitrogen compound having a good ability to accept electrons and holes. By introducing groups with large steric hindrance such as azafluorene/benzofluorene/azabenzofluorene/silafluorene/germafluorene, the interactions between luminescent molecules can be effectively inhibited. Structures such as the large conjugated spiro-ring structural unit and the sp² aza-aromatic rings enable the compound to have improved energy transmission performance between the host and the guest (or the sensitizer). Specifically, after the boron-nitrogen compound of the present disclosure is used as a functional layer, particularly as the emissive layer, in a manufactured organic electroluminescent device, there is a relatively good improvement in current efficiency and a relatively big improvement in the lifespan of the device. This indicates that after most electrons recombine with holes, energy is effectively transferred to the boron-nitrogen compound, resulting in high luminous efficiency.

### DETAILED DESCRIPTION

The present disclosure is described in detail below. The following descriptions of the constituent elements are sometimes formed based on representative embodiments or specific examples of the present disclosure; however, the present disclosure is not limited to such embodiments or specific examples. The present disclosure can be more easily understood by reference to the following specific embodiments and the examples included therein. Before the disclosure and description of the compounds, devices, and/or methods of the present disclosure, it should be understood that they are not limited to specific synthesis methods or specific reagents unless otherwise specified, as such may vary. It should also be understood that the terms used in the present disclosure are for the purpose of describing particular aspects only and are not intended to be limiting. Although any similar or equivalent method and material described in the present disclosure can be used in the practice or experiments, exemplary methods and materials are now described.

As used herein, “alkyl” refers to a monovalent alkyl group having 1-24 carbon atoms, preferably 1-14 carbon atoms, and more preferably 1-6 carbon atoms. Examples of the term include: methyl, ethyl, n-propyl, isopropyl, n-butyl, isobutyl, tert-butyl, n-hexyl, etc.

As used herein, “cycloalkyl” refers to a cyclic alkyl group having 3-24 carbon atoms, preferably 3-14 carbon atoms, and a single ring or multiple rings that are fused, and it may be optionally substituted with 1-3 alkyl groups. Such cycloalkyl groups include, for example, those of a monocyclic structure such as cyclopropyl, cyclobutyl, cyclopentyl, cyclohexane, cyclooctyl, 1-methylcyclopropyl, 2-methylcyclopentyl, 2-methylcyclooctyl, and methylcyclohexane, or those of a polycyclic structure such as adamantyl.

As used herein, “aryl” refers to an unsaturated aromatic carbocycle having 6-30 carbon atoms, preferably 6-18 carbon atoms, and more preferably 1-12 carbon atoms, and a single ring (e.g., phenyl) or multiple rings that are fused (e.g., naphthyl or anthryl). Preferred aryl groups include phenyl, biphenyl, naphthyl, phenanthryl, terphenyl, etc. Unless otherwise defined for individual substituents, such aryl groups may be optionally substituted with 1-3 of the following substituents: hydroxyl, acyl, acyloxy, alkyl, alkoxy, alkenyl, alkynyl, amino, aminoacyl, aryl, aryloxy, carboxyl, carboxyl esters, aminocarboxyl esters, cyano, halogen, nitro, heteroaryl, heterocycles, thioalkoxy, trihalomethyl, etc. Preferred substituents include, but are not limited to, alkyl, alkoxy, halogen, cyano, nitro, trihalomethyl, and thioalkoxy.

As used herein, “heteroaryl” is a collective term for groups having 6-30 carbon atoms, preferably 6-18 carbon atoms, obtained by replacing one or more aromatic core carbon atoms in aryl with heteroatoms including, but not limited to, the oxygen (O), sulfur (S) or nitrogen (N), silicon (Si), or germanium (Ge) atom. The heteroaryl may be a monocyclic heteroaryl group or a fused-ring heteroaryl group, and examples may include, but are not limited to, pyridyl, pyrrolyl, pyridyl, thienyl, furyl, indolyl, quinolyl, isoquinolyl, benzothienyl, benzofuryl, dibenzofuryl, dibenzothienyl, carbazolyl, etc.

The substitution in the present disclosure may be by a single bond or by fusion.

As used in the specification and the appended claims, the singular forms “a”, “an”, and “the” include plural referents, unless the context clearly dictates otherwise. Thus, for example, reference to “a component” includes mixtures of two or more components.

Unless otherwise specified, all commercial reagents referred to in the following experiments were purchased and then used directly.

In a preferred embodiment of the present disclosure, the OLED device of the present disclosure comprises a hole transport layer, and the hole transport material may be preferably selected from known and unknown materials and may be particularly preferably selected from the following structures; however, this does not mean that the present disclosure is limited to the following structures (Ph is phenyl):

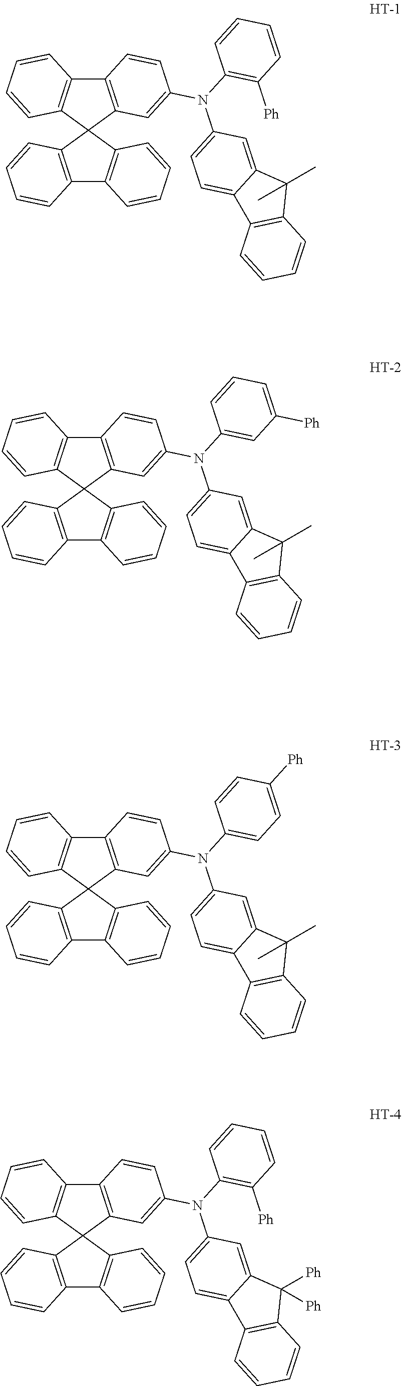

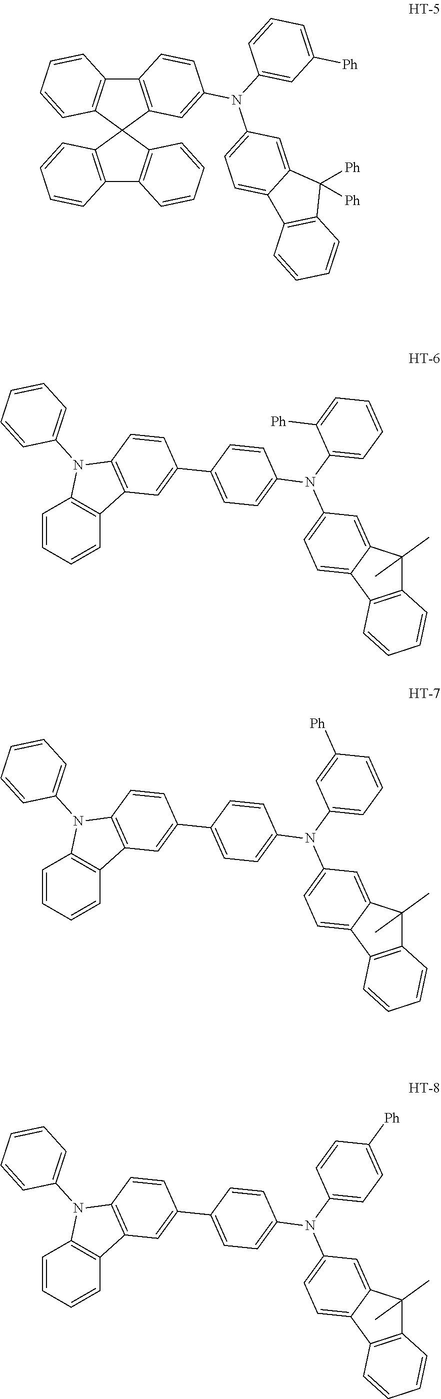

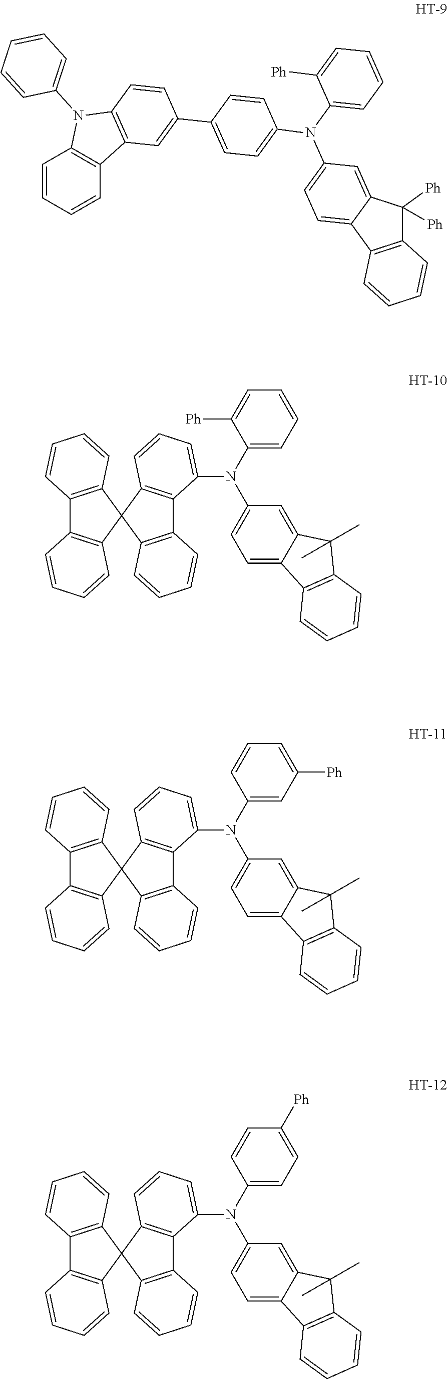

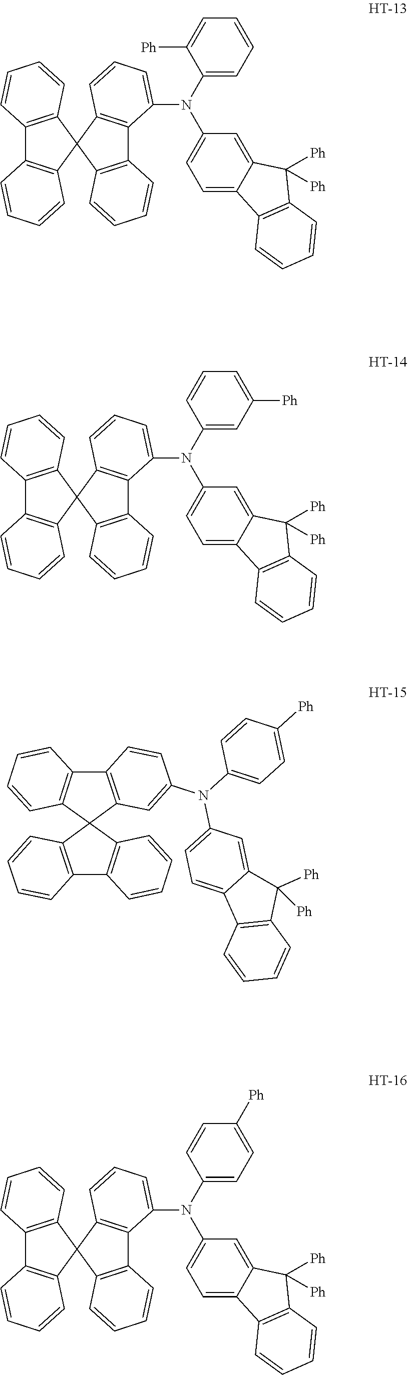 [SMILES: c1ccc(-c2ccccc2N(c2ccc3c(c2)C(c2ccccc2)(c2ccccc2)c2ccccc2-3)c2cccc3c2-c2ccccc2C32c3ccccc3-c3ccccc32)cc1 ; c1ccc(-c2cccc(N(c3ccc4c(c3)C(c3ccccc3)(c3ccccc3)c3ccccc3-4)c3cccc4c3-c3ccccc3C43c4ccccc4-c4ccccc43)c2)cc1 ; c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; c1ccc(-c2ccc(N(c3ccc4c(c3)C(c3ccccc3)(c3ccccc3)c3ccccc3-4)c3cccc4c3-c3ccccc3C43c4ccccc4-c4ccccc43)cc2)cc1]

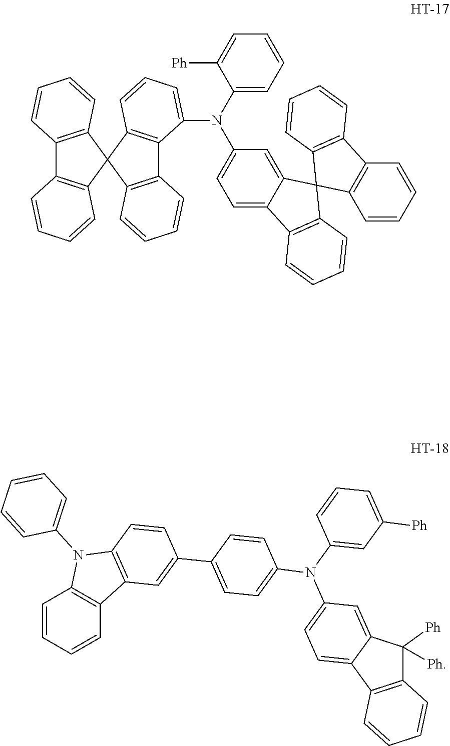 [SMILES: c1ccc(-c2ccccc2N(c2ccc3c(c2)C2(c4ccccc4-c4ccccc42)c2ccccc2-3)c2cccc3c2-c2ccccc2C32c3ccccc3-c3ccccc32)cc1 ; c1ccc(-c2cccc(N(c3ccc(-c4ccc5c(c4)c4ccccc4n5-c4ccccc4)cc3)c3ccc4c(c3)C(c3ccccc3)(c3ccccc3)c3ccccc3-4)c2)cc1]

In a preferred embodiment of the present disclosure, the OLED device of the present disclosure comprises a hole injection layer. The preferred hole injection layer materials of the present disclosure are the following structures; however, this does not mean that the present disclosure is limited to the following structures:

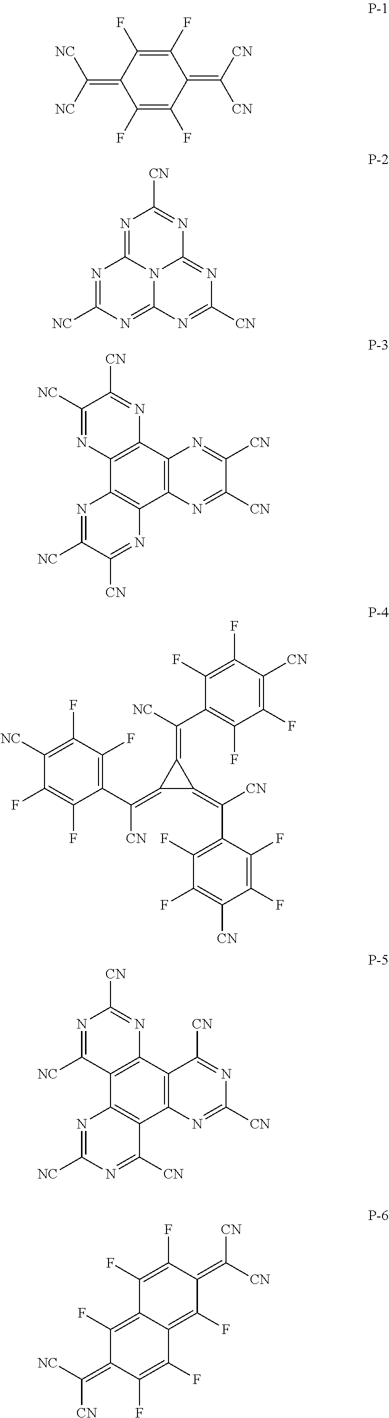

In a preferred embodiment of the present disclosure, the electron transport layer may be selected from at least one of the following compounds; however, this does not mean that the present disclosure is limited to the following structures:

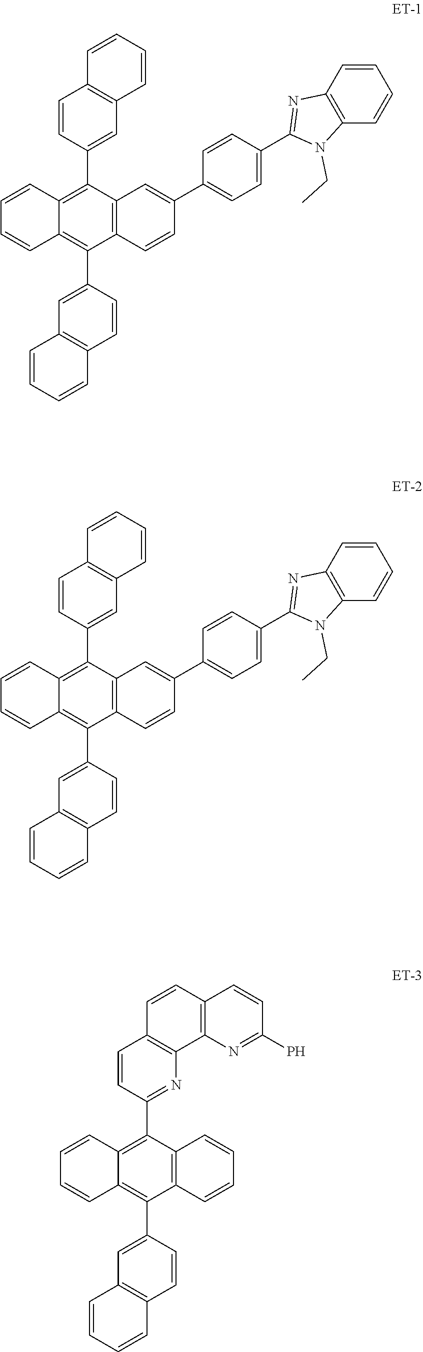

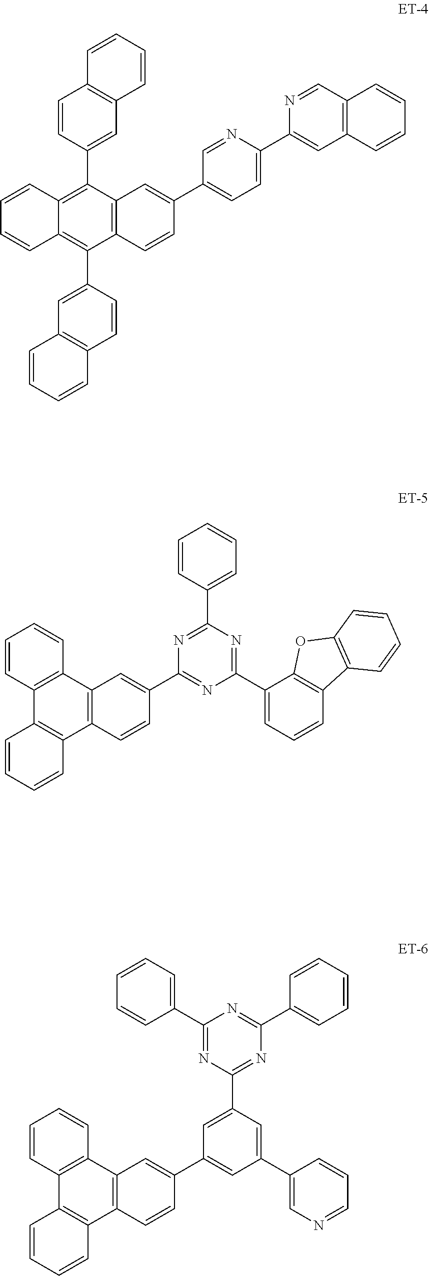 [SMILES: c1ccc2cc(-c3c4ccccc4c(-c4ccc5ccccc5c4)c4cc(-c5ccc(-c6cc7ccccc7cn6)nc5)ccc34)ccc2c1 ; c1ccc(-c2nc(-c3ccc4c5ccccc5c5ccccc5c4c3)nc(-c3cccc4c3oc3ccccc34)n2)cc1 ; c1ccc(-c2nc(-c3ccccc3)nc(-c3cc(-c4cccnc4)cc(-c4ccc5c6ccccc6c6ccccc6c5c4)c3)n2)cc1]

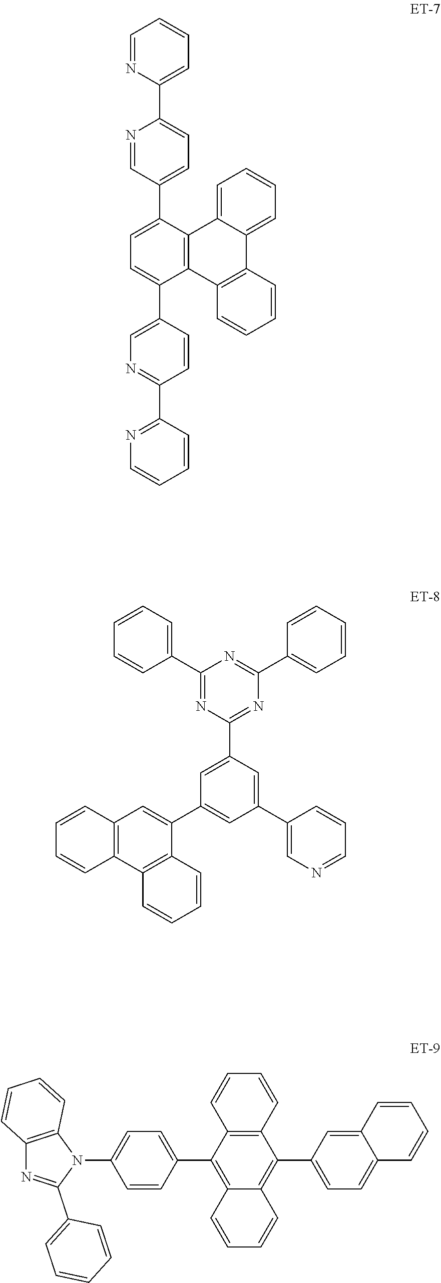 [SMILES: c1ccc(-c2ccc(-c3ccc(-c4ccc(-c5ccccn5)nc4)c4c5ccccc5c5ccccc5c34)cn2)nc1 ; c1ccc(-c2nc(-c3ccccc3)nc(-c3cc(-c4cccnc4)cc(-c4cc5ccccc5c5ccccc45)c3)n2)cc1 ; c1ccc(-c2nc3ccccc3n2-c2ccc(-c3c4ccccc4c(-c4ccc5ccccc5c4)c4ccccc34)cc2)cc1]

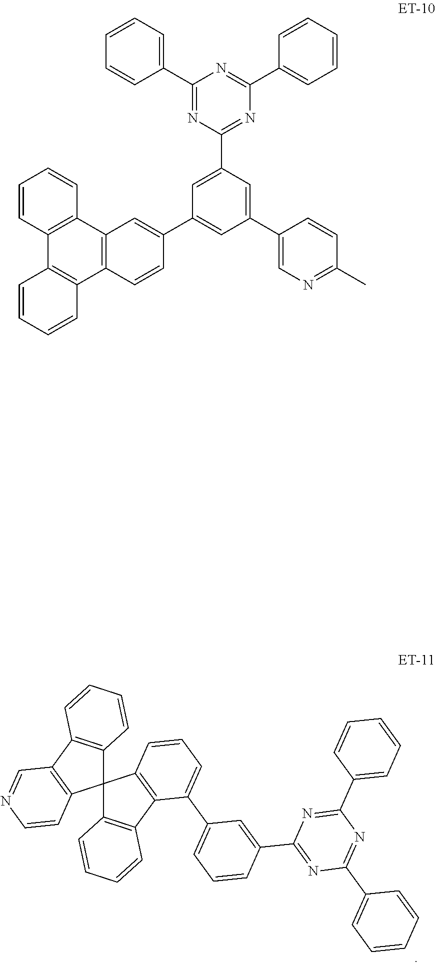 [SMILES: Cc1ccc(-c2cc(-c3ccc4c5ccccc5c5ccccc5c4c3)cc(-c3nc(-c4ccccc4)nc(-c4ccccc4)n3)c2)cn1 ; c1ccc(-c2nc(-c3ccccc3)nc(-c3cccc(-c4cccc5c4-c4ccccc4C54c5ccccc5-c5cnccc54)c3)n2)cc1]

The preparation method for the boron-nitrogen compound, i.e., the guest compound, and the light-emitting performance of the device are explained in detail with reference to the following examples. The molecular structural formulas of the related materials are shown below:

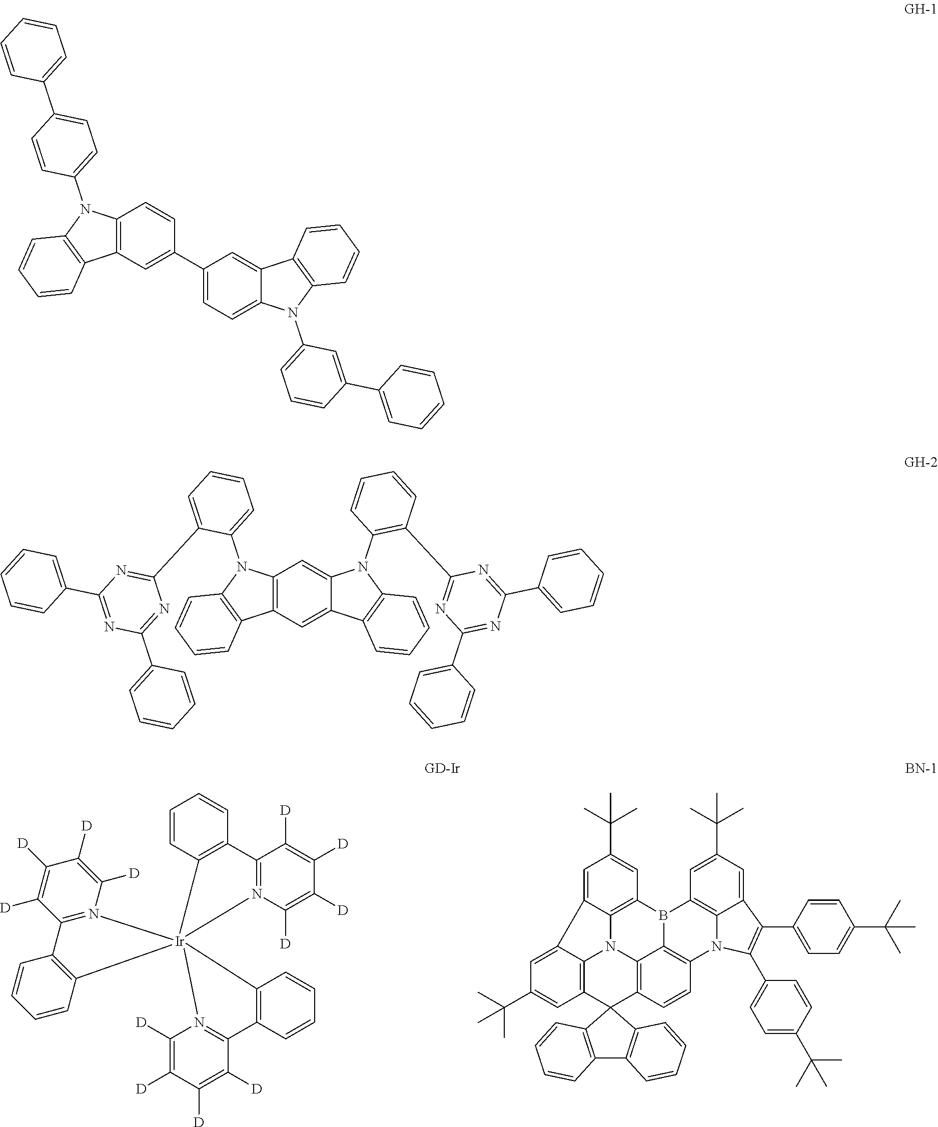

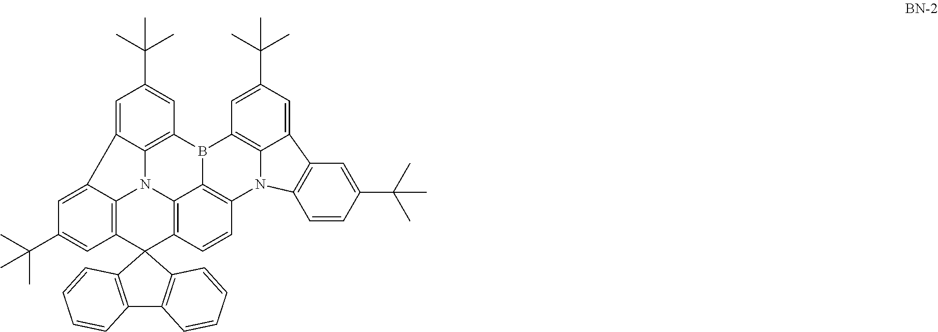 [SMILES: CC(C)(C)c1ccc2c(c1)c1cc(C(C)(C)C)cc3c1n2-c1ccc2c4c1B3c1cc(C(C)(C)C)cc3c5cc(C(C)(C)C)cc(c5n-4c13)C21c2ccccc2-c2ccccc21]

### Example 1: Synthesis of Compound 1

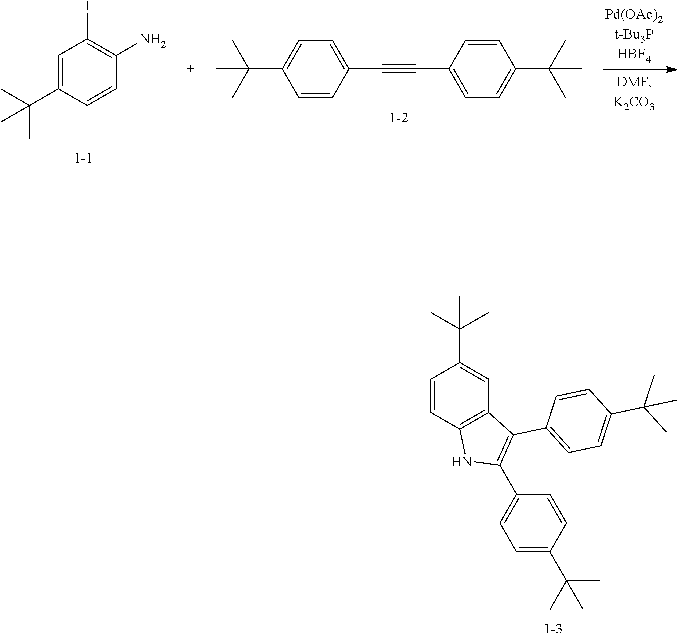

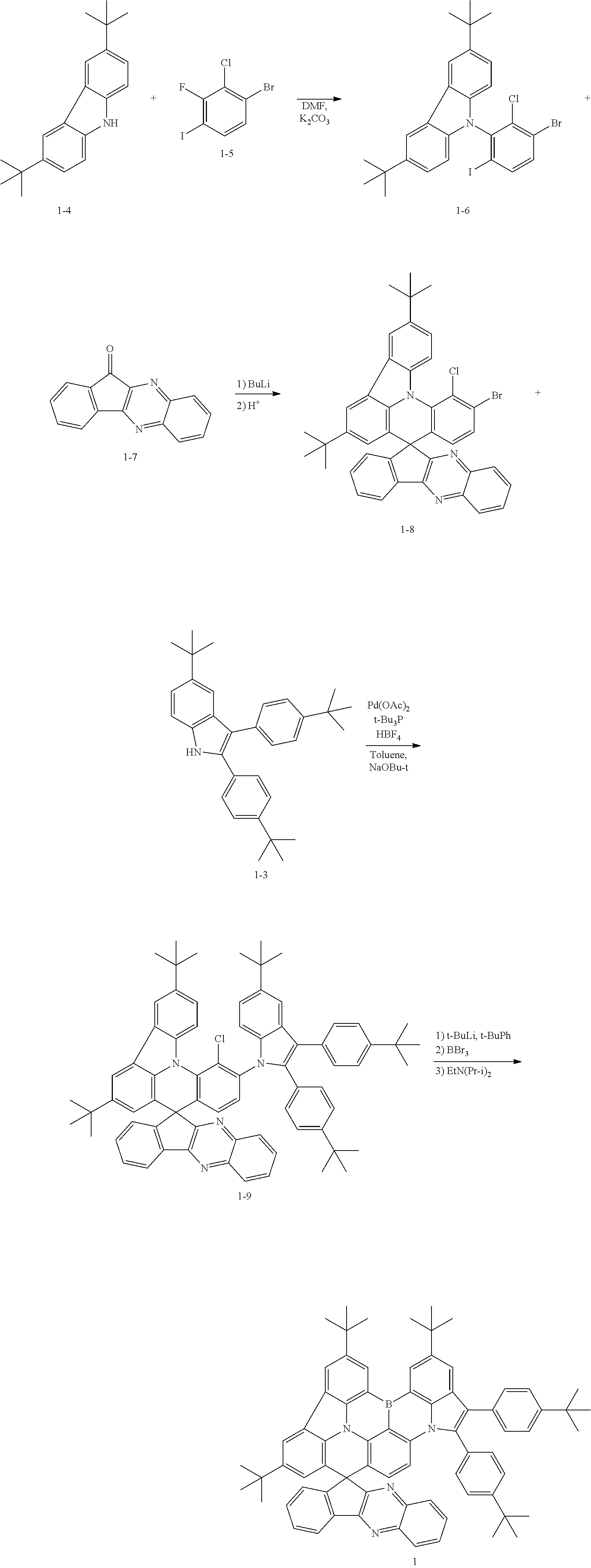

(1) Synthesis of compound 1-3: Compound 1-1 (275 mg, 1 mmol) and compound 1-2 (290 mg, 1 mmol) were dissolved in 50 mL of a DMF solution. Potassium carbonate (691 mg, 5 mmol), palladium acetate (12 mg, 0.05 mmol), and tri-tert-butylphosphonium tetrafluoroborate (145 mg, 0.5 mmol) were added under a nitrogen atmosphere. The reaction system was heated at 140° C. for 24 hours and then cooled to room temperature. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:7) to give product 1-3 (212 mg, yield: 49%). Mass spectrometry m/z, calculated: 437.31; found M+H: 438.33.
(2) Synthesis of compound 1-6: Compound 1-4 (279 mg, 1 mmol) and compound 1-5 (334 mg, 1 mmol) were dissolved in 50 mL of a DMF solution, and potassium carbonate (691 mg, 5 mmol) was added. The reaction system was heated at 140° C. for 24 hours and then cooled to room temperature. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:8) to give product 1-6 (523 mg, yield: 88%). Mass spectrometry m/z, calculated: 592.99; found M+H: 594.01.
(3) Synthesis of compound 1-8: BuLi (0.5 mL, 1 mmol, 2 M in hexane) was slowly added to a solution of compound 1-6 (593 mg, 1 mmol) in anhydrous THF (50 mL) at −78° C. After 3 hours of reaction, 1-7 (232 mg, 1 mmol) was slowly added. The mixture was slowly warmed to room temperature and then left to react overnight, and 1 mL of ice-cold water was added. The solvent was removed by rotary evaporation, and the residue was extracted with dichloromethane (3×100 mL). The organic phase was washed with water and then dried over sodium sulfate. The solvent was removed by distillation under reduced pressure. The resulting residue was dissolved in acetic acid (100 mL), and concentrated hydrochloric acid (10 mL) was then added dropwise. The reaction system was refluxed overnight and then cooled to room temperature. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:1) to give product 1-8 (418 mg, yield: 61%). Mass spectrometry m/z, calculated: 681.16; found M+H: 682.18.
(4) Synthesis of compound 1-9: Compound 1-8 (681 mg, 1 mmol) and compound 1-3 (437 mg, 1 mmol) were dissolved in 50 mL of a toluene solution. Sodium tert-butoxide (192 mg, 2 mmol), palladium acetate (12 mg, 0.05 mmol), and tri-tert-butylphosphonium tetrafluoroborate (145 mg, 0.5 mmol) were added under a nitrogen atmosphere. The reaction system was refluxed for 24 hours and then cooled to room temperature. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:2) to give product 1-9 (410 mg, yield: 39%). Mass spectrometry m/z, calculated: 1038.54; found M+H: 1039.56.
(5) Synthesis of compound 1: tert-Butyllithium (1.25 mL, 1.6 M in pentane, 2 mmol) was slowly added dropwise to a solution of compound 1-9 (1038 mg, 1 mmol) in tert-butylbenzene (100 mL) at 0° C. under a nitrogen atmosphere. The system was left to react at 60° C. for 4 hours and then cooled to −50° C., and BBr₃ (494 mg, 2 mmol) was then added. After 1 hour of reaction at room temperature, N,N-diisopropylethylamine (259 mg, 2 mmol) was added. Then the mixture was heated to 120° C. and left to react for 12 hours. After the mixture was cooled to room temperature, 5 mL of an aqueous sodium acetate solution (1 M) was added. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:3) to give product 1 (265 mg, yield: 26%). Mass spectrometry m/z, calculated: 1012.56; found M+H: 1013.58.

### Example 2: Synthesis of Compound 112

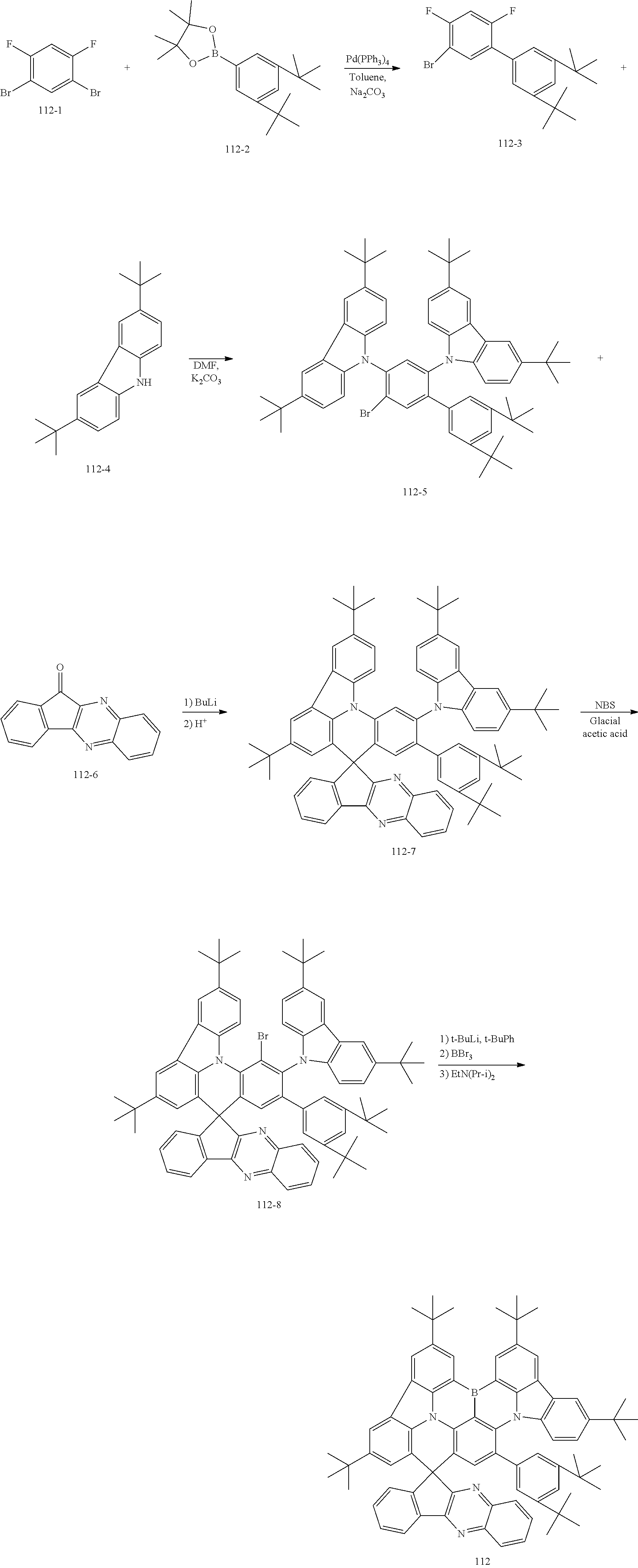

(1) Synthesis of compound 112-3: Compound 112-1 (270 mg, 1 mmol) and compound 112-2 (316 mg, 1 mmol) were dissolved in 50 mL of a toluene solution. 10 mL of an aqueous sodium carbonate solution (2 M) and tetrakis(triphenylphosphine)palladium (57 mg, 0.05 mmol) were added under a nitrogen atmosphere. The reaction system was refluxed for 24 hours and then cooled to room temperature. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:10) to give product 112-3 (231 mg, yield: 61%). Mass spectrometry m/z, calculated: 380.09; found M+H: 381.11.
(2) Synthesis of compound 112-5: Compound 112-3 (380 mg, 1 mmol) and compound 112-4 (558 mg, 2 mmol) were dissolved in 50 mL of a DMF solution, and potassium carbonate (691 mg, 5 mmol) was added. The reaction system was heated at 140° C. for 48 hours and then cooled to room temperature. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:9) to give product 112-5 (712 mg, yield: 79%). Mass spectrometry m/z, calculated: 898.48; found M+H: 899.50.
(3) Synthesis of compound 112-7: BuLi (0.5 mL, 1 mmol, 2 M in hexane) was slowly added to a solution of compound 112-5 (898 mg, 1 mmol) in anhydrous THF (50 mL) at −78° C. After 3 hours of reaction, 112-6 (232 mg, 1 mmol) was slowly added. The mixture was slowly warmed to room temperature and then left to react overnight, and 1 mL of ice-cold water was added. The solvent was removed by rotary evaporation, and the residue was extracted with dichloromethane (3×100 mL). The organic phase was washed with water and then dried over sodium sulfate. The solvent was removed by distillation under reduced pressure. The resulting residue was dissolved in acetic acid (100 mL), and concentrated hydrochloric acid (10 mL) was then added dropwise. The reaction system was refluxed overnight and then cooled to room temperature. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:3) to give product 112-7 (456 mg, yield: 44%). Mass spectrometry m/z, calculated: 1034.62; found M+H: 1035.64.
(4) Synthesis of compound 112-8: In a dark place at 0° C., compound 112-7 (1034 mg, 1 mmol) was slowly added to 100 mL of glacial acetic acid, and NBS (178 mg, 1 mmol) was then slowly added. The mixture was stirred at 0° C. for 18 h. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:5) to give product 112-8 (342 mg, yield: 31%). Mass spectrometry m/z, calculated: 1112.53; found M+H: 1113.55.
(5) Synthesis of compound 112: tert-Butyllithium (1.25 mL, 1.6 M in pentane, 2 mmol) was slowly added dropwise to a solution of compound 112-8 (1112 mg, 1 mmol) in tert-butylbenzene (100 mL) at 0° C. under a nitrogen atmosphere. The system was left to react at 60° C. for 4 hours and then cooled to −50° C., and BBr₃ (494 mg, 2 mmol) was then added. After 1 hour of reaction at room temperature, N,N-diisopropylethylamine (259 mg, 2 mmol) was added. Then the mixture was heated to 120° C. and left to react for 12 hours. After the mixture was cooled to room temperature, 5 mL of an aqueous sodium acetate solution (1 M) was added. The solvent was removed by rotary evaporation, and the residue was extracted with dichloromethane (3×100 mL). The organic phase was washed with water and then dried over sodium sulfate. The solvent was removed by distillation under reduced pressure, and the resulting crude product was separated and purified by silica gel column chromatography (eluent: dichloromethane:petroleum ether=1:4) to give product 112 (259 mg, yield: 25%). Mass spectrometry m/z, calculated: 1042.61; found M+H: 1043.63.

### Example 3: Synthesis of Compound 5

Compound 5 was prepared and synthesized with reference to the preparation scheme of Example 1 or Example 2. The yield of the final product was 24%. Mass spectrometry m/z, calculated: 1168.66; found M+H: 1169.68.

### Example 4: Synthesis of Compound 9

Compound 9 was prepared and synthesized with reference to the preparation scheme of Example 1 or Example 2. The yield of the final product was 23%. Mass spectrometry m/z, calculated: 1052.62; found M+H: 1053.64.

### Example 5: Synthesis of Compound 13

Compound 13 was prepared and synthesized with reference to the preparation scheme of Example 1 or Example 2. The yield of the final product was 28%. Mass spectrometry m/z, calculated: 1011.57; found M+H: 1012.59.

### Example 6: Synthesis of Compound 19

Compound 19 was prepared and synthesized with reference to the preparation scheme of Example 1 or Example 2. The yield of the final product was 23%. Mass spectrometry m/z, calculated: 1012.56; found M+H: 1013.59.

### Example 7: Synthesis of Compound 25

Compound 25 was prepared and synthesized with reference to the preparation scheme of Example 1 or Example 2. The yield of the final product was 29%. Mass spectrometry m/z, calculated: 1011.57; found M+H: 1012.59.

### Example 8: Synthesis of Compound 31

Compound 31 was prepared and synthesized with reference to the preparation scheme of Example 1 or Example 2. The yield of the final product was 22%. Mass spectrometry m/z, calculated: 1011.57; found M+H: 1012.60.

### Example 9: Synthesis of Compound 37

Compound 37 was prepared and synthesized with reference to the preparation scheme of Example 1 or Example 2. The yield of the final product was 26%. Mass spectrometry m/z, calculated: 1011.57; found M+H: 1012.59.

### Example 10: Synthesis of Compound 43

Compound 43 was prepared and synthesized with reference to the preparation scheme of Example 1 or Example 2. The yield of the final product was 24%. Mass spectrometry m/z, calculated: 1048.56; found M+H: 1049.58.

### Example 11: Synthesis of Compound 46

Compound 46 was prepared and synthesized with reference to the preparation scheme of Example 1 or Example 2. The yield of the final product was 23%. Mass spectrometry m/z, calculated: 1004.52; found M+H: 1005.54.

### Example 12: Synthesis of Compound 52

Compound 52 was prepared and synthesized with reference to the preparation scheme of Example 1 or Example 2. The yield of the final product was 21%. Mass spectrometry m/z, calculated: 1005.52; found M+H: 1006.55.

### Example 13: Synthesis of Compound 61

Compound 61 was prepared and synthesized with reference to the preparation scheme of Example 1 or Example 2. The yield of the final product was 28%. Mass spectrometry m/z, calculated: 1062.55; found M+H: 1063.57.

### Example 14: Synthesis of Compound 64

Compound 64 was prepared and synthesized with reference to the preparation scheme of Example 1 or Example 2. The yield of the final product was 24%. Mass spectrometry m/z, calculated: 1016.43; found M+H: 1017.45.

### Example 15: Synthesis of Compound 72

Compound 72 was prepared and synthesized with reference to the preparation scheme of Example 1 or Example 2. The yield of the final product was 27%. Mass spectrometry m/z, calculated: 1178.57; found M+H: 1179.59.

### Example 16: Synthesis of Compound 76

Compound 76 was prepared and synthesized with reference to the preparation scheme of Example 1 or Example 2. The yield of the final product was 25%. Mass spectrometry m/z, calculated: 956.50; found M+H: 957.52.

### Example 17: Synthesis of Compound 87

Compound 87 was prepared and synthesized with reference to the preparation scheme of Example 1 or Example 2. The yield of the final product was 27%. Mass spectrometry m/z, calculated: 1118.64; found M+H: 1119.67.

### Example 18: Synthesis of Compound 91

Compound 91 was prepared and synthesized with reference to the preparation scheme of Example 1 or Example 2. The yield of the final product was 28%. Mass spectrometry m/z, calculated: 1138.70; found M+H: 1139.72.

### Example 19: Synthesis of Compound 99

Compound 99 was prepared and synthesized with reference to the preparation scheme of Example 1 or Example 2. The yield of the final product was 23%. Mass spectrometry m/z, calculated: 1170.67; found M+H: 1171.69.

### Example 20: Synthesis of Compound 106

Compound 106 was prepared and synthesized with reference to the preparation scheme of Example 1 or Example 2. The yield of the final product was 21%. Mass spectrometry m/z, calculated: 1122.67; found M+H: 1123.69.

### Example 21: Synthesis of Compound 121

Compound 121 was prepared and synthesized with reference to the preparation scheme of Example 1 or Example 2. The yield of the final product was 23%. Mass spectrometry m/z, calculated: 1164.65; found M+H: 1165.67.

### Example 22: Synthesis of Compound 124

Compound 124 was prepared and synthesized with reference to the preparation scheme of Example 1 or Example 2. The yield of the final product was 29%. Mass spectrometry m/z, calculated: 1098.67; found M+H: 1099.69.

### Example 23: Synthesis of Compound 130

Compound 130 was prepared and synthesized with reference to the preparation scheme of Example 1 or Example 2. The yield of the final product was 24%. Mass spectrometry m/z, calculated: 1152.72; found M+H: 1153.74.

### Example 24: Synthesis of Compound 142

Compound 142 was prepared and synthesized with reference to the preparation scheme of Example 1 or Example 2. The yield of the final product was 25%. Mass spectrometry m/z, calculated: 1150.73; found M+H: 1151.75.

### Example 25: Synthesis of Compound 151

Compound 151 was prepared and synthesized with reference to the preparation scheme of Example 1 or Example 2. The yield of the final product was 26%. Mass spectrometry m/z, calculated: 1176.56; found M+H: 1177.58.

### Example 26: Synthesis of Compound 154

Compound 154 was prepared and synthesized with reference to the preparation scheme of Example 1 or Example 2. The yield of the final product was 27%. Mass spectrometry m/z, calculated: 1174.70; found M+H: 1175.73.

### Example 27: Synthesis of Compound 155

Compound 155 was prepared and synthesized with reference to the preparation scheme of Example 1 or Example 2. The yield of the final product was 27%. Mass spectrometry m/z, calculated: 1118.64; found M+H: 1119.67.

### Example 28: Synthesis of Compound 156

Compound 156 was prepared and synthesized with reference to the preparation scheme of Example 1 or Example 2. The yield of the final product was 28%. Mass spectrometry m/z, calculated: 1230.77; found M+H: 1231.79.

### Example 29: Synthesis of Compound 158

Compound 158 was prepared and synthesized with reference to the preparation scheme of Example 1 or Example 2. The yield of the final product was 24%. Mass spectrometry m/z, calculated: 1121.67; found M+H: 1122.69.

### Example 30: Synthesis of Compound 166

Compound 166 was prepared and synthesized with reference to the preparation scheme of Example 1 or Example 2. The yield of the final product was 29%. Mass spectrometry m/z, calculated: 1041.61; found M+H: 1042.63.

### Example 31: Synthesis of Compound 167

Compound 167 was prepared and synthesized with reference to the preparation scheme of Example 1 or Example 2. The yield of the final product was 26%. Mass spectrometry m/z, calculated: 1069.65; found M+H: 1070.67.

### Example 32: Synthesis of Compound 168

Compound 168 was prepared and synthesized with reference to the preparation scheme of Example 1 or Example 2. The yield of the final product was 22%. Mass spectrometry m/z, calculated: 1095.66; found M+H: 1096.68.

### Example 33: Synthesis of Compound 170

Compound 170 was prepared and synthesized with reference to the preparation scheme of Example 1 or Example 2. The yield of the final product was 25%. Mass spectrometry m/z, calculated: 1063.60; found M+H: 1064.62.

### Example 34: Synthesis of Compound 174

Compound 174 was prepared and synthesized with reference to the preparation scheme of Example 1 or Example 2. The yield of the final product was 29%. Mass spectrometry m/z, calculated: 1168.65; found M+H: 1169.67.

### Example 35: Synthesis of Compound 175

Compound 175 was prepared and synthesized with reference to the preparation scheme of Example 1 or Example 2. The yield of the final product was 24%. Mass spectrometry m/z, calculated: 1146.67; found M+H: 1147.69.

### Example 36: Synthesis of Compound 176

Compound 176 was prepared and synthesized with reference to the preparation scheme of Example 1 or Example 2. The yield of the final product was 29%. Mass spectrometry m/z, calculated: 1174.70; found M+H: 1175.72.

### Example 37: Synthesis of Compound 177

Compound 177 was prepared and synthesized with reference to the preparation scheme of Example 1 or Example 2. The yield of the final product was 21%. Mass spectrometry m/z, calculated: 1223.69; found M+H: 1224.71.

### Manufacture of OLED Devices:

As a reference preparation method for a device example, the present disclosure manufactured an organic electroluminescent diode by depositing a p-doped material on the surface or anode of a piece of ITO glass with a light-emitting area of 2 mm×2 mm or co-depositing the p-doped material at a concentration of 1%-50% with a hole transport material to form a 5-100 nm hole injection layer (HIL), forming a 5-200 nm hole transport layer (HTL) on the hole injection layer, subsequently co-depositing host materials (GH-1 and GH-2), GD-Ir, and the boron-nitrogen compound prepared by the present disclosure (guest material) in a ratio of 64:32:3:1 by mass on the hole transport layer to form a 10-100 nm emissive layer (EML), finally co-depositing to form a 35 nm electron transport layer (ETL), and then depositing to form a 70 nm Al cathode.

In a preferred specific example, the bottom-emitting OLED device provided by the present disclosure has a structure as follows: An organic electroluminescent diode was prepared by using a piece of glass containing ITO as an anode, sequentially forming, by deposition, a 10 nm thick HIL made of HT-5:P-4 (97:3 by mass), a 60 nm thick HTL made of HT-5, a 20 nm thick EBL made of HT-16, a 35 nm thick EML made of host materials (GH-1 and GH-2):GD-Ir:the boron-nitrogen compound 1 provided by the present disclosure (64:32:3:1 by mass), a 35 nm thick ETL made of ET-6:LiQ (50:50 by mass), and a 1 nm EIL made of LiF, and then forming a 70 nm Al cathode by deposition and was designated Application Example 1.

Organic electroluminescent diodes were prepared by referring to the device structure provided by Application Example 1 and selecting the boron-nitrogen compounds listed in Table 1 as implementation objects to replace compound 1 and were designated Application Examples 2-33 and Comparative Examples 1 and 2. The above prepared device examples and comparative examples were tested for properties such as current efficiency, voltage, and lifespan by standard methods, and data on the light emission property of the devices are shown in Table 1.

TABLE 1
Data on the light emission property of the devices

| Application | Boron-nitrogen | FWHM | Current efficiency | LT95 |
|---|---|---|---|---|
| example | compound | (nm) | (cd/A) | (hours) |
| Application | Compound 1 | 27 | 64.52 | 387 |
| Example 1 | | | | |
| Application | Compound 5 | 27 | 65.87 | 393 |
| Example 2 | | | | |
| Application | Compound 9 | 27 | 60.77 | 349 |
| Example 3 | | | | |
| Application | Compound 13 | 27 | 67.21 | 401 |
| Example 4 | | | | |
| Application | Compound 19 | 27 | 64.98 | 405 |
| Example 5 | | | | |
| Application | Compound 25 | 27 | 65.88 | 386 |
| Example 6 | | | | |
| Application | Compound 31 | 27 | 67.82 | 379 |
| Example 7 | | | | |
| Application | Compound 37 | 27 | 66.62 | 389 |
| Example 8 | | | | |
| Application | Compound 43 | 27 | 63.99 | 397 |
| Example 9 | | | | |
| Application | Compound 52 | 27 | 64.53 | 391 |
| Example 10 | | | | |
| Application | Compound 61 | 27 | 59.78 | 351 |
| Example 11 | | | | |
| Application | Compound 64 | 27 | 57.57 | 343 |
| Example 12 | | | | |
| Application | Compound 72 | 27 | 56.43 | 356 |
| Example 13 | | | | |
| Application | Compound 76 | 27 | 67.12 | 387 |
| Example 14 | | | | |
| Application | Compound 87 | 27 | 61.32 | 378 |
| Example 15 | | | | |
| Application | Compound 91 | 27 | 64.26 | 395 |
| Example 16 | | | | |
| Application | Compound 99 | 26 | 63.47 | 382 |
| Example 17 | | | | |
| Application | Compound 106 | 27 | 64.37 | 398 |
| Example 18 | | | | |
| Application | Compound 112 | 27 | 65.43 | 389 |
| Example 19 | | | | |
| Application | Compound 121 | 27 | 58.67 | 345 |
| Example 20 | | | | |
| Application | Compound 130 | 27 | 65.57 | 382 |
| Example 21 | | | | |
| Application | Compound 154 | 27 | 64.57 | 405 |
| Example 22 | | | | |
| Application | Compound 155 | 27 | 65.77 | 389 |
| Example 23 | | | | |
| Application | Compound 156 | 27 | 65.43 | 397 |
| Example 24 | | | | |
| Application | Compound 158 | 27 | 56.12 | 344 |
| Example 25 | | | | |
| Application | Compound 166 | 26 | 62.77 | 393 |
| Example 26 | | | | |
| Application | Compound 167 | 27 | 63.11 | 391 |
| Example 27 | | | | |
| Application | Compound 168 | 27 | 64.78 | 385 |
| Example 28 | | | | |
| Application | Compound 170 | 27 | 63.74 | 394 |
| Example 29 | | | | |
| Application | Compound 174 | 27 | 64.39 | 397 |
| Example 30 | | | | |
| Application | Compound 175 | 27 | 62.81 | 401 |
| Example 31 | | | | |
| Application | Compound 176 | 27 | 63.73 | 396 |
| Example 32 | | | | |
| Application | Compound 177 | 27 | 64.45 | 397 |
| Example 33 | | | | |
| Comparative | BN-1 | 28 | 51.31 | 235 |
| Example 1 | | | | |
| Comparative | BN-2 | 28 | 50.64 | 242 |
| Example 2 | | | | |

As can be seen from Table 1, the electronic devices prepared using the compounds of the present disclosure as emissive layer materials exhibited higher current efficiencies and lifespans. Compared to Comparative Examples 1 and 2, Application Examples 1 to 33 exhibited good device performance in terms of both current efficiency and lifespan, and the improvements in the devices' performance were achieved based on the better ability of the boron-nitrogen compound materials of the present disclosure to transport electrons. This indicates that the boron-nitrogen compounds provided by the present disclosure have certain commercial application value.

The above descriptions are only the preferred specific embodiments of the present disclosure; however, the protection scope of the present disclosure is not limited thereto. Equivalent replacements or changes made by anyone skilled in the art within the technical scope of the present disclosure based on the technical solutions of the present disclosure and the inventive concept thereof shall be encompassed within the protection scope of the present disclosure.

1. A boron-nitrogen compound, having a structure represented by formula (I) as shown below: 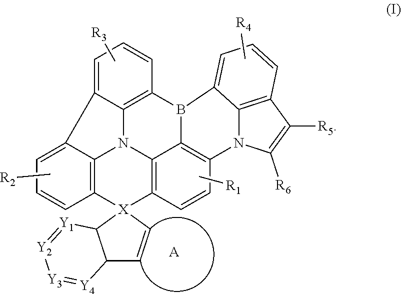
wherein X is selected from C, Si and Ge; ring A is selected from substituted or unsubstituted C6-C30 aryl and substituted or unsubstituted C6-C30 heteroaryl; Y₁, Y₂, Y₃ and Y₄ are each independently selected from CR and N; each of R₁-R₄ represents one or more substitutents; and R and R₁-R₆ are each independently selected from hydrogen, deuterium, C1-C24 alkyl, substituted or unsubstituted C3-C24 cycloalkyl, substituted or unsubstituted C6-C30 aryl and substituted or unsubstituted C6-C30 heteroaryl, a heteroatom in the heteroaryl being selected from N, O and S, and a substituent therein being selected from deuterium, C1-C24 alkyl, C3-C24 cycloalkyl and C6-C30 aryl when substitution is contained.

2. The boron-nitrogen compound according to claim 1, having a structure represented by formula (I-1) or formula (I-2) as shown below: 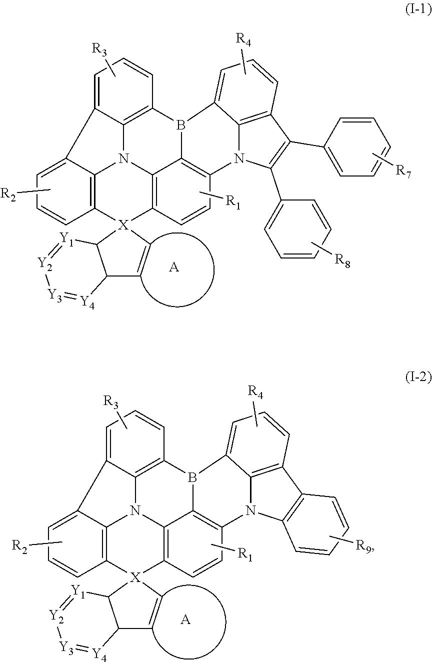
wherein each of R₇, R₈ and R₉ represents one or more substituents; and R₇, R₈ and R₉ are each independently selected from hydrogen, deuterium, C1-C24 alkyl and C3-C24 cycloalkyl

3. The boron-nitrogen compound according to claim 2, wherein in formula (I-1), R₁ is hydrogen; one or more substituents represented by R₄ are identically or differently selected from hydrogen, deuterium, methyl, ethyl, propyl, butyl, tert-butyl, pentyl, tert-pentyl, hexyl, heptyl and a benzene or naphthalene ring formed by fusion with an adjacent substituent; and one or more substituents represented by each of R₇ and R₈ are identically or differently selected from hydrogen, deuterium, methyl, ethyl, propyl, butyl, tert-butyl, pentyl, tert-pentyl, hexyl, heptyl, cyclohexane and adamantyl.

4. The boron-nitrogen compound according to claim 2, wherein in formula (I-2), R₁ is selected from substituted or unsubstituted C6-C18 aryl and substituted or unsubstituted tetrahydronaphthyl, a substituent therein being one or more selected from hydrogen, deuterium, methyl, ethyl, propyl, butyl, tert-butyl, adamantyl and pyridyl when substitution is contained; and one or more substituents represented by each of R₄ and R₉ are identically or differently selected from hydrogen, deuterium, methyl, ethyl, propyl, butyl, tert-butyl, pentyl, tert-pentyl, hexyl, heptyl and adamantyl.

5. The boron-nitrogen compound according to claim 2, wherein at least one of R₄, R₇ or R₈ is fused with an adjacent group to form a ring.

6. The boron-nitrogen compound according to claim 1, wherein R₂ and R₃ are each independently selected from hydrogen, deuterium, methyl, ethyl, propyl, tert-butyl and tert-pentyl.

7. The boron-nitrogen compound according to claim 1, wherein ring A is any one selected from phenyl, pyridyl, naphthyl and following ring structures:

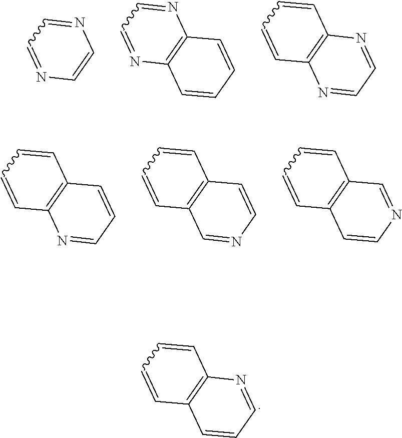

8. The boron-nitrogen compound according to claim 1, wherein when at least one of Y₁-Y₄ is N, ring A is selected from phenyl and naphthyl; and when Y₁-Y₄ each are CR, ring A is any one selected from pyridyl and following ring structures:

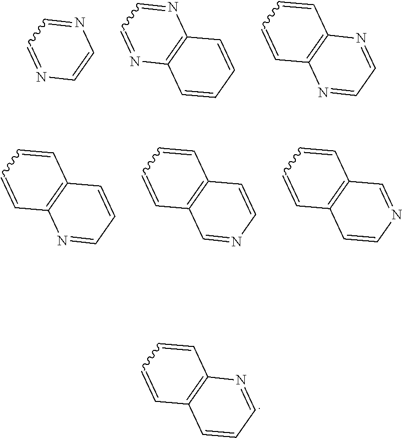

9. The boron-nitrogen compound according to claim 1, wherein each of one or more substituents represented by R is independently selected from hydrogen, deuterium, methyl, ethyl, propyl, butyl, tert-butyl, pentyl, tert-pentyl, hexyl, heptyl, cyclohexane, substituted or unsubstituted phenyl and substituted or unsubstituted pyridyl; and each of one or more substituents represented by each of R₂ and R₃ is independently selected from hydrogen, deuterium, methyl, ethyl, propyl, butyl, tert-butyl, pentyl, tert-pentyl, hexyl and heptyl.

10. The boron-nitrogen compound according to claim 9, wherein R is fused with an adjacent substituent to form substituted or unsubstituted cyclopentane.

11. The boron-nitrogen compound according to claim 1, wherein the boron-nitrogen compound is any one selected from chemical structures shown below: 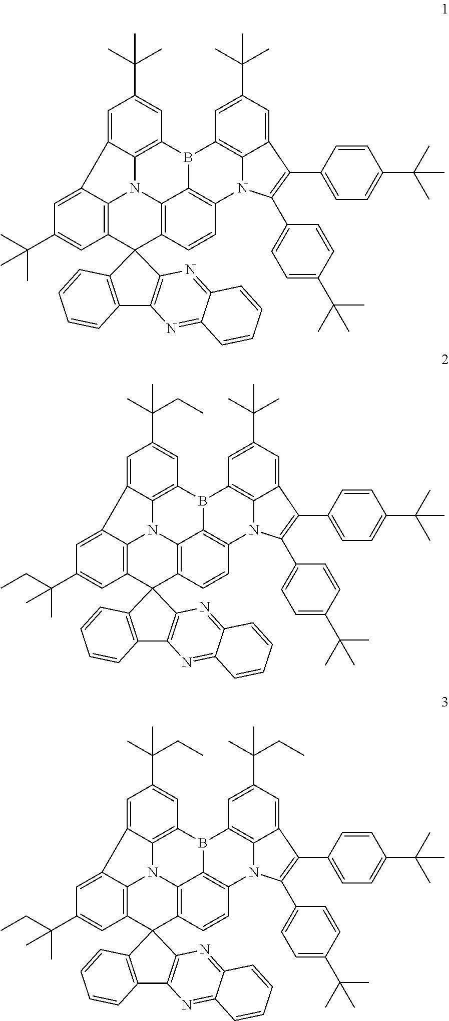 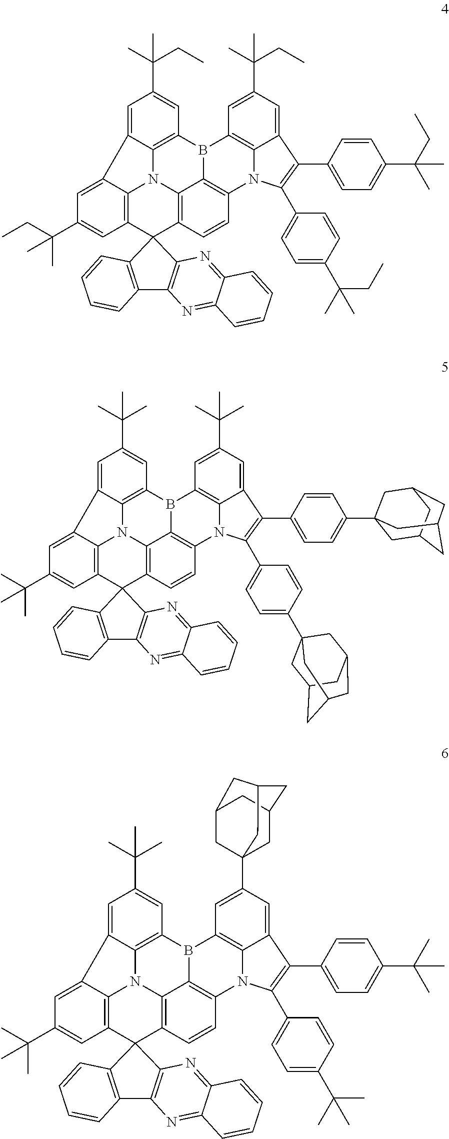 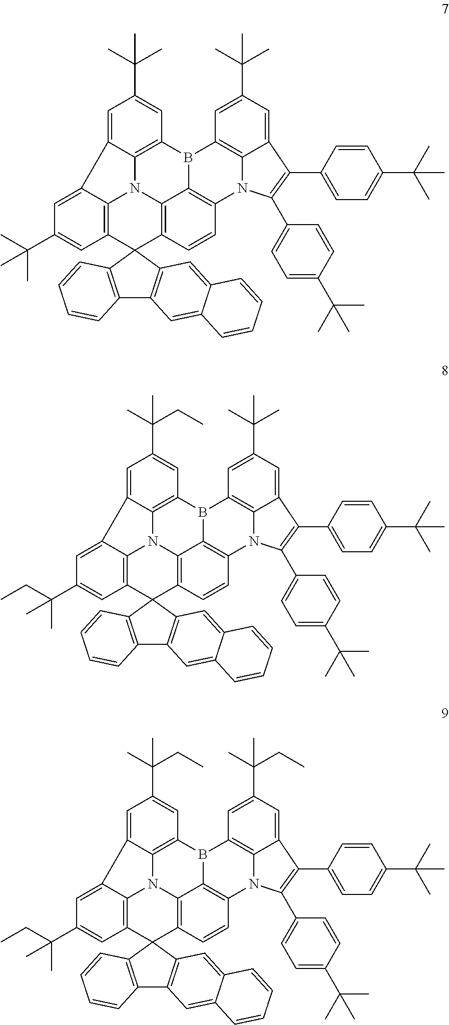 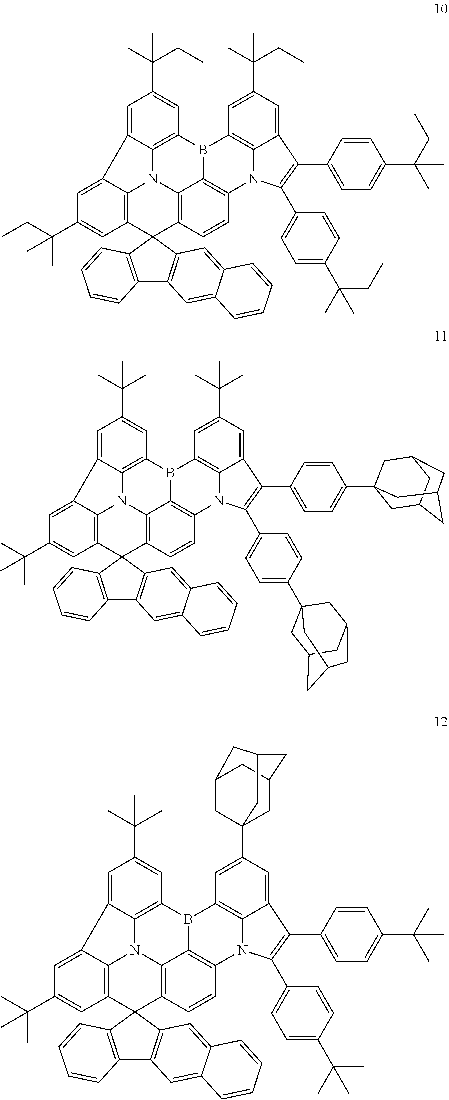 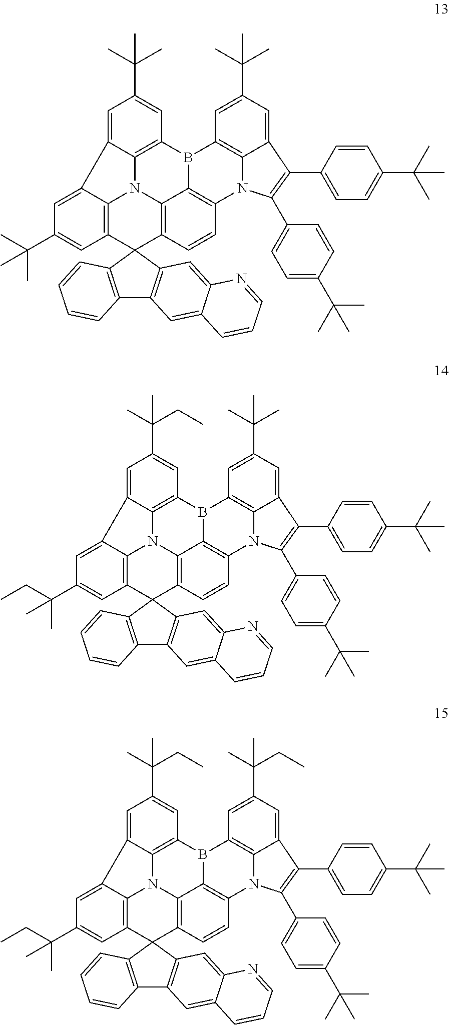 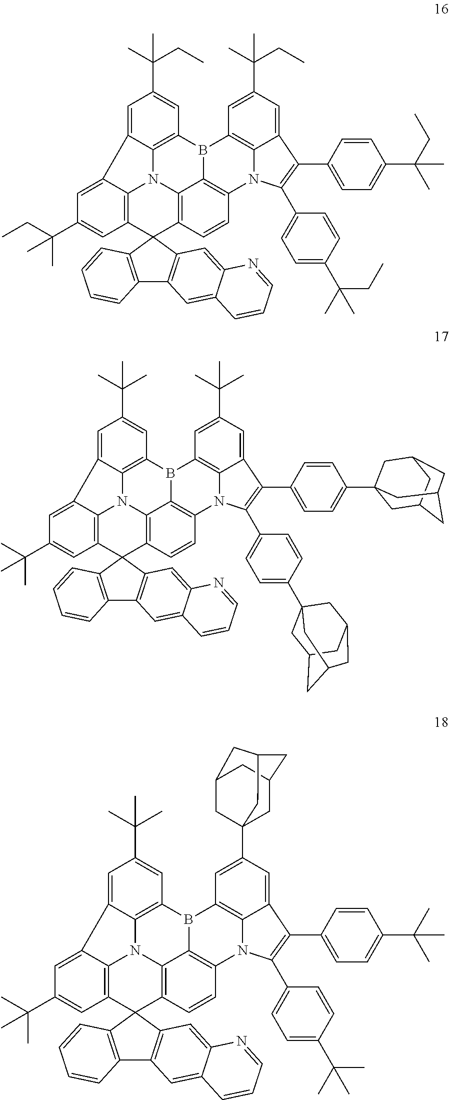 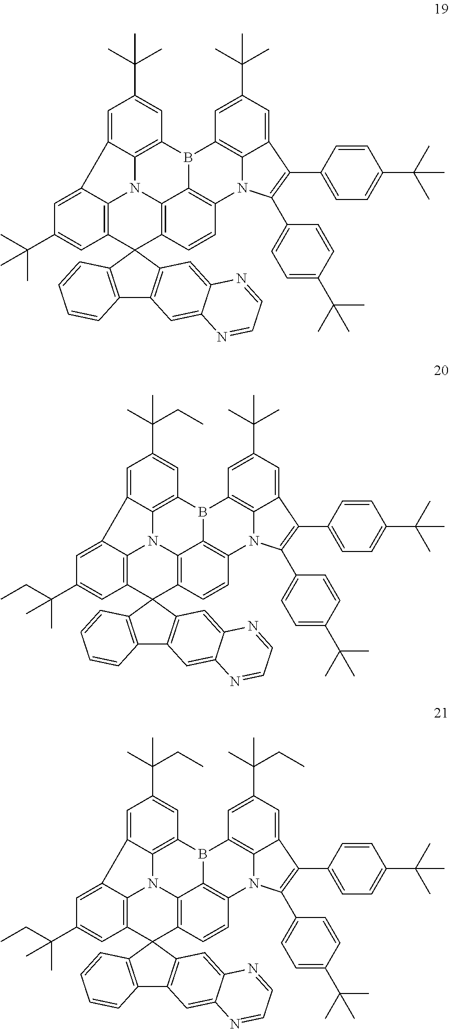 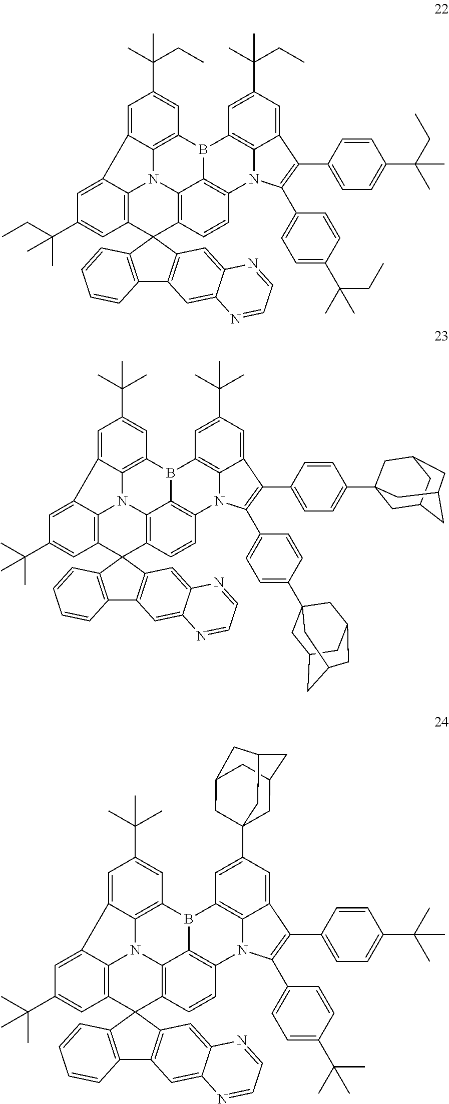 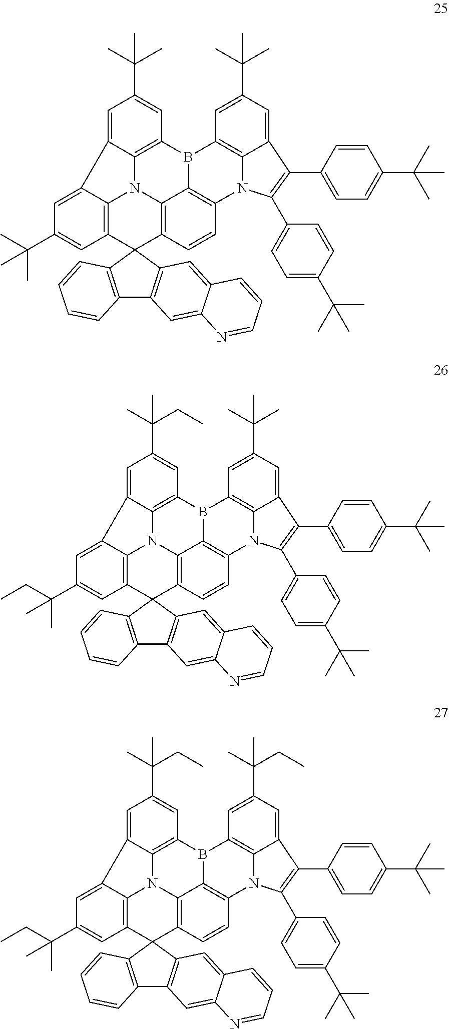 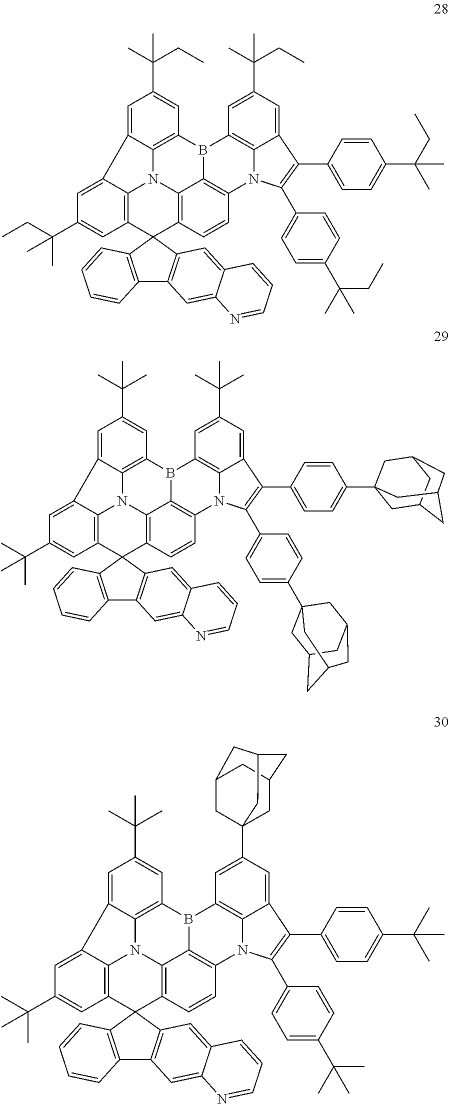 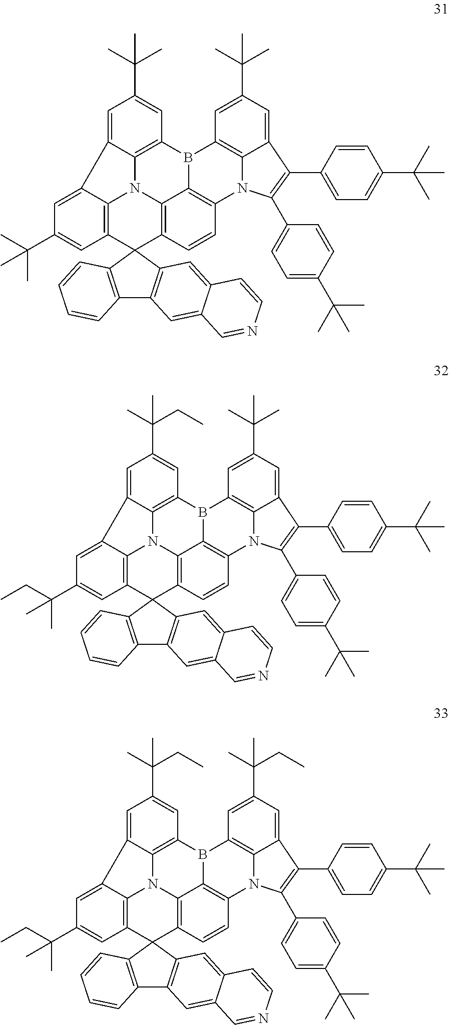 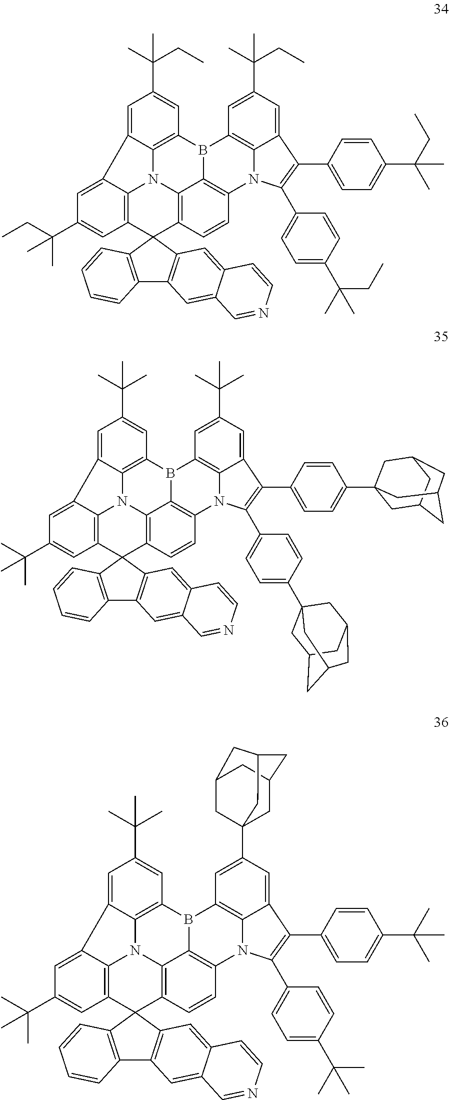 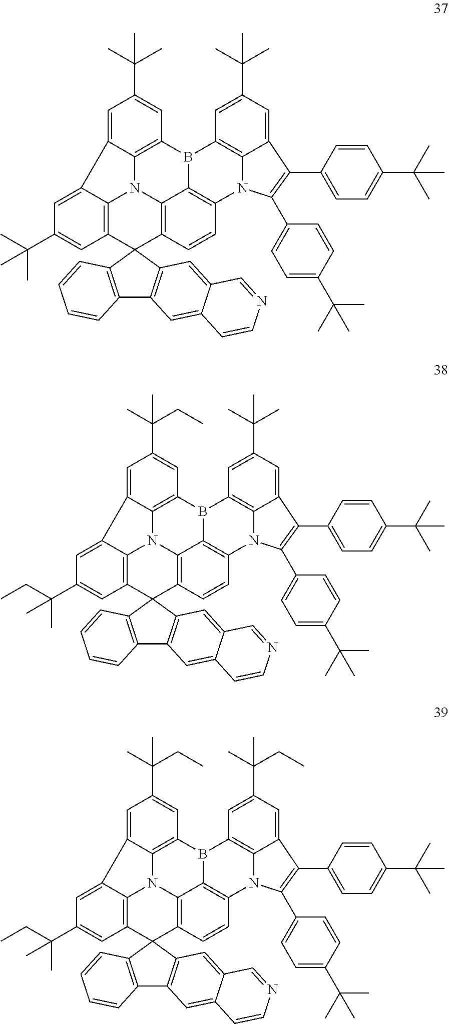 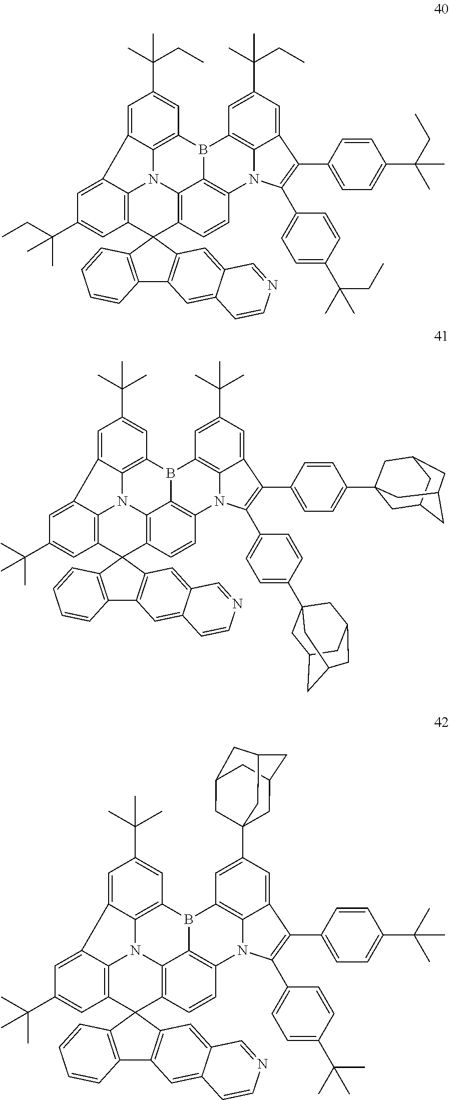 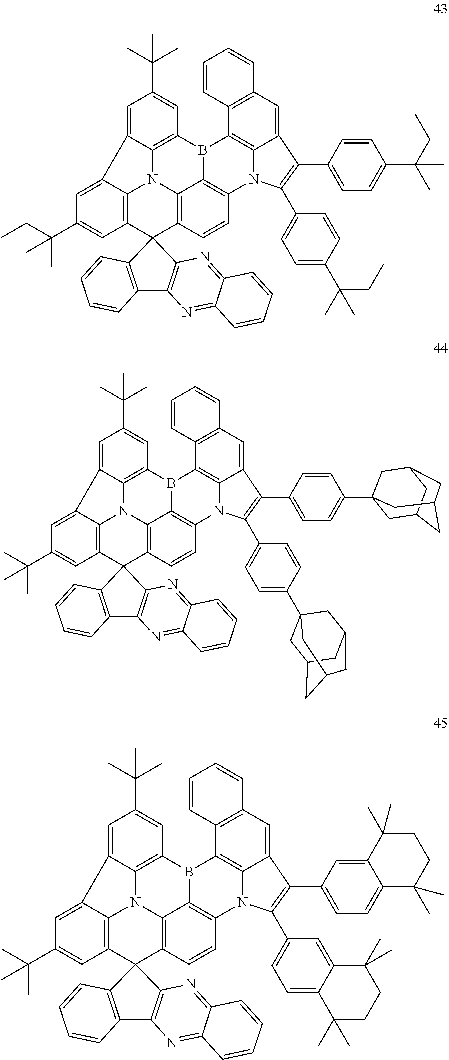 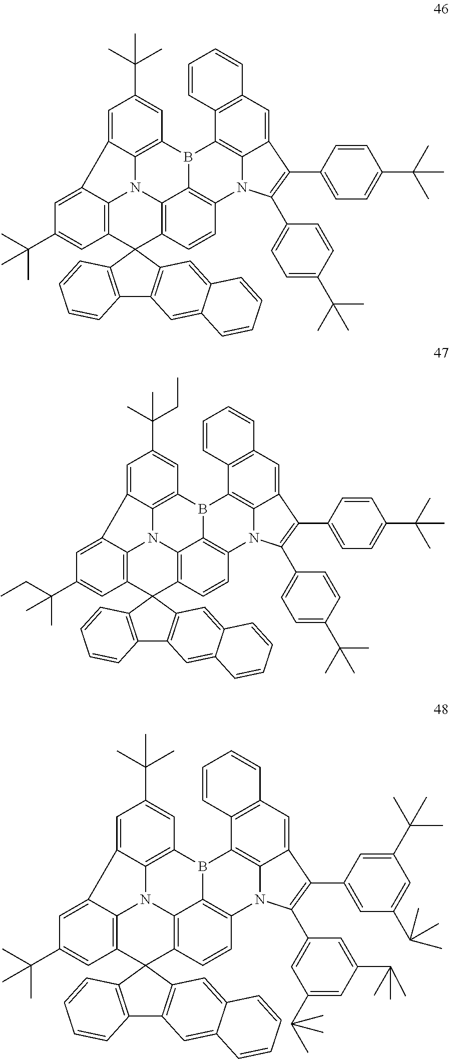 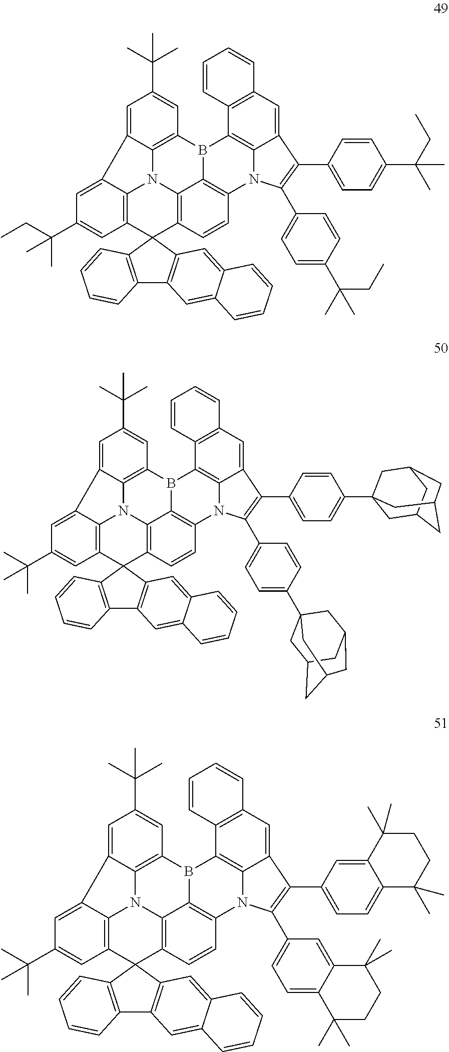 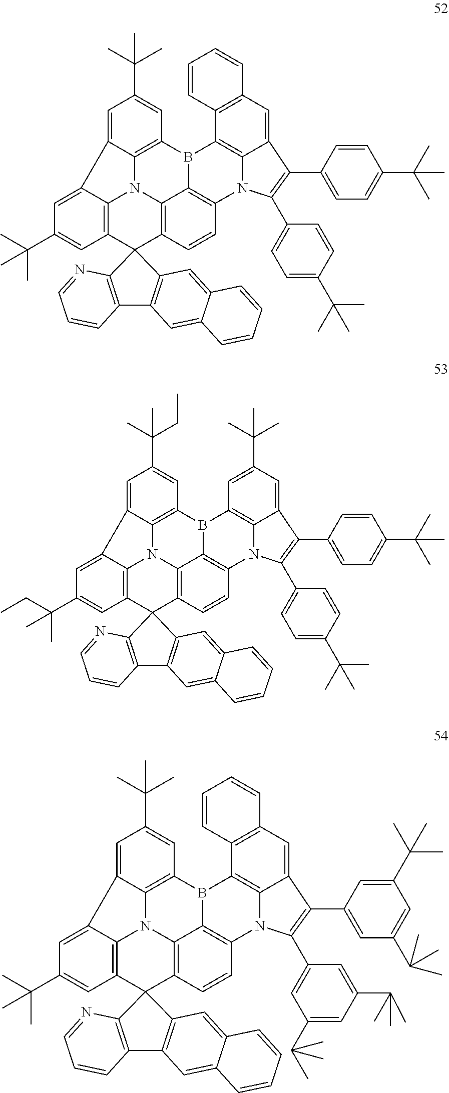 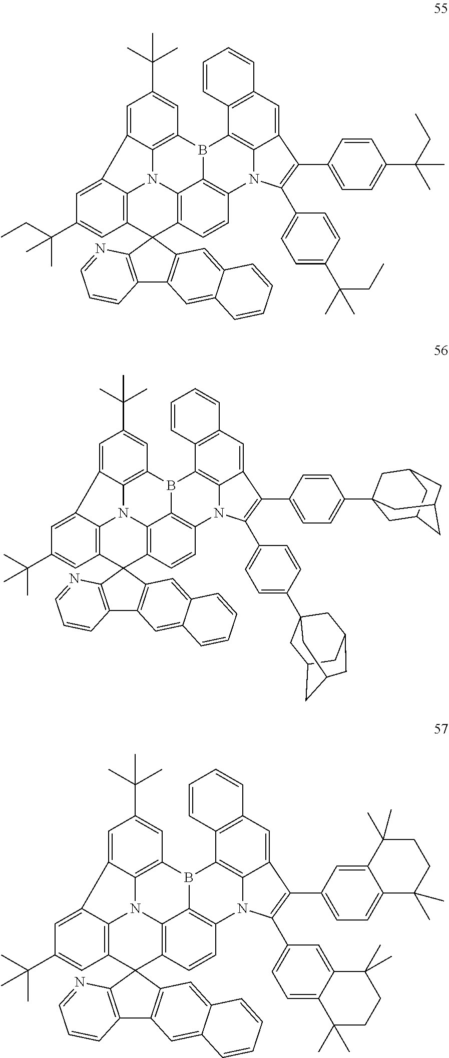 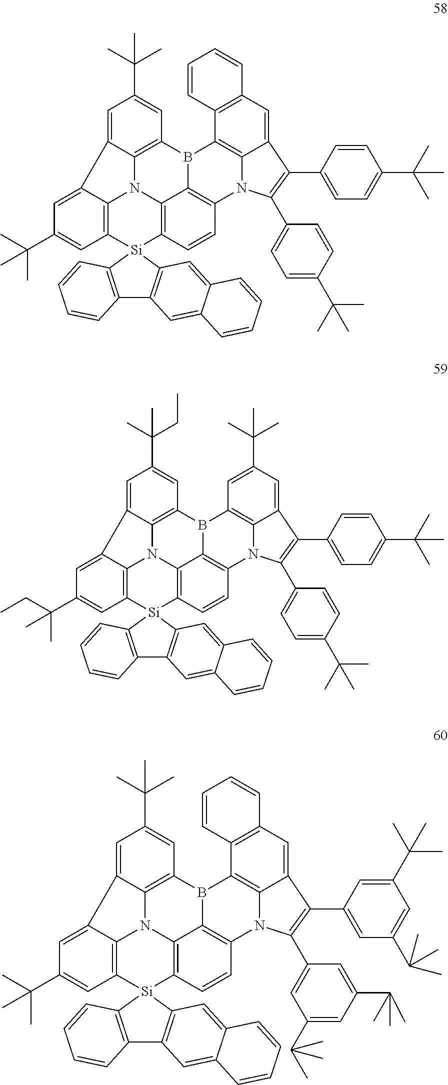 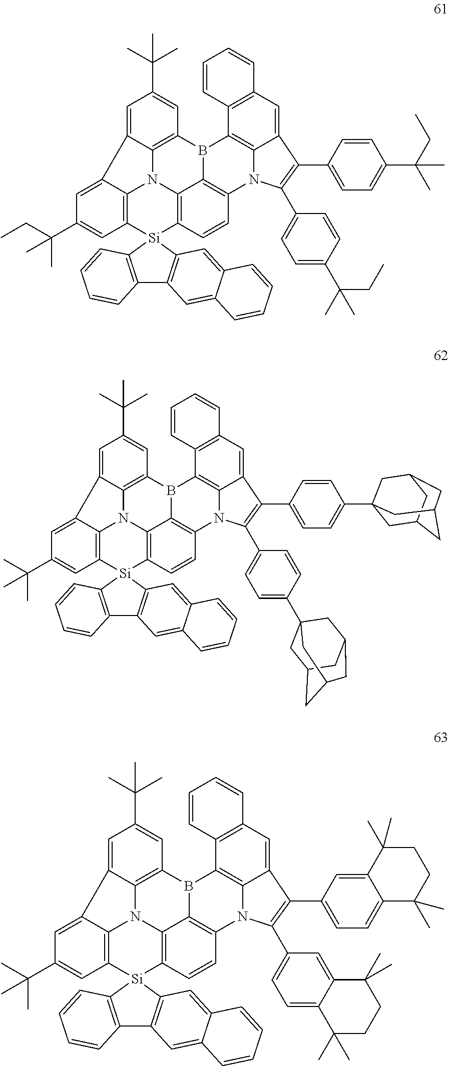 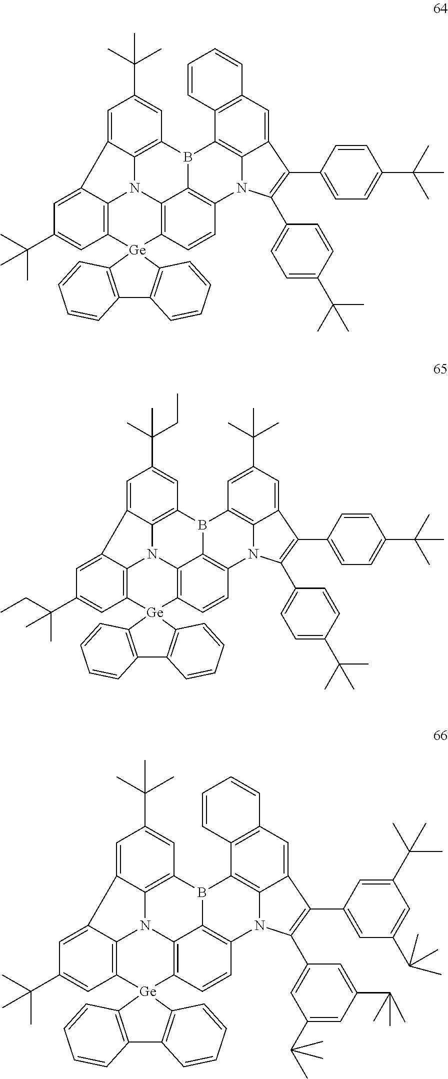 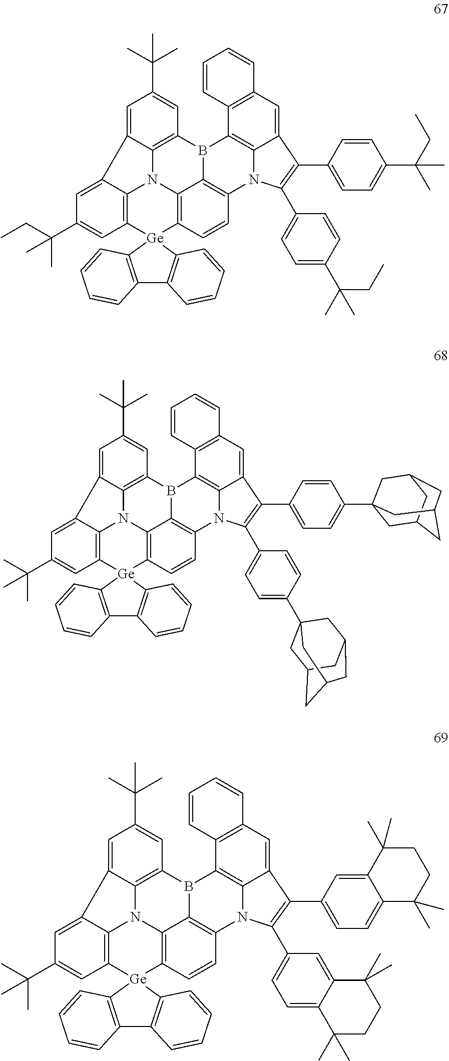 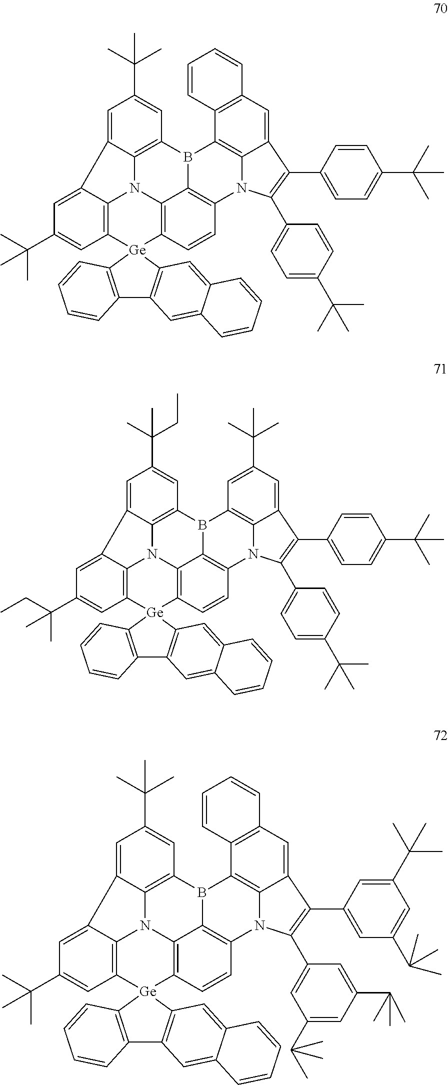 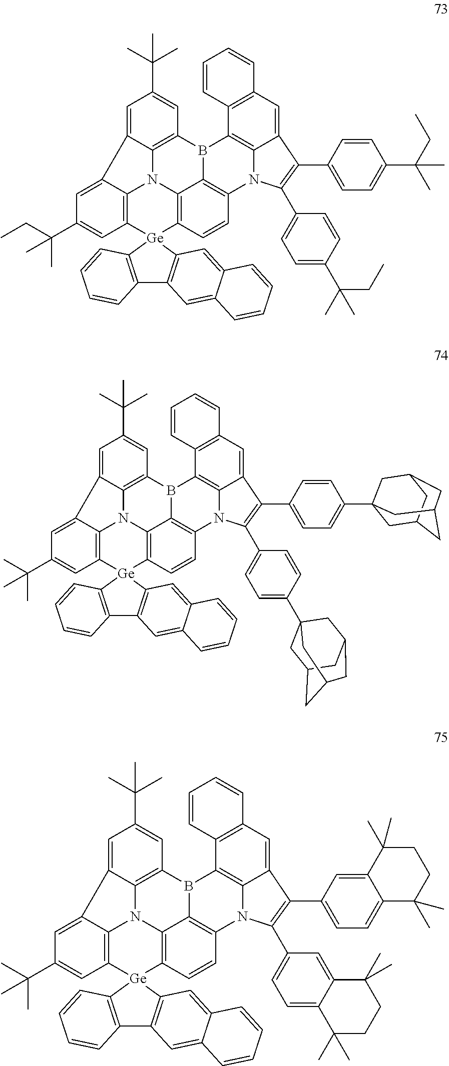 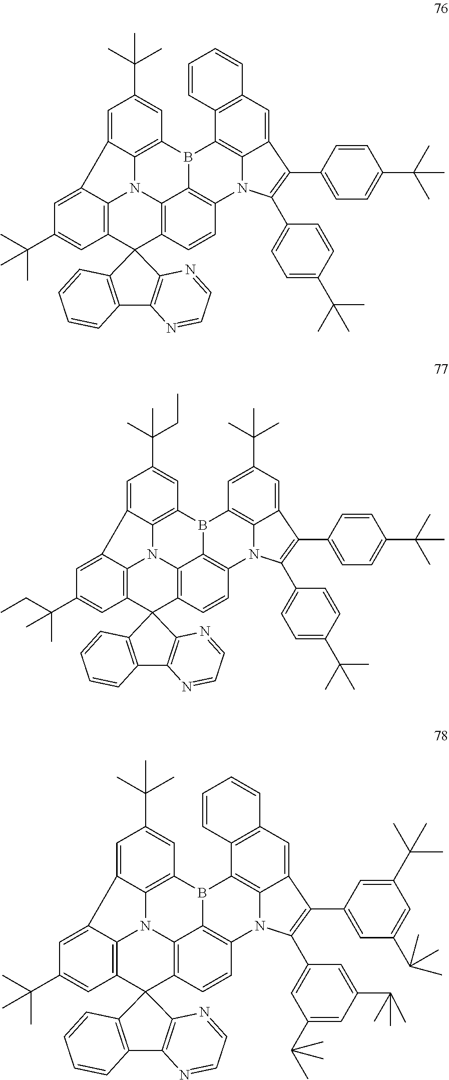 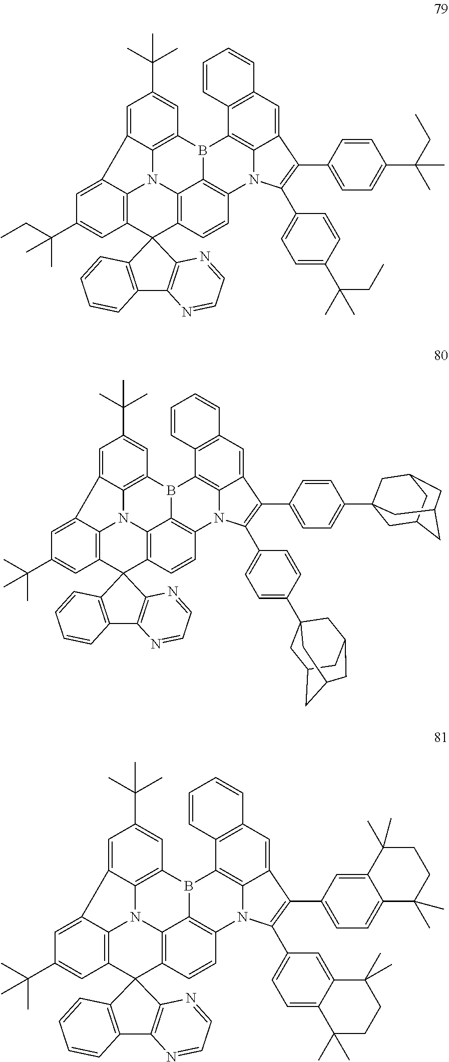 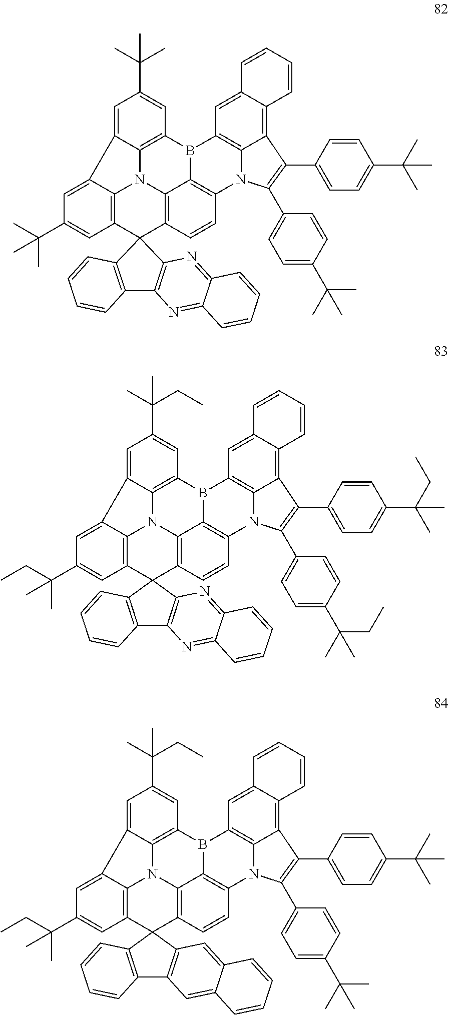 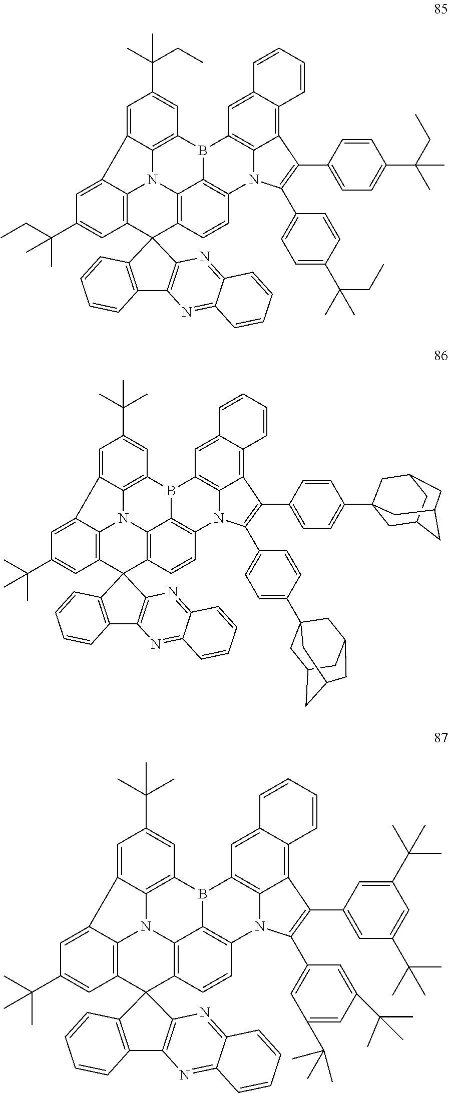 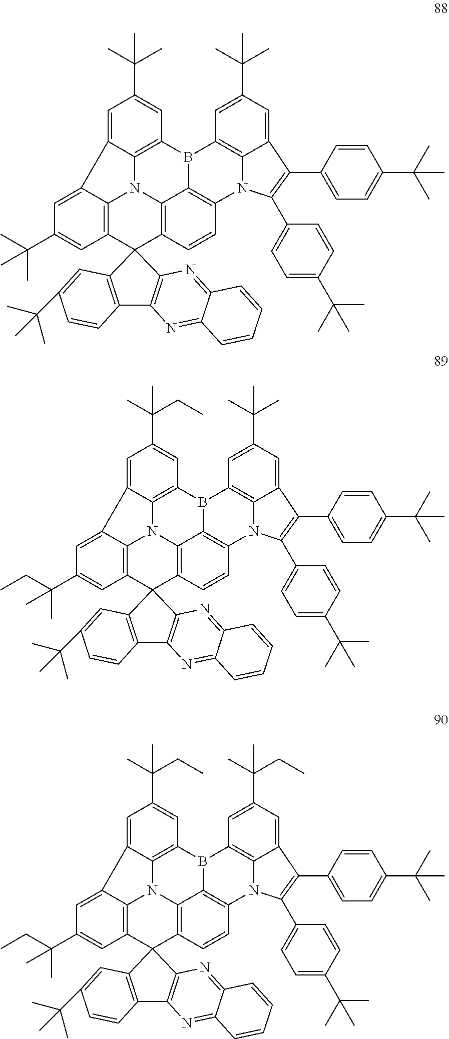 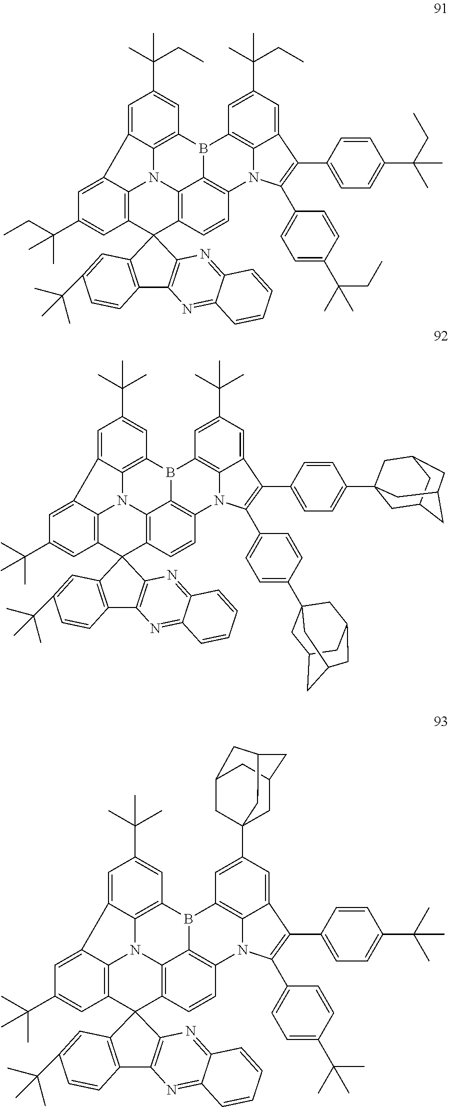 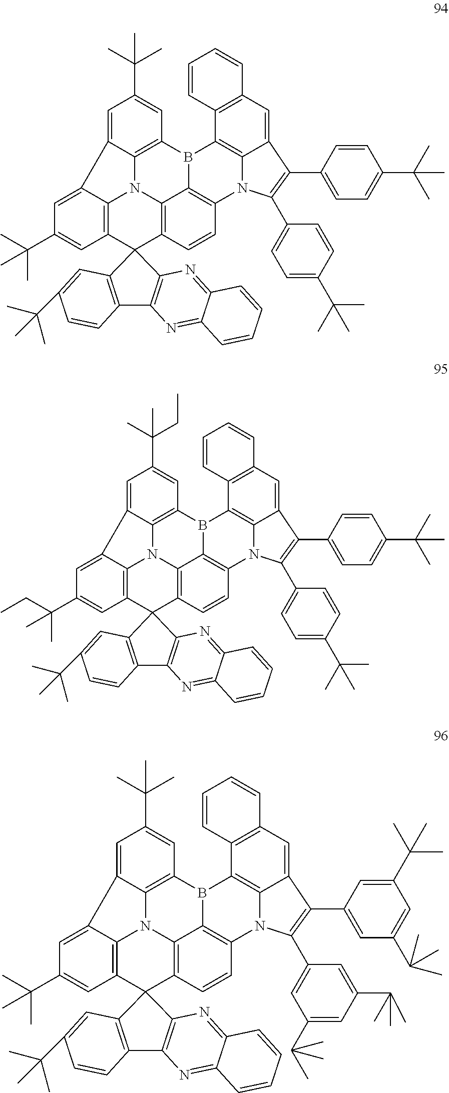 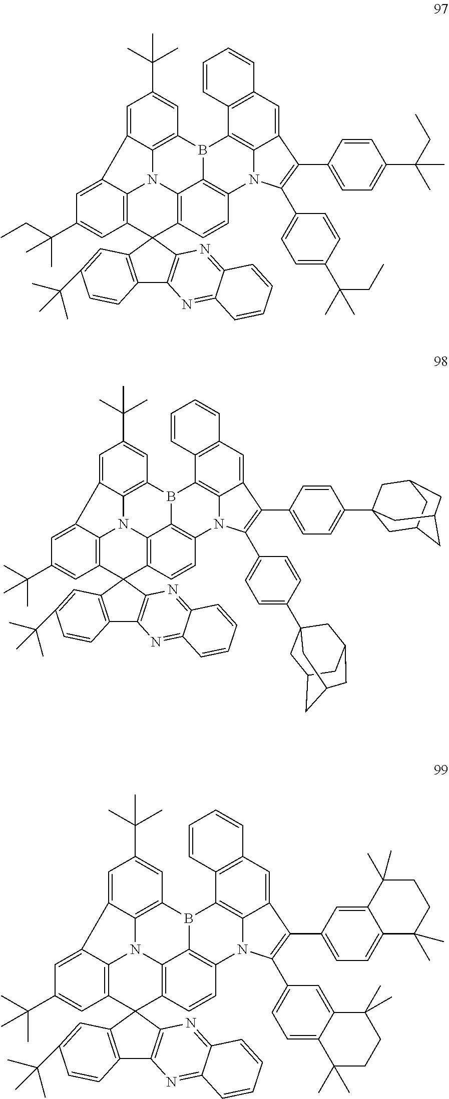 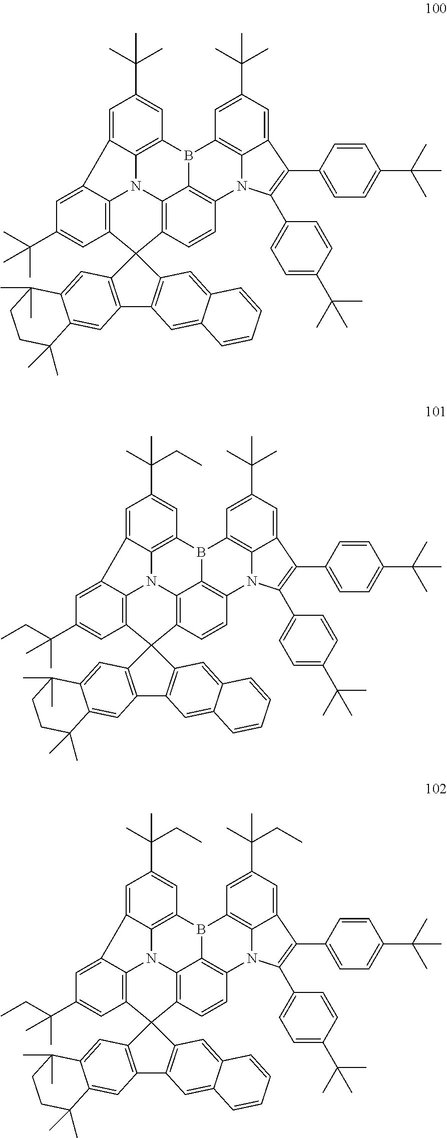 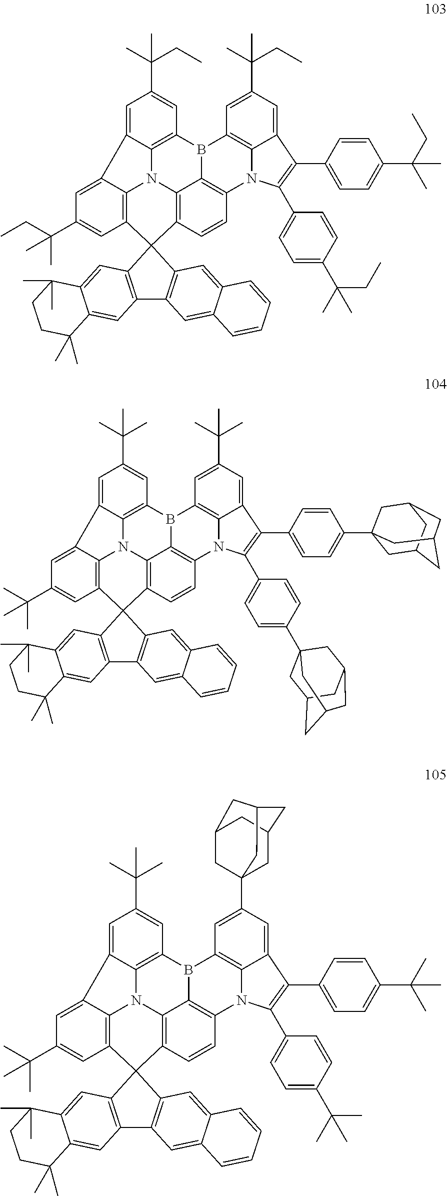 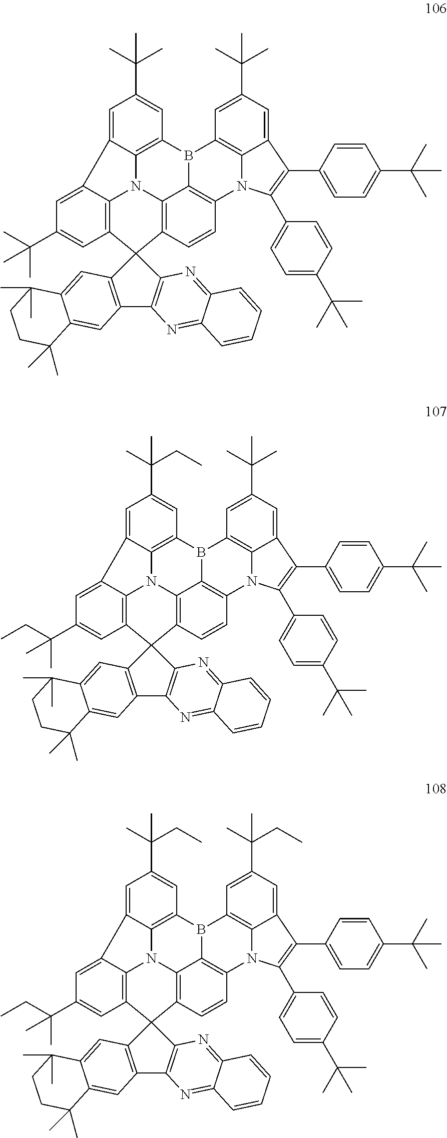 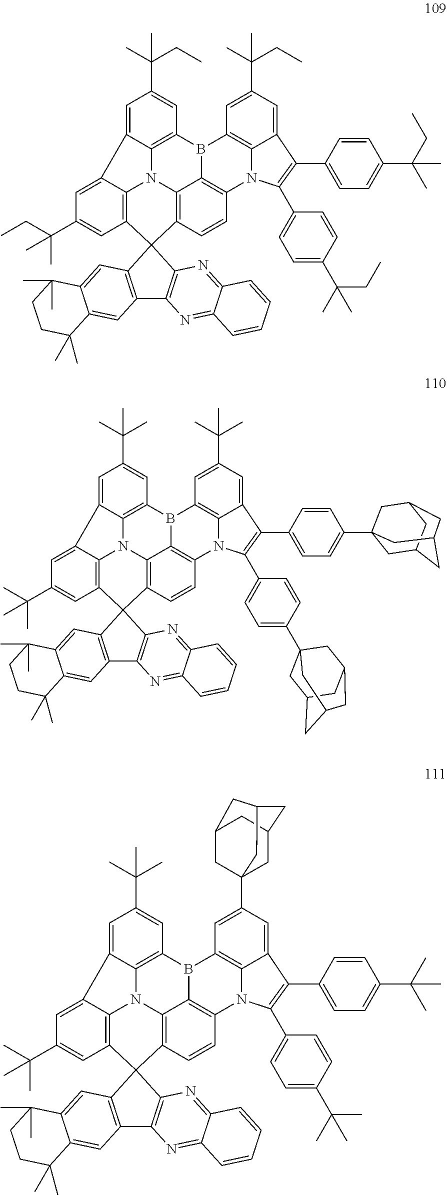 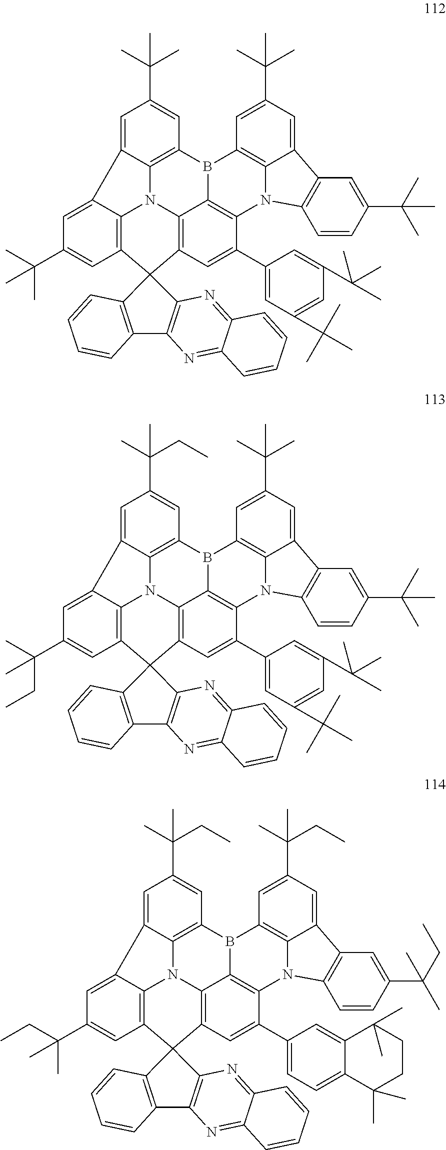 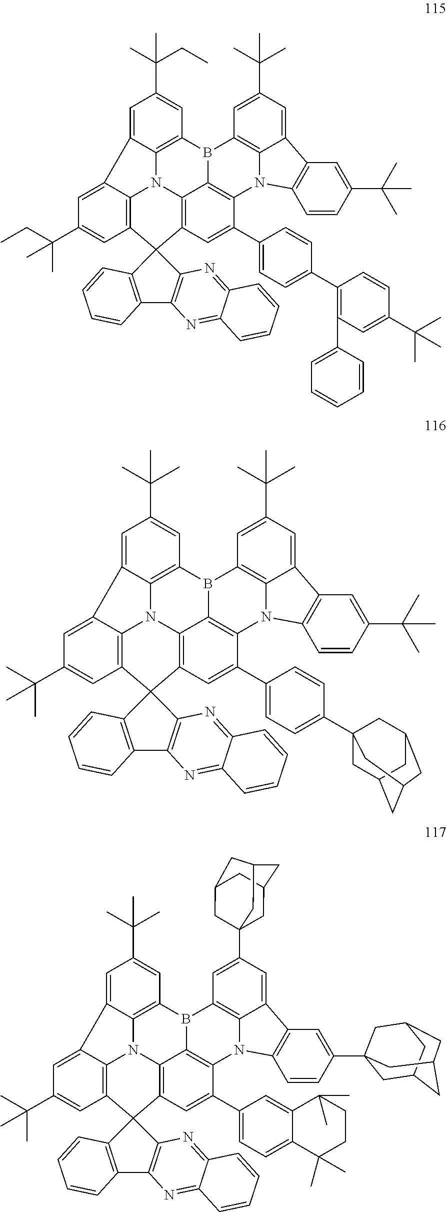 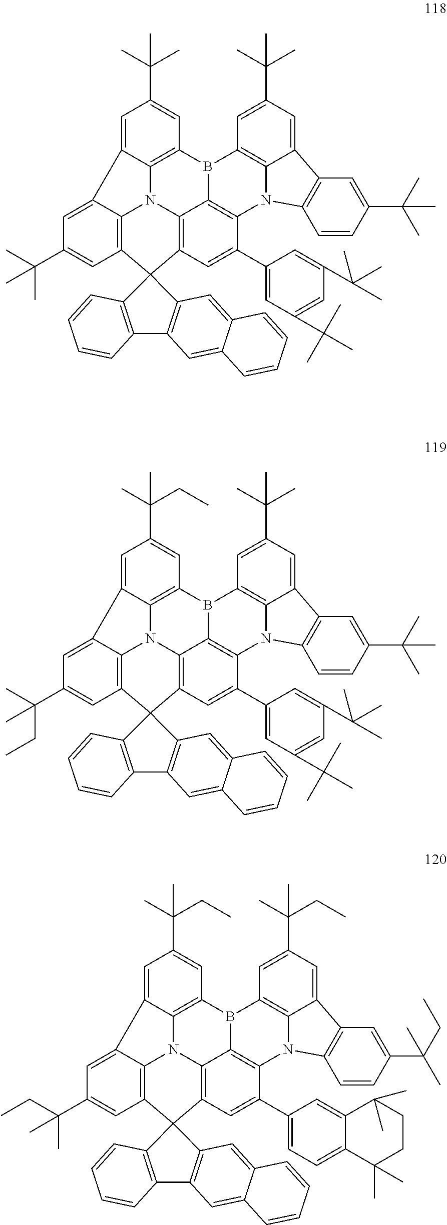 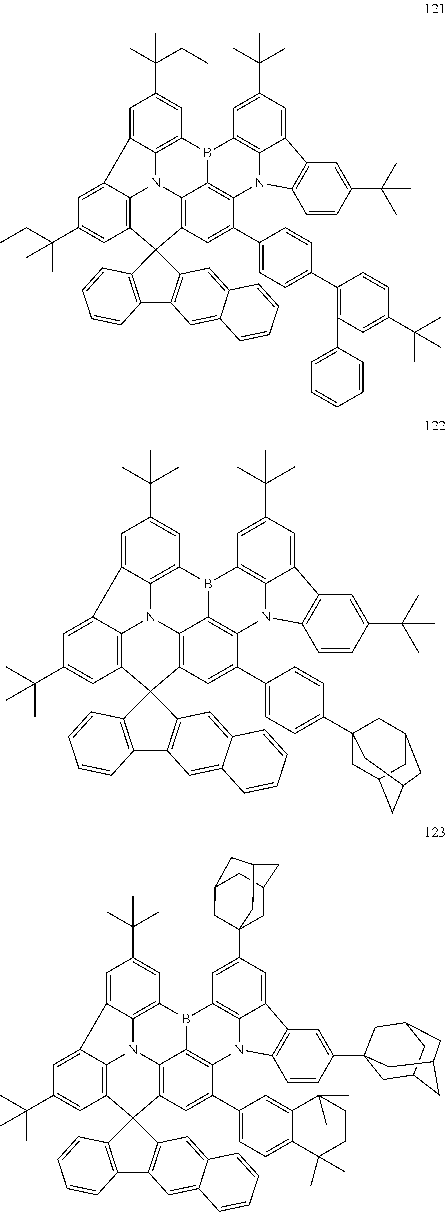 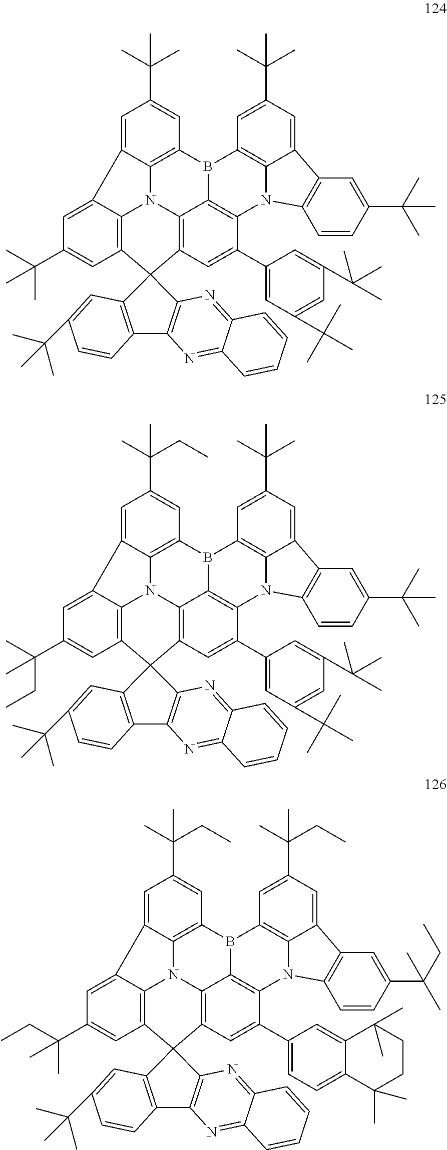 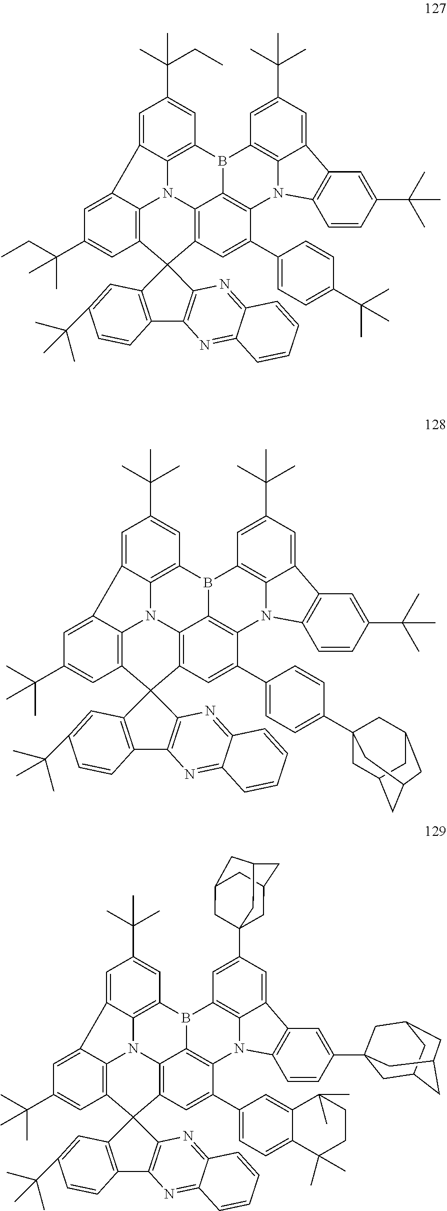 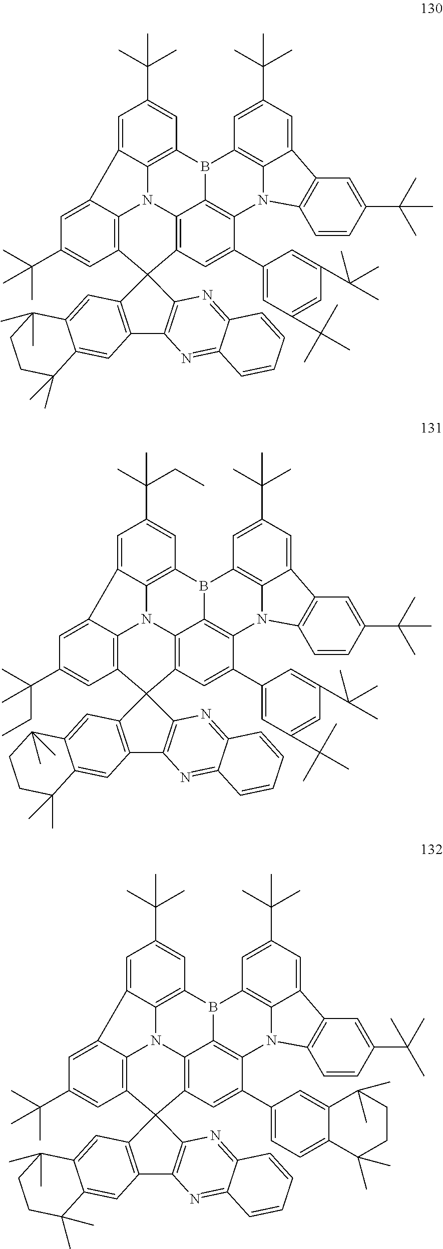 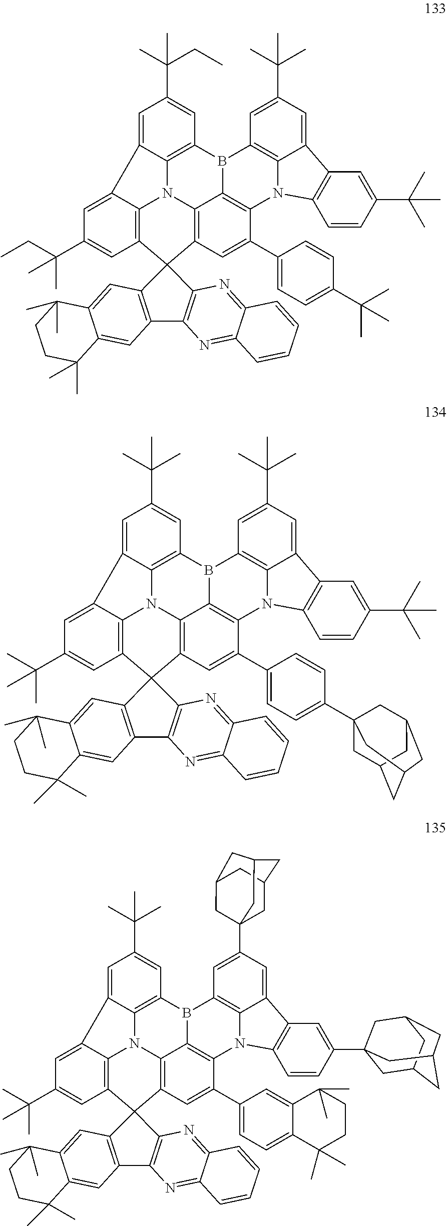 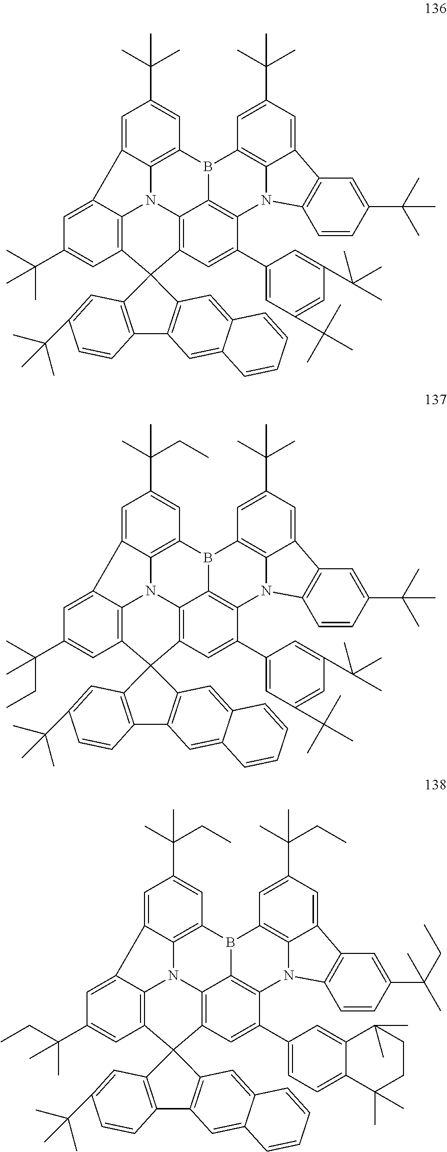 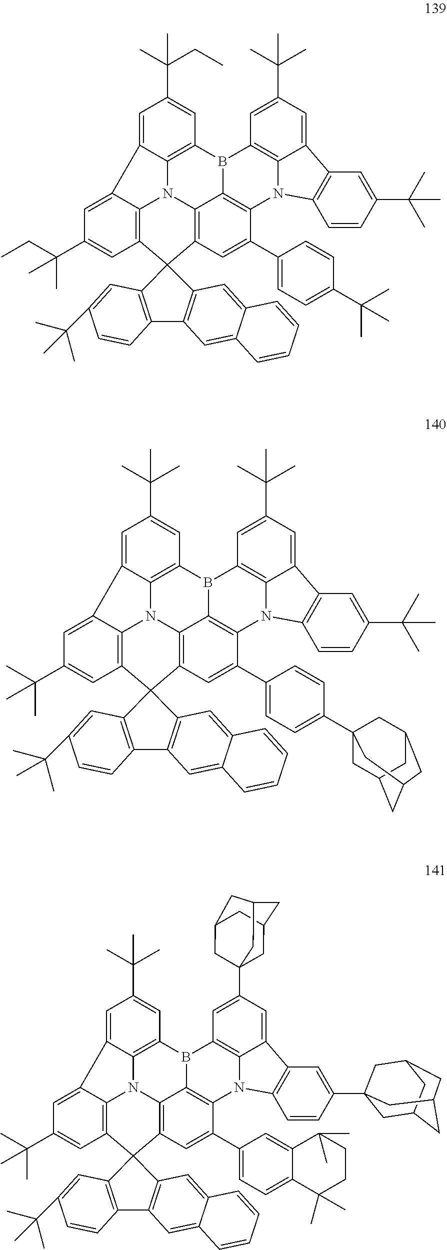 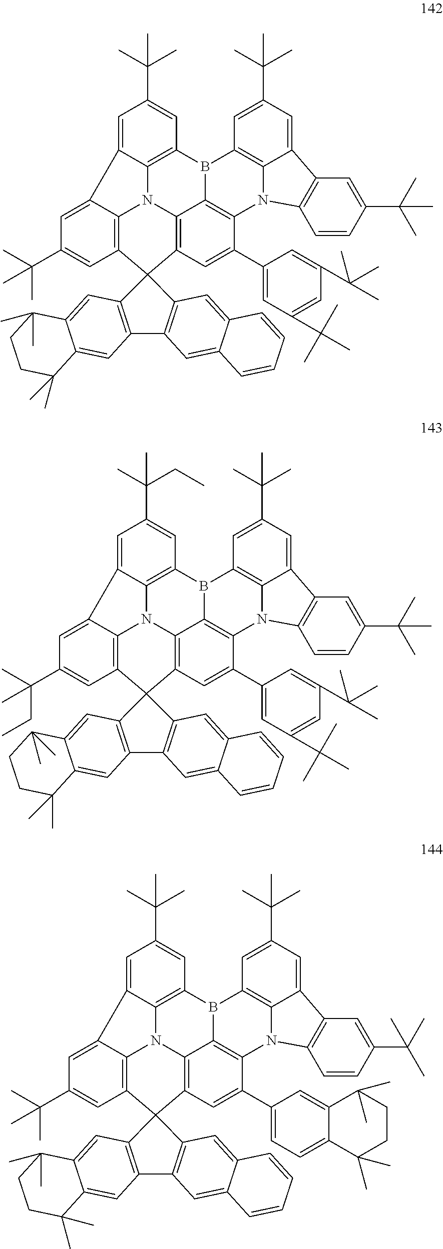 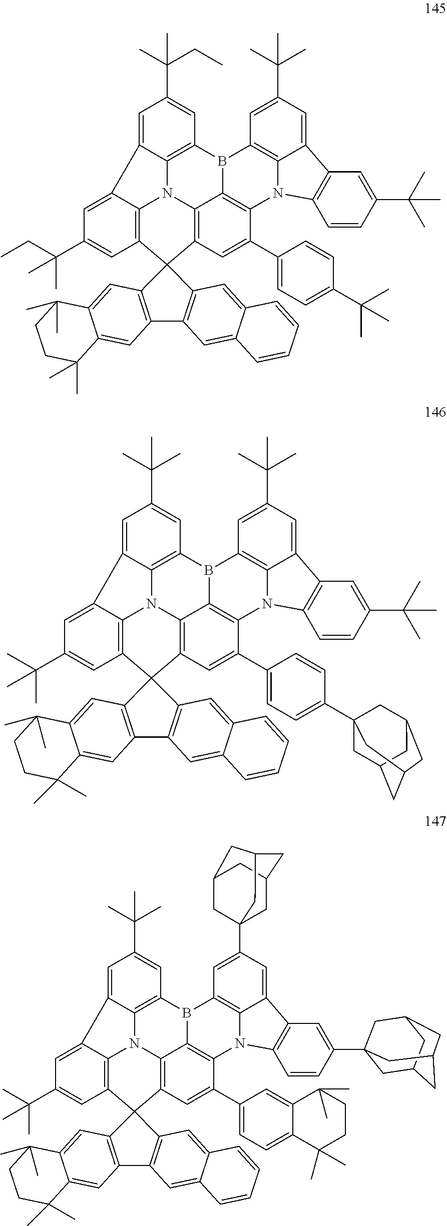 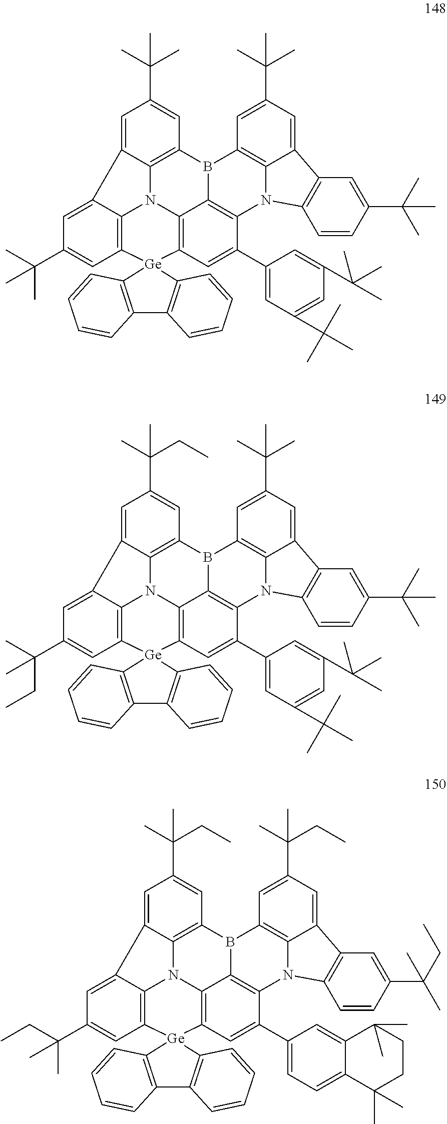 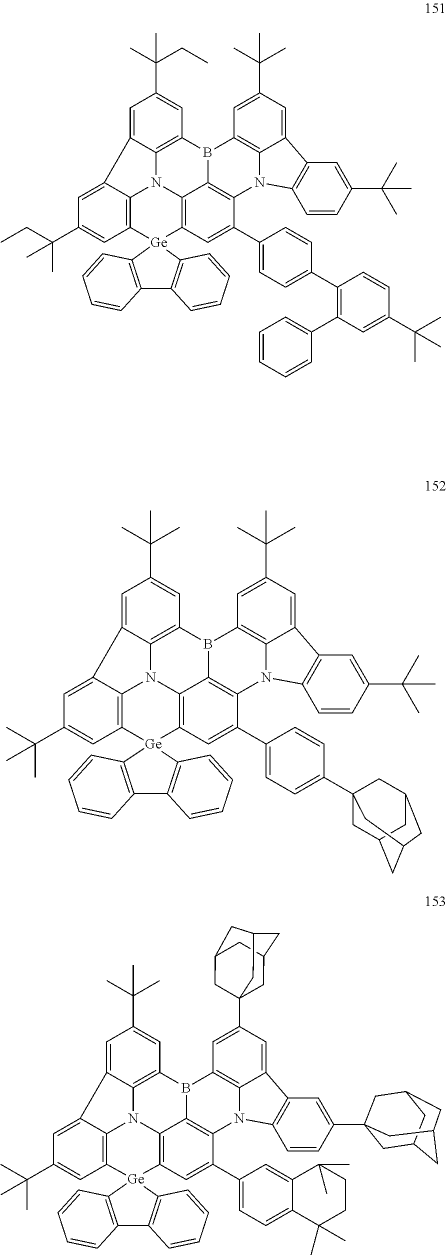 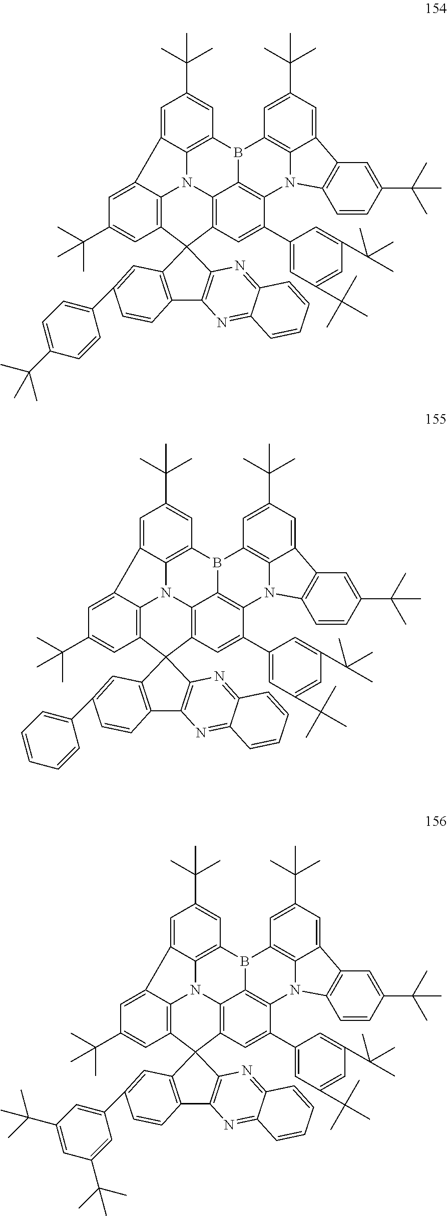 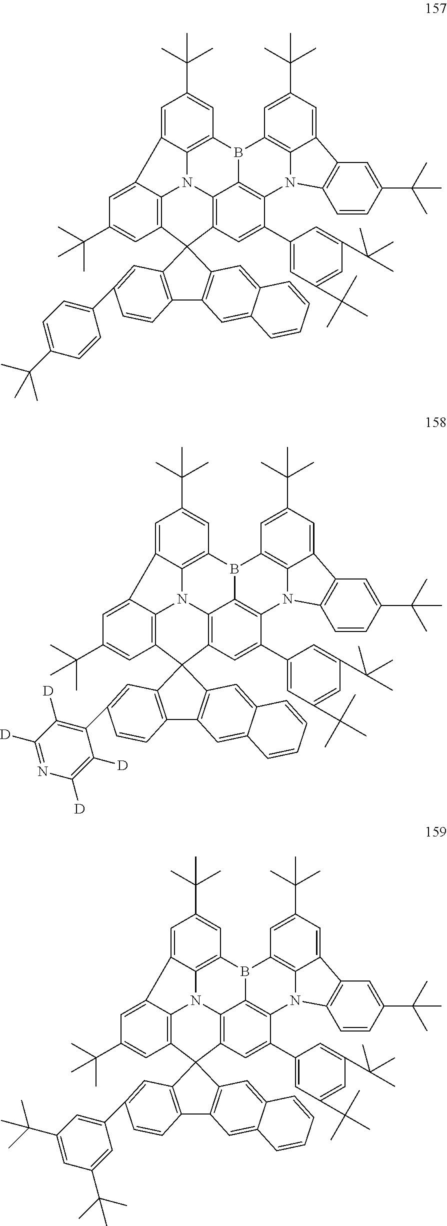 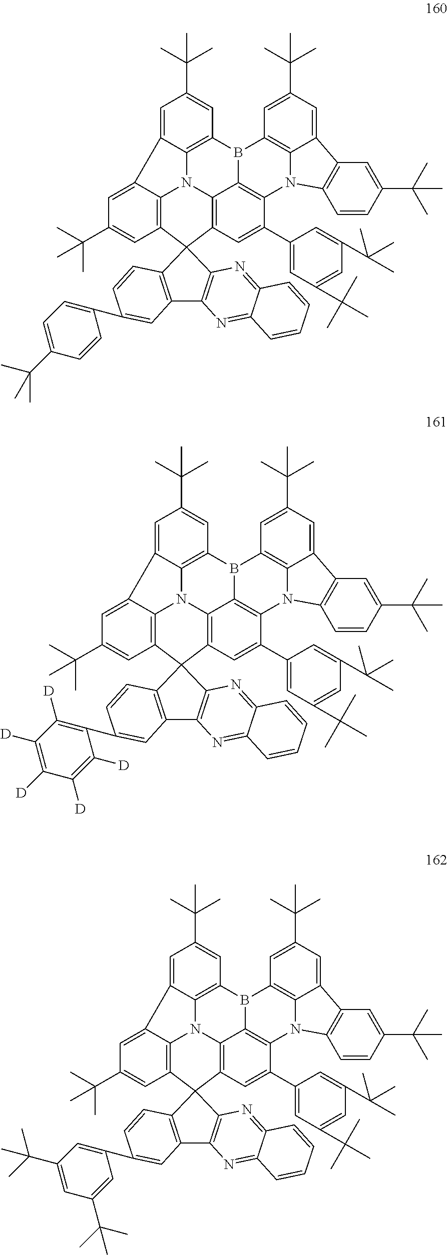 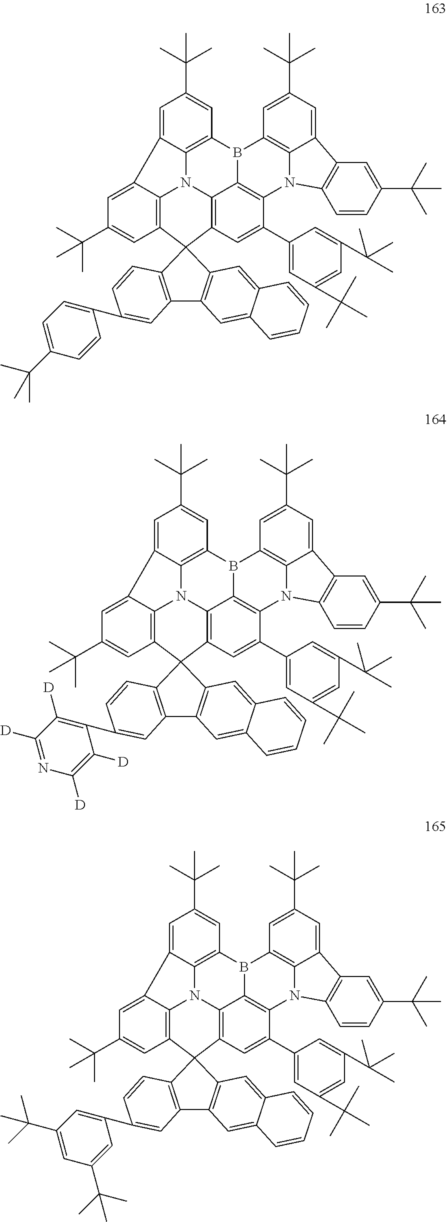 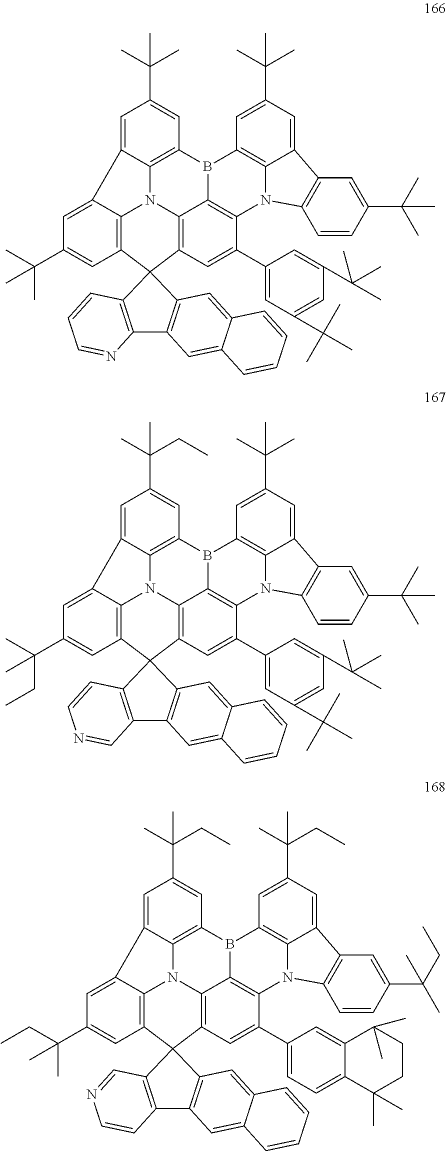 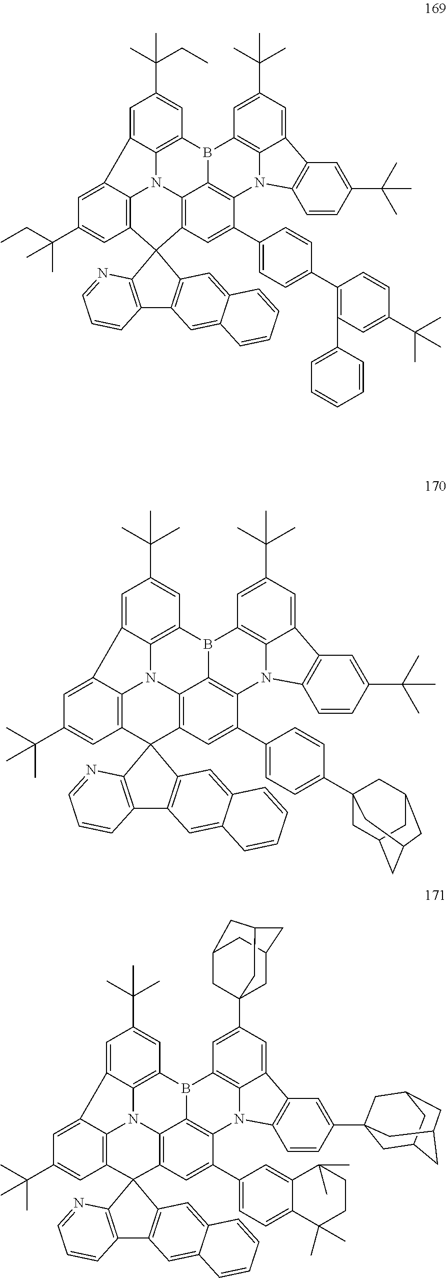 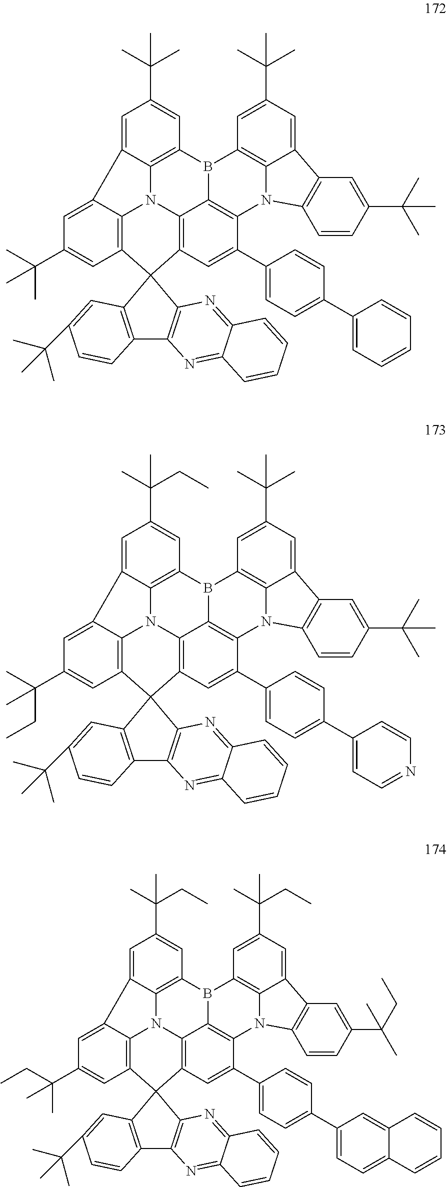 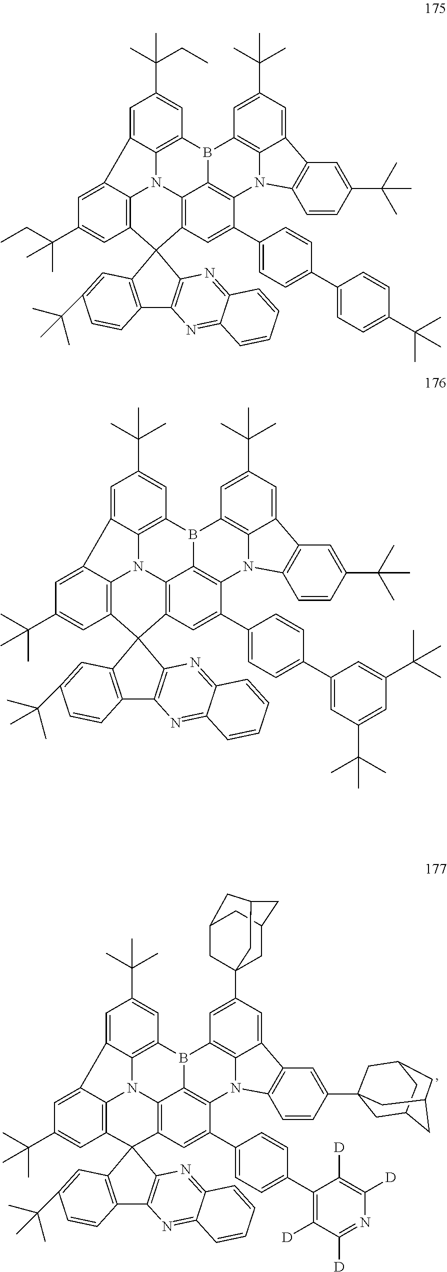
wherein D represents deuterium.

12. The boron-nitrogen compound according to claim 1, wherein at least one of R, R₄, R₅ or R₆ is connected with an adjacent substituent to form a ring.

13. An organic electroluminescent device, comprising a cathode, an anode and an organic functional layer between the cathode and the anode, wherein the organic functional layer comprises the boron-nitrogen compound according to claim 1.

14. An organic photoelectric device, comprising a first electrode, a second electrode facing the first electrode and a light-emitting material layer arranged between the first electrode and the second electrode, wherein the light-emitting material layer contains the boron-nitrogen compound according to claim 1.

15. A composition, containing the boron-nitrogen compound according to claim 1.

16. A formulation, containing the boron-nitrogen compound according to claim 1 and at least one solvent.

17. A display apparatus, comprising the organic electroluminescent device according to claim 13.

18. A display apparatus, comprising the organic photoelectric device according to claim 14.

19. A display apparatus, comprising an organic electroluminescent device and an organic photoelectric device, wherein
the organic electroluminescent device comprises a cathode, an anode and an organic functional layer between the cathode and the anode; and
the organic photoelectric device comprises a first electrode, a second electrode facing the first electrode and a light-emitting material layer arranged between the first electrode and the second electrode,
wherein the organic functional layer and the organic photoelectric device each contain the boron-nitrogen compound according to claim 1.

20. A lighting apparatus, comprising the organic electroluminescent device according to claim 13.
